(19) United States
(12) Patent Application Publication
(10) Pub. No.: US 2026/0068083 A1
(43) Pub. Date: Mar. 5, 2026

(54) COOLING DEVICE AND IN-VEHICLE APPARATUS

(71) Applicant: Panasonic Automotive Systems Co., Ltd., Kanagawa (JP)

(72) Inventors: Masanori YOKOTA, Kanagawa Ken (JP); Tomoko SASAKI, Kanagawa Ken (JP); Takeshi YAMAZAKI, Kanagawa Ken (JP); Yuki WATANABE, Kanagawa Ken (JP); Retta ITO, Kanagawa Ken (JP)

(73) Assignee: Panasonic Automotive Systems Co., Ltd., Kanagawa (JP)

(21) Appl. No.: 19/310,289

(22) Filed: Aug. 26, 2025

(30) Foreign Application Priority Data
Aug. 27, 2024 (JP) 2024-145612
Mar. 31, 2025 (JP) 2025-059768
Mar. 31, 2025 (JP) 2025-059769

(51) Int. Cl. H05K 7/20

(52) U.S. Cl. CPC H05K 7/20218

(57) ABSTRACT

A cooling device according to an embodiment cools a plurality of cooling target components mounted on a substrate. The cooling device includes a liquid cooler, an inlet port, an outlet port, and a housing. The liquid cooler is thermally coupled to the plurality of cooling target components and causes a liquid coolant to flow into a liquid coolant flow path to cool the plurality of cooling target components. The inlet port introduces the liquid coolant into the liquid coolant flow path. The outlet port discharges the liquid coolant from the liquid coolant flow path. The housing houses the liquid cooler in a state in which the inlet port and the outlet port protrude. The housing includes a guide member that guides a liquid to be removed in a predetermined direction.

### CROSS-REFERENCE TO RELATED APPLICATIONS

This application is based upon and claims the benefit of priority from Japanese Patent Application No. 2024-145612, filed Aug. 27, 2024, Japanese Patent Application No. 2025-059768, filed Mar. 31, 2025 and Japanese Patent Application No. 2025-059769, filed Mar. 31, 2025, the entire contents of which are incorporated herein by reference.

### FIELD

The present disclosure relates to a cooling device and an in-vehicle apparatus.

### BACKGROUND

Hitherto, there has been proposed a cooling device capable of reducing a thermal resistance and efficiently dissipating heat by closing a gap between a chip that is a heat dissipation target and a heat dissipation member such as a heat sink when dissipating the heat generated from the chip on a substrate on which a plurality of chips are mounted by using the heat dissipation member.

A related technique is described in JP 2006-294699 A.

In a cooling device that cools a substrate by using a metal water-cooling unit through which a liquid coolant is circulated, there is a possibility that the liquid coolant (for example, water) leaks from a liquid coolant flow path or dew condensation occurs on the water-cooling unit itself, and there is a possibility that a short circuit of the substrate occurs.

In order to cope with such problems, in the related art, measures have been taken to apply a coating for water resistance and moisture resistance to the substrate. However, since applying a coating increases a resistance value and creates a non-conductive state, it is difficult to apply such a coating to communication lines, ground lines, and the like, where a conductive state needs to be maintained.

In view of the above problems, an object of the present disclosure is to provide a cooling device and an in-vehicle apparatus capable of preventing a short circuit and migration in a substrate even in a case where leakage of a liquid coolant or dew condensation occurs.

### BRIEF DESCRIPTION OF THE DRAWINGS

FIG. 1 is a schematic configuration block diagram of a substrate cooling system of an embodiment;

FIG. 2 is an exploded perspective view of an example of an in-vehicle apparatus including a cooling unit of an embodiment;

FIG. 3 is an external perspective view of a cooling unit of a first embodiment;

FIG. 4 is a cross-sectional view taken along line A-A of FIG. 3;

FIG. 5 is a schematic explanatory cross-sectional view illustrating a mounting state of a cooling unit of a second embodiment;

FIG. 6A is a schematic explanatory cross-sectional view illustrating a mounting state of a cooling unit of a third embodiment;

FIG. 6B is a plan view of the vicinity of a height adjustment portion AD21 when viewed from a lower side in FIG. 6A;

FIG. 7 is a schematic explanatory cross-sectional view illustrating a mounting state of a cooling unit of a fourth embodiment;

FIG. 8 is a schematic explanatory cross-sectional view illustrating a mounting state of a cooling unit of a fifth embodiment;

FIG. 9 is a schematic explanatory cross-sectional view illustrating a mounting state of a cooling unit of a sixth embodiment;

FIG. 10 is an external perspective view illustrating a mounting state of a heat transfer member of the sixth embodiment;

FIG. 11 is a schematic explanatory cross-sectional view illustrating a mounting state of a cooling unit of a seventh embodiment;

FIG. 12A is a schematic explanatory cross-sectional view illustrating a mounting state of a cooling unit of an eighth embodiment;

FIG. 12B is a cross-sectional view taken along line A-A of FIG. 12A;

FIG. 13A is a schematic explanatory cross-sectional view illustrating a mounting state of a cooling unit of a ninth embodiment;

FIG. 13B is a cross-sectional view taken along line A-A of FIG. 13A;

FIG. 14A is a schematic explanatory cross-sectional view illustrating a mounting state of a cooling unit of a tenth embodiment;

FIG. 14B is an external perspective view of a spacer of the tenth embodiment;

FIG. 15 is a schematic explanatory cross-sectional view illustrating a mounting state of a cooling unit of an eleventh embodiment;

FIG. 16 is a schematic explanatory cross-sectional view illustrating a mounting state of a cooling unit of a twelfth embodiment;

FIG. 17A is a cross-sectional view of a height adjustment portion of a thirteenth embodiment;

FIG. 17B is a schematic explanatory cross-sectional view illustrating a mounting state of a cooling unit of the thirteenth embodiment;

FIG. 18 is a schematic explanatory view illustrating a mounting state of a cooling unit of a fourteenth embodiment;

FIG. 19 is a schematic explanatory cross-sectional view illustrating a mounting state of a cooling unit of a fifteenth embodiment;

FIG. 20A is a schematic explanatory cross-sectional view of a metal thick plate used in a sixteenth embodiment;

FIG. 20B is a schematic explanatory cross-sectional view of a height adjustment member of the sixteenth embodiment;

FIG. 20C is a schematic explanatory cross-sectional view illustrating a mounting state of a cooling unit of the sixteenth embodiment;

FIG. 21A is a front view of a cooling unit 13F of a seventeenth embodiment;

FIG. 21B is a (right) side view of the cooling unit 13F of the seventeenth embodiment;

FIG. 21C is a rear view of the cooling unit 13F of the seventeenth embodiment;

FIG. 22 is a partially exploded perspective view (part 1) of the cooling unit of the seventeenth embodiment;

FIG. 23 is a partially exploded perspective view (part 2) of the cooling unit of the seventeenth embodiment;

FIG. 24 is a partially enlarged cross-sectional perspective view of the cooling unit of the seventeenth embodiment;

FIG. 25 is an explanatory view of a flow of a liquid coolant in the cooling unit of the seventeenth embodiment;

FIG. 26A is a plan view of a flow path protrusion 55F as another shape example of a flow path protrusion;

FIG. 26B is a plan view of a flow path protrusion 55G as another shape example of the flow path protrusion;

FIG. 26C is a plan view of a flow path protrusion 55H as another shape example of the flow path protrusion;

FIG. 26D is a plan view of a flow path protrusion 55J as another shape example of the flow path protrusion;

FIG. 27A is an explanatory view (part 1) of a flow of the liquid coolant on an introduction side;

FIG. 27B is an explanatory view (part 2) of the flow of the liquid coolant on the introduction side;

FIG. 27C is an explanatory view (part 3) of the flow of the liquid coolant on the introduction side;

FIG. 28A is an explanatory view illustrating a case where distribution of a flow of the liquid coolant is uneven on a discharge side;

FIG. 28B is an explanatory view illustrating a case where an installation position of the flow path protrusion is shifted to suppress unevenness of the distribution of the flow of the liquid coolant when the distribution of the flow of the liquid coolant is uneven on the discharge side;

FIG. 29A is a plan view of a flow path protrusion 55K as another shape example;

FIG. 29B is a plan view of a flow path protrusion 55L as another shape example;

FIG. 30 is an internal explanatory view of a cooling unit of an eighteenth embodiment;

FIG. 31A is a partial cross-sectional view of a liquid coolant flow path of a modified example of the eighteenth embodiment;

FIG. 31B is a cross-sectional view of the liquid coolant flow path of the modified example of the eighteenth embodiment;

FIG. 32 is an external perspective view of a cooling unit of a nineteenth embodiment when viewed from a rear side;

FIG. 33 is an explanatory view of a twentieth embodiment;

FIG. 34 is a partially exploded perspective view of a cooling unit of a twenty-first embodiment;

FIG. 35 is a plan view of a cooling unit of a twenty-second embodiment;

FIG. 36 is a cross-sectional view of a portion corresponding to a broken line frame BA in FIG. 35;

FIG. 37 is a cross-sectional view of a cooling unit of a modified example of the twenty-second embodiment;

FIG. 38 is an explanatory view of a twenty-third embodiment;

FIG. 39 is an explanatory view of a twenty-fourth embodiment;

FIG. 40A is a partial front view of a cooling unit 13N of a twenty-fifth embodiment;

FIG. 40B is a front view of a slit member of the twenty-fifth embodiment;

FIG. 40C is an explanatory view in a case where the slit member is inserted into the cooling unit 13N of the twenty-fifth embodiment;

FIG. 41A is a cross-sectional view taken along line B-B of FIG. 40A;

FIG. 41B is a view corresponding to a cross section taken along line B-B of FIG. 40A after brazing of a slit member 122;

FIG. 42A is a partial front view of a cooling unit 13N of a first modified example of the twenty-fifth embodiment;

FIG. 42B is a front view of a slit member of the first modified example of the twenty-fifth embodiment;

FIG. 43 is an explanatory view of a second modified example of the twenty-fifth embodiment;

FIG. 44A is an explanatory view of a third modified example of the twenty-fifth embodiment;

FIG. 44B is an explanatory view of a fourth modified example of the twenty-fifth embodiment;

FIG. 45A is a plan view of an introduction coupler 130 of a first aspect of a twenty-sixth embodiment;

FIG. 45B is a front view of the introduction coupler 130 of the first aspect of the twenty-sixth embodiment;

FIG. 45C is a side view of the introduction coupler 130 of the first aspect of the twenty-sixth embodiment;

FIG. 46A is a plan view of an introduction coupler 130X of a second aspect of the twenty-sixth embodiment;

FIG. 46B is a front view of the introduction coupler 130X of the second aspect of the twenty-sixth embodiment;

FIG. 46C is a side view of the introduction coupler 130X of the second aspect of the twenty-sixth embodiment;

FIG. 47 is an explanatory perspective view illustrating an example of a case where a cooling unit is housed between a housing and a front chassis;

FIG. 48 is a front view illustrating a case where the cooling unit is housed between the housing and the front chassis;

FIG. 49 is an external perspective view of a cooling unit attached with a liquid intrusion prevention wall member of a twenty-seventh embodiment;

FIG. 50 is a view of the cooling unit attached with the liquid intrusion prevention wall member of the twenty-seventh embodiment when viewed from an introduction coupler and a discharge coupler;

FIG. 51 is a front view illustrating a case where the cooling unit is housed between a housing and a front chassis, and the liquid intrusion prevention wall member and a liquid intrusion prevention member of the twenty-seventh embodiment are provided;

FIG. 52 is an explanatory view of a twenty-eighth embodiment;

FIG. 53 is a partially enlarged view of a housing of a twenty-ninth embodiment;

FIG. 54 is an explanatory view of a modified example of the twenty-ninth embodiment;

FIG. 55 is an explanatory view of a thirtieth embodiment;

FIG. 56 is an explanatory view of a first modified example of the thirtieth embodiment;

FIG. 57 is an explanatory view of a second modified example of the thirtieth embodiment;

FIG. 58 is an external perspective view of a cooling unit of a thirty-first embodiment;

FIG. 59 is an exploded perspective view of the cooling unit of the thirty-first embodiment;

FIG. 60 is an external perspective view of a cooling unit of a thirty-second embodiment;

FIG. 61 is an exploded perspective view of the cooling unit of the thirty-second embodiment;

FIG. 62A is an external perspective view of a cooling unit body 173 in an assembled state;

FIG. 62B is a front view of the cooling unit body 173 in the assembled state;

FIG. 63 is an explanatory view illustrating a step of fitting a sealing member into the cooling unit;

FIG. 64 is an exploded perspective view (part 1) of a cooling unit of a thirty-third embodiment at the time of assembly;

FIG. 65 is an exploded perspective view (part 2) of the cooling unit of the thirty-third embodiment at the time of assembly;

FIG. 66 is an exploded perspective view (part 3) of the cooling unit of the thirty-third embodiment at the time of assembly; and

FIG. 67 is a completed perspective view of the cooling unit of the thirty-third embodiment.

### DETAILED DESCRIPTION

### Solution to Problem

A cooling device according to an embodiment cools a plurality of cooling target components mounted on a substrate. The cooling device includes a liquid cooler, an inlet port, an outlet port, and a housing. The liquid cooler is thermally coupled to the plurality of cooling target components and causes a liquid coolant to flow into a liquid coolant flow path to cool the plurality of cooling target components. The inlet port introduces the liquid coolant into the liquid coolant flow path. The outlet port discharges the liquid coolant from the liquid coolant flow path. The housing houses the liquid cooler in a state in which the inlet port and the outlet port protrude. The housing includes a guide member that guides a liquid to be removed in a predetermined direction.

According to the present disclosure, a short circuit or migration in a substrate can be prevented even in a case where leakage of a liquid coolant or dew condensation occurs.

Next, an embodiment will be described in detail with reference to the drawings.

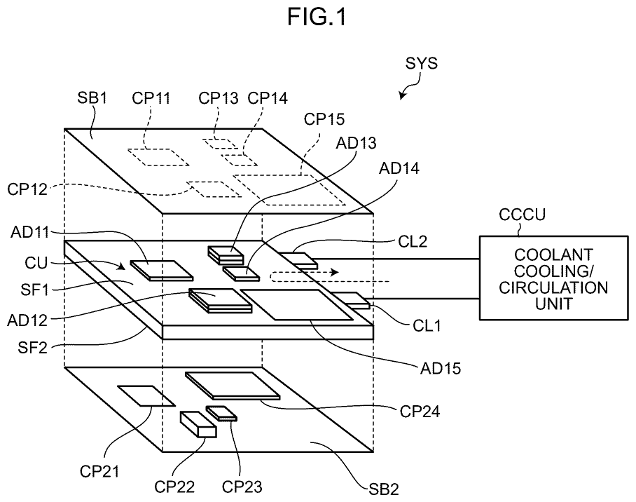

FIG. 1 is a schematic configuration block diagram of a substrate cooling system of an embodiment.

A substrate cooling system SYS includes a cooling unit (liquid cooler) CU and a coolant cooling/circulation unit CCCU.

In FIG. 1, actually, a substrate SB1 and a substrate SB2 thermally (and mechanically) coupled to the cooling unit CU are illustrated in a separated state for easy understanding.

In this case, it is assumed that cooling target chips CP11 to CP15 are mounted on a back side (a lower surface side in FIG. 1) of the substrate SB1, and cooling target chips CP21 to CP24 are mounted on a front side (an upper surface in FIG. 1) of the substrate SB2.

The cooling unit CU includes an introduction coupler CL1 into which a liquid coolant supplied from the coolant cooling/circulation unit CCCU is introduced, a discharge coupler CL2 from which the liquid coolant after cooling is discharged to the coolant cooling/circulation unit CCCU, and height adjustment portions (coupling position adjustment portions) AD11 to AD15 formed on a first surface SF1 of the cooling unit CU.

In the above configuration, in an actual use state, the height adjustment portions AD11 to AD15 are thermally coupled to the corresponding cooling target chips CP11 to CP15, which are mounted on the substrate SB1, and transfer heat generated in the chips CP11 to CP15 to the cooling unit CU to perform heat exchange, thereby cooling the chips CP11 to CP15.

In this case, the thermal coupling includes not only direct coupling (direct contact) but also coupling via a heat conductive material such as thermal grease (the same applies hereinafter).

In the example of FIG. 1, the height adjustment portion AD11 corresponds to the chip CP11 mounted on the substrate SB1. Similarly, the height adjustment portion AD12 corresponds to the chip CP12, the height adjustment portion AD13 corresponds to the chip CP13, the height adjustment portion AD14 corresponds to the chip CP14, and the height adjustment portion AD15 corresponds to the chip CP15.

In the above description, a case where the height adjustment portions AD11 to AD15 are provided for the chips CP11 to CP15, respectively, has been described. However, in a case where there is a chip that can be thermally coupled directly to the first surface SF1 of the cooling unit, the chip can be thermally coupled directly to the cooling unit CU.

Although not illustrated in FIG. 1, four height adjustment portions are also formed on a second surface SF2 of the cooling unit CU so as to correspond to the cooling target chips CP21 to CP24, the chips CP21 to CP24 being mounted on the substrate SB2.

Next, a schematic operation of the substrate cooling system SYS of FIG. 1 will be described.

The coolant cooling/circulation unit CCCU introduces the cooled liquid coolant into the cooling unit CU via the introduction coupler CL1.

As a result, the liquid coolant exchanges heat with the cooling target chips via the height adjustment portions AD11 to AD15 and the height adjustment portions on the second surface SF2 of the cooling unit CU to cool the cooling target chips.

Further, the liquid coolant after the heat exchange returns to the coolant cooling/circulation unit CCCU again via the discharge coupler CL2, is cooled, and is supplied to the introduction coupler CL1.

By repeating the above operation, the cooling target chips CP11 to CP15, which are mounted on the substrate SB1, and the cooling target chips CP21 to CP24 mounted on the substrate SB2, can be operated in a cooled state, predetermined processing can be reliably executed without causing a decrease in processing speed due to heat generation, so that desired performance can be exhibited.

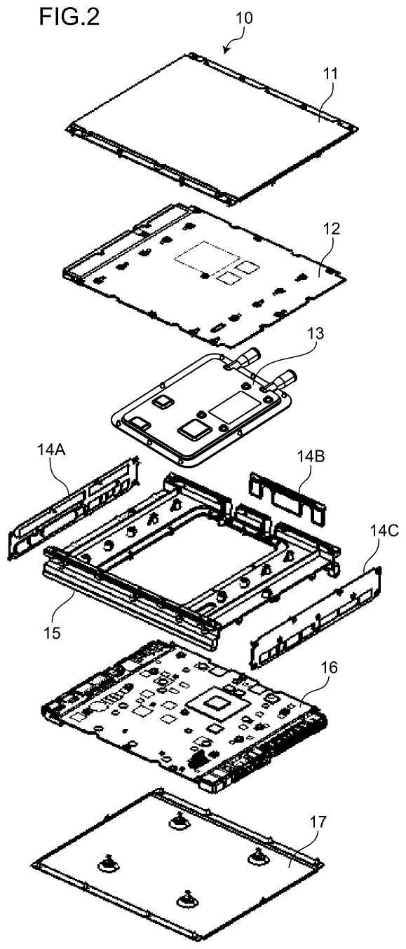

FIG. 2 is an exploded perspective view of an example of an in-vehicle apparatus including a cooling unit of an embodiment.

An in-vehicle apparatus 10 includes a top panel 11, a first substrate 12, a cooling unit 13, side chassis 14A and 14C, a side cover 14B, a central chassis 15, a second substrate 16, and a bottom panel 17.

The top panel 11 is formed of, for example, an aluminum press material, and forms a part of a casing of the in-vehicle apparatus 10.

The first substrate 12 is a printed circuit board (PCB) on which a plurality of cooling target semiconductor chips are mounted.

A liquid coolant flow path is formed inside the cooling unit 13, and the cooling unit 13 performs heat exchange with the semiconductor chips mounted on the first substrate 12 and the second substrate 16 to perform cooling.

The side chassis 14A and 14C are formed of, for example, aluminum press materials, and form a part of the casing of the in-vehicle apparatus 10.

The side cover 14B is formed by, for example, two-color molding of resin and rubber, and forms a part of the casing of the in-vehicle apparatus 10.

The central chassis 15 is, for example, a component made of die-cast aluminum. The first substrate 12, the cooling unit 13, and the second substrate 16 are fixed to the central chassis 15, and the central chassis 15 supports the first substrate 12, the cooling unit 13, and the second substrate 16 while maintaining a state in which the first substrate 12 and the second substrate 16 are thermally coupled to the cooling unit 13.

Similarly to the first substrate 12, the second substrate 16 is a printed circuit board (PCB) on which a plurality of cooling target semiconductor chips are mounted.

The bottom panel 17 is formed of, for example, an aluminum press material, and forms a part of the casing of the in-vehicle apparatus 10.

Next, more specific embodiments will be described with reference to the drawings.

### (1) First Embodiment

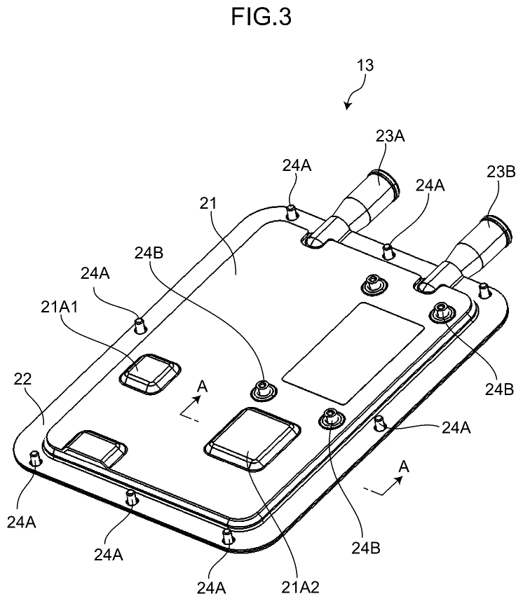

FIG. 3 is an external perspective view of a cooling unit of a first embodiment.

A cooling unit 13 includes a heat transfer member 21, a cooling unit body 22, an introduction coupler 23A, a discharge coupler 23B, a screw fastening portion 24A, and a stud 24B.

The heat transfer member 21 is implemented by one metal plate, and the heat transfer member 21 is provided with height adjustment portions 21A1 and 21A2 corresponding to a plurality of cooling target semiconductor chips.

In this case, a shape, a height, and a planar shape of each of the height adjustment portions 21A1 and 21A2 are determined according to a planar shape and a height of the cooling target semiconductor chip and a mounting position of the semiconductor chip.

A liquid coolant flow path is formed inside the cooling unit body 22 and the cooling unit body 22 performs heat exchange with the cooling target semiconductor chip via the heat transfer member 21 to cool the semiconductor chip.

The introduction coupler 23A is connected to a coolant cooling/circulation unit (not illustrated), and a liquid coolant is introduced into the cooling unit body 22 from the coolant cooling/circulation unit (not illustrated).

The discharge coupler 23B is connected to the coolant cooling/circulation unit (not illustrated), and the liquid coolant after the heat exchange is discharged to the coolant cooling/circulation unit (not illustrated).

The screw fastening portion 24A indicates a state in which a screw is inserted into and fastened to a through-hole provided in the cooling unit 13. Therefore, in a state in which fastening with the screw is not made, each through-hole is provided at a position corresponding to the screw fastening portion 24A. In FIG. 3, the screw fastening portion 24A is used to fasten a water-cooling unit together. However, the screw fastening portion 24A does not necessarily have such a function, and positioning pins may be provided in a necessary number of through-holes as necessary.

The stud 24B is also provided on both an upper surface and a lower surface of the cooling unit 13, and each of a first substrate 12 and a second substrate 16 is fixed and supported by a screw or the like in a state in which the first substrate 12 and the second substrate 16 are separated from each other by a predetermined distance.

Here, an internal structure of the cooling unit 13 will be described.

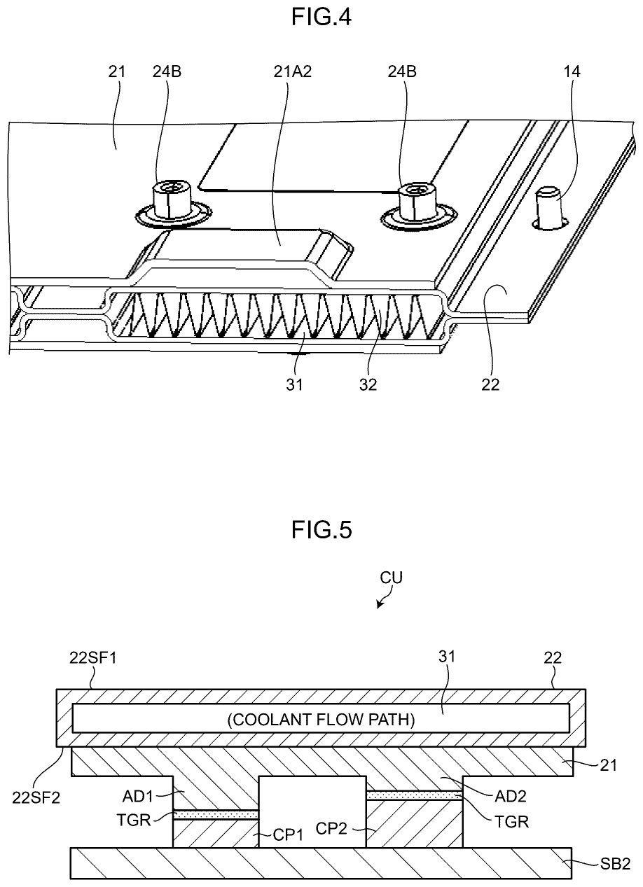

FIG. 4 is a cross-sectional view taken along line A-A of FIG. 3.

A liquid coolant flow path 31 is formed inside the cooling unit body 22 of the cooling unit 13, and a fin (straightening plate) 32 for straightening a flow of the liquid coolant is disposed in the liquid coolant flow path 31.

In addition, in the example of FIG. 4, the height adjustment portion 21A2 of the heat transfer member 21 is formed by drawing a metal plate-shaped member using a press machine, and has a protruding cross-sectional shape. As a result, a space is formed between the height adjustment portion 21A2 and the cooling unit body 22.

As described above, in the configuration of the first embodiment, the heat transfer member 21 is configured as one member and has the plurality of height adjustment portions formed according to the heights of the semiconductor chips and the mounting positions of the semiconductor chips. Therefore, it is possible to efficiently cool the semiconductor chips without increasing the number of components.

### (2) Second Embodiment

FIG. 5 is a schematic explanatory cross-sectional view illustrating a mounting state of a cooling unit of a second embodiment.

A heat transfer member 21 of the second embodiment is formed by forging.

In the heat transfer member 21 formed by forging, a gap as an air layer is not formed unlike a case where a height adjustment portion is formed by drawing using a press machine between the heat transfer member and a cooling unit body 22 as a height adjustment portion thermally coupled to a semiconductor chip. Therefore, a thermal resistance can be reduced, and heat dissipation efficiency can be improved.

For easy understanding, FIG. 5 illustrates a case where the heat transfer member 21 is disposed only on a second surface 22SF2 of the cooling unit body 22.

A cooling unit 13 includes the heat transfer member 21 formed by forging and the cooling unit body 22.

In the example of FIG. 5, a semiconductor chip CP1 having a first height and a semiconductor chip CP2 having a second height larger than the first height are mounted on a surface of the substrate SB2.

Therefore, a height of a height adjustment portion AD1 formed in the heat transfer member 21 is smaller than a height of a height adjustment portion AD2.

In addition, a thermally conductive member TGR such as thermal grease is provided between the semiconductor chip CP1 and the height adjustment portion AD1 and between the semiconductor chip CP2 and the height adjustment portion AD2, so that the thermal resistance is reduced, and cooling efficiency is improved as compared with a case where the thermally conductive member TGR is not provided.

As a result, heat generated by operations of the semiconductor chip CP1 and the semiconductor chip CP2 is transferred to the cooling unit body 22 via the thermally conductive member TGR, a height adjustment member AD1, and a height adjustment member AD2, and heat exchange is performed with a coolant flowing in a liquid coolant flow path 31 in the cooling unit body 22.

Accordingly, the semiconductor chip CP1 and the semiconductor chip CP2 are cooled and thus can be continuously normally operated.

### (3) Third Embodiment

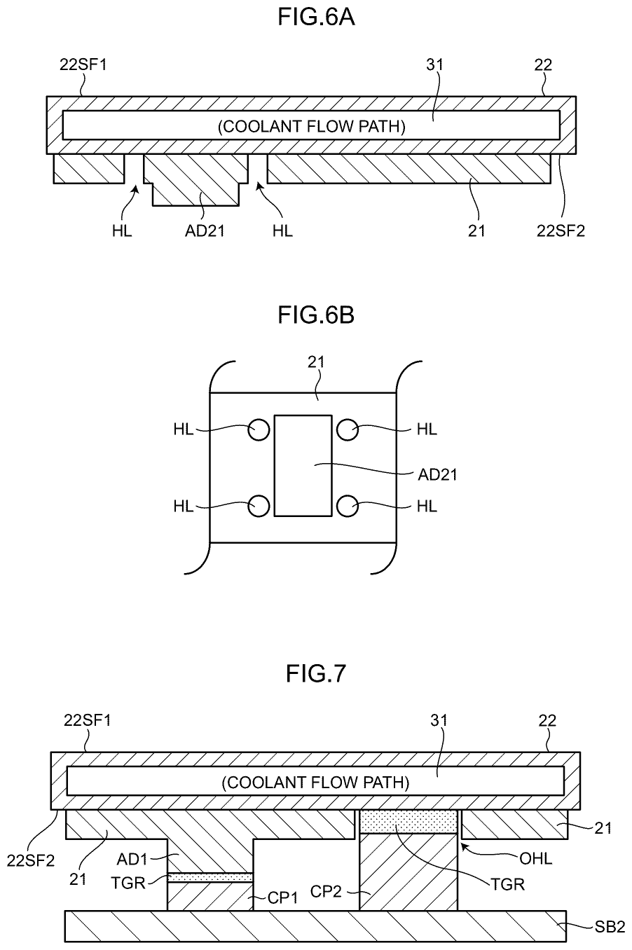

FIG. 6A is a schematic explanatory cross-sectional view illustrating a mounting state of a cooling unit of a third embodiment.

FIG. 6B is a plan view of the vicinity of a height adjustment portion AD21 when viewed from a lower side in FIG. 6A.

A heat transfer member 21 formed by forging, metal pressing, or casting is bonded to a surface (a second surface 22SF2 in the example of FIGS. 6A and 6B) of a cooling unit body 22 by so-called brazing, and thermally and physically coupled.

The heat transfer member 21 can be formed not only by forging but also by metal pressing or casting. In addition, thermal and physical coupling may be performed by soldering instead of brazing.

In this case, surfaces of the heat transfer member 21 and the cooling unit body 22 are coupled to each other with a relatively large area as illustrated in FIGS. 6A and 6B, and thus, brazing is difficult. There is a high possibility that bubbles are formed between the heat transfer member 21 and the cooling unit body 22 at the time of brazing. This also applies to soldering.

In particular, since portions where height adjustment members AD1 and AD2 are provided serve as contact surfaces for semiconductor chips CP1 and CP2, when bubbles are formed at an interface between the heat transfer member 21 and the cooling unit body 22, the presence of an air layer due to the bubbles increases a thermal resistance and reduces a heat transfer rate, and thus, cooling cannot be efficiently performed.

Therefore, it is desirable to be able to remove the bubbles particularly at portions where the height adjustment members AD1 and AD2 that are protrusions are provided.

Therefore, as illustrated in FIG. 6B, a plurality of holes HL are provided in the vicinity of the height adjustment member AD21 that is a protrusion, so that the bubbles formed at the time of brazing are released via the holes HL. As a result, the bubbles do not remain between the heat transfer member 21 and the cooling unit body 22, and a surface tension acts to achieve uniform brazing (or soldering).

Therefore, according to the third embodiment, it is possible to construct a substrate cooling system that does not reduce a heat transfer efficiency.

### (4) Fourth Embodiment

FIG. 7 is a schematic explanatory cross-sectional view illustrating a mounting state of a cooling unit of a fourth embodiment.

In each of the above embodiments, a height adjustment portion is provided for each of all cooling target semiconductor chips. However, in a case where a height of the cooling target semiconductor chip is sufficiently high, an opening OHL can be provided as the height adjustment portion, and the semiconductor chip can penetrate through the opening OHL and be thermally coupled directly to a cooling unit body 22 via a thermally conductive member TGR.

Since a heat transfer member 21 of the fourth embodiment is also formed by forging, metal pressing, or casting, a gap as an air layer is not formed unlike a case where the height adjustment portion is formed by drawing using a press machine between the heat transfer member and the cooling unit body 22. Therefore, a thermal resistance can be reduced, and heat dissipation efficiency can be improved.

FIG. 7 also illustrates a case where the heat transfer member 21 is disposed only on a second surface 22SF2 of the cooling unit body 22 for easy understanding.

A cooling unit 13 includes the heat transfer member 21 formed by forging and the cooling unit body 22.

In the example of FIG. 7, a semiconductor chip CP1 having a first height and a semiconductor chip CP2 having a second height larger than the first height are mounted on a surface of a substrate SB2.

In this case, the height of the semiconductor chip CP2 is relatively much larger than the height of the semiconductor chip CP1. Therefore, the opening OHL is provided instead of a protruding shape like a height adjustment portion AD1, and the semiconductor chip CP2 is thermally coupled directly to the second surface 22SF2 of the cooling unit body 22 via the thermally conductive member TGR such as thermal grease.

Therefore, the thermal resistance can be reliably reduced and the cooling efficiency can be improved as compared with a case where the height adjustment portion having a projection shape is provided.

As a result, as for heat generated by operations of the semiconductor chip CP1 and the semiconductor chip CP2, the heat generated by the operation of the semiconductor chip CP1 is transferred to the cooling unit body 22 via the thermally conductive member TGR and a height adjustment member AD1. On the other hand, the heat generated by the operation of the semiconductor chip CP2 is transferred to the cooling unit body 22 only via the thermally conductive member TGR.

Therefore, the semiconductor chip CP1 and the semiconductor chip CP2 have different heat exchange efficiency and are subjected to heat exchange by a coolant flowing in a liquid coolant flow path 31 in the cooling unit body 22.

As a result, the semiconductor chip CP1 and the semiconductor chip CP2 are cooled and thus can be continuously normally operated.

As described above, according to such a configuration, in particular, the thermal resistance of a thermal conduction path for the semiconductor chip CP2 corresponding to the opening OHL can be further reduced, and a cooling effect can be improved. Furthermore, a weight of the heat transfer member 21 can be reduced, and a manufacturing cost can also be reduced.

### (5) Fifth Embodiment

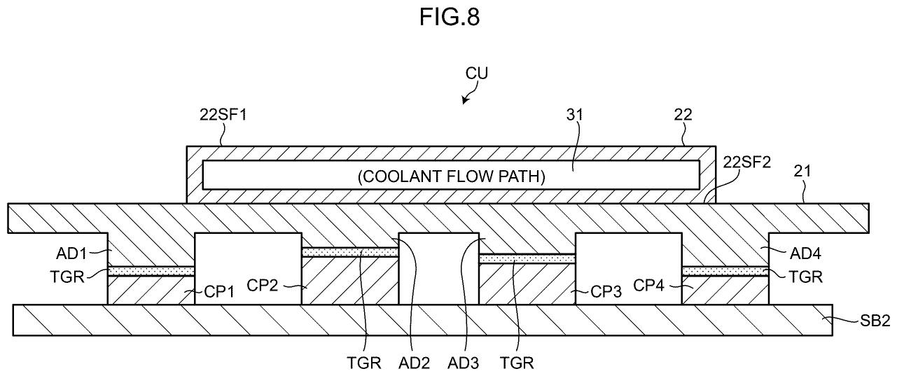

FIG. 8 is a schematic explanatory cross-sectional view illustrating a mounting state of a cooling unit of a fifth embodiment.

In each of the above embodiments, a case where a planar shape of a heat transfer member 21 is substantially the same as that of a cooling unit body 22 has been described. However, in the fifth embodiment, for example, an area of the heat transfer member 21 is larger than an area of the cooling unit body 22 in plan views of the cooling unit body 22 and the heat transfer member 21, and the stacked heat transfer member 21 is seen without being hidden by the cooling unit body 22 when viewed from above in FIG. 8.

Since the heat transfer member 21 of the fifth embodiment is also formed by forging, metal pressing, or casting, a gap as an air layer is not formed unlike a case where a height adjustment portion is formed by drawing using a press machine between the heat transfer member and the cooling unit body 22. Therefore, a thermal resistance can be reduced, and heat dissipation efficiency can be improved.

FIG. 8 also illustrates a case where the heat transfer member 21 is disposed only on a second surface 22SF2 of the cooling unit body 22 for easy understanding.

A cooling unit 13 includes the heat transfer member 21 formed by forging and the cooling unit body 22.

In the example of FIG. 8, a semiconductor chip CP1 having a first height, a semiconductor chip CP2 having a second height larger than the first height, a semiconductor chip CP3 having a third height larger than the first height and smaller than the second height, and a semiconductor chip CP4 having the same height as the first height are mounted on a surface of a substrate SB2.

In this case, the heat transfer member 21 includes a protruding height adjustment portion AD1 having a height corresponding to the height of the semiconductor chip CP1, a protruding height adjustment portion AD2 having a height corresponding to the height of the semiconductor chip CP2, a protruding height adjustment portion AD3 having a height corresponding to the height of the semiconductor chip CP3, and a protruding height adjustment portion AD4 having a height corresponding to the height of the semiconductor chip CP4.

Furthermore, the height adjustment portion AD2 and the height adjustment portion AD3, and furthermore, the semiconductor chip CP2 and the semiconductor chip CP3 are provided at positions facing the second surface 22SF2 of the cooling unit body 22, and have a positional relationship similar to that of each of the above embodiments.

On the other hand, the height adjustment portion AD1 and the height adjustment portion AD4, and furthermore, the semiconductor chip CP1 and the semiconductor chip CP4 are not provided at positions facing the second surface 22SF2 of the cooling unit body 22 except for portions thereof.

Therefore, although the thermal resistance of a heat transfer path corresponding to the height adjustment portion AD1 and the height adjustment portion AD4 is higher than that of the height adjustment portion AD2 and the height adjustment portion AD3, heat exchange can be performed by the heat transfer member 21.

Therefore, in the case of adopting such a configuration, cooling efficiency can be effectively set to a desired value by increasing a flow rate of a liquid coolant flowing in a liquid coolant flow path 31 of the cooling unit body 22 or by positioning a semiconductor chip that generates less heat as a semiconductor chip to be disposed at a location having a higher thermal resistance, such as the semiconductor chip CP1 and the semiconductor chip CP4.

According to the present embodiment, the cooling unit body can be reduced in size while increasing an actual arrangement area of a cooling target, so that a construction cost of the entire cooling system can be reduced, an installation condition of the cooling unit body 22 can be relaxed, and the cooling system can be constructed more easily.

### (6) Sixth Embodiment

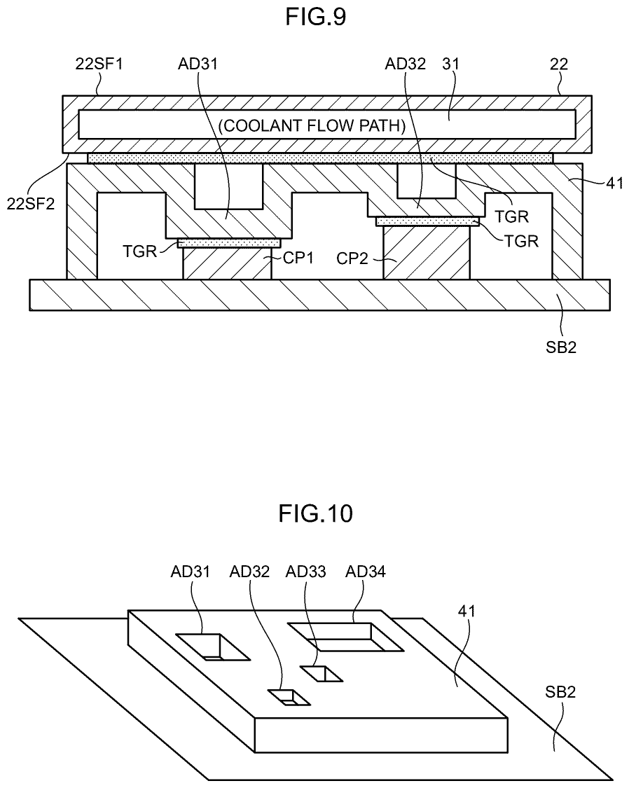

FIG. 9 is a schematic explanatory cross-sectional view illustrating a mounting state of a cooling unit of a sixth embodiment.

In each of the above embodiments, a height adjustment portion is provided in a heat transfer member 21 mechanically supported on a cooling unit body 22, but the sixth embodiment is an embodiment in which the heat transfer member is provided on a substrate on which a cooling target semiconductor chip is mounted.

Although the heat transfer member 21 of the sixth embodiment can also be formed by forging, in the example of FIG. 9, a case where the height adjustment portion is formed by drawing using a press machine is described.

FIG. 9 also illustrates a case where a heat transfer member 41 is disposed only on a second surface 22SF2 of the cooling unit body 22 for easy understanding.

As illustrated in FIG. 9, the heat transfer member 41 is supported on and fixed to a substrate SB2.

A height adjustment portion AD31 corresponding to a height of a semiconductor chip CP1 is provided at a position facing the semiconductor chip CP1 on the heat transfer member 41, and is thermally coupled to the semiconductor chip CP1 via a thermally conductive member TGR such as thermal grease.

Similarly, a height adjustment portion AD32 corresponding to a height of a semiconductor chip CP2 is provided at a position facing the semiconductor chip CP2 on the heat transfer member 41, and is thermally coupled to the semiconductor chip CP2 via the thermally conductive member TGR.

As a result, heat generated by operations of the semiconductor chip CP1 and the semiconductor chip CP2 is transferred to the cooling unit body 22 via the thermally conductive member TGR, the height adjustment portion AD31, and the height adjustment portion AD32, and heat exchange is performed with a coolant flowing in a liquid coolant flow path 31 in the cooling unit body 22.

Accordingly, the semiconductor chip CP1 and the semiconductor chip CP2 are cooled and thus can be continuously normally operated.

FIG. 10 is an external perspective view illustrating a mounting state of the heat transfer member of the sixth embodiment.

In FIG. 10, it is assumed that four cooling target semiconductor chips CP1 to CP4 are mounted on the substrate SB2.

In this case, in the heat transfer member 41, four recesses (protrusions when viewed from the semiconductor chips CP1 to CP4) corresponding to height adjustment portions AD31 to AD34 are formed.

Therefore, the semiconductor chips CP1 to CP4 on the substrate SB2 are covered with the heat transfer member 41.

With such a configuration, according to the sixth embodiment, countermeasure for dew condensation can be taken by covering the substrate SB2 with the heat transfer member 41.

In addition, it is possible to secure grounding of a large area by grounding the heat transfer member 41.

Furthermore, as the heat transfer member 41 is formed of a conductive material such as an aluminum plate, is grounded, and surrounds the entire target circuit, it is possible to provide an electrical shielding property, easily eliminate an influence of noise and the like, and achieve a highly reliable circuit operation.

### (7) Seventh Embodiment

The first to sixth embodiments describe configurations in which a height adjustment portion is provided in a heat transfer member separated from a cooling unit body 22. However, a seventh embodiment is an embodiment in which the height adjustment portion is provided in a cooling unit.

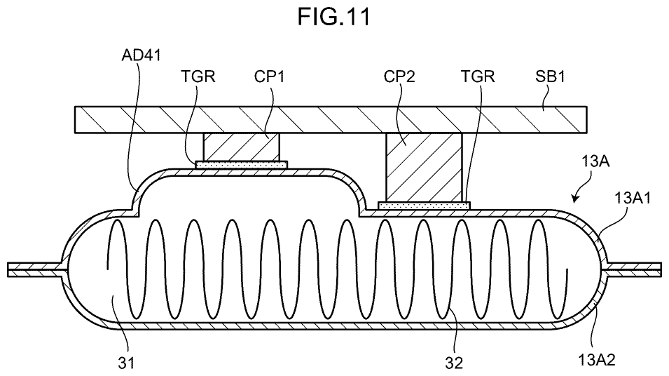

FIG. 11 is a schematic explanatory cross-sectional view illustrating a mounting state of the cooling unit of the seventh embodiment.

A cooling unit 13A of the seventh embodiment includes a first housing 13A1, a second housing 14A2, a liquid coolant flow path 31, and a fin 32.

In the first housing 13A1, a metal plate is drawn by a press device to form a part of the liquid coolant flow path and a height adjustment portion AD41.

In this case, in the example of FIG. 11, the height adjustment portion AD41 is formed of a single member as the first housing 13A1 so as to have a height corresponding to a corresponding position based on a height and disposition of a semiconductor chip CP1 mounted on a substrate SB1. The height adjustment portion AD41 is thermally coupled to the semiconductor chip CP1 via a thermally conductive member TGR such as thermal grease.

In addition, a semiconductor chip CP2 mounted on the substrate SB1 is thermally coupled to a top surface (an upper surface in FIG. 11) of the first housing 13A1 via the thermally conductive member TGR.

In the example of FIG. 11, only the height adjustment portion AD41 is illustrated as the height adjustment portion. However, in a case where a plurality of cooling target semiconductor chips are mounted on the substrate SB1, the height adjustment portions are formed as a part of the first housing 13A1 at positions corresponding to the cooling target semiconductor chips.

A second housing 13A2 is brazed to the first housing 13A1 and integrated to form the liquid coolant flow path 31.

In the example of FIG. 11, the height adjustment portion is not formed in the second housing 13A2 for easy understanding. However, in a case where the cooling target semiconductor chip is present on a second substrate SB2 positioned below the second housing 13A2, the height adjustment portion may be formed at a position corresponding to the semiconductor chip on the second substrate SB2.

With such a configuration, the semiconductor chip CP1 and the semiconductor chip CP2 are cooled by heat exchange via the thermally conductive member TGR using a coolant flowing in the liquid coolant flow path 31 from a back side to a front side in the drawing or from the front side to the back side in the drawing.

As described above, in the configuration of the seventh embodiment, the first housing 13A1 of the cooling unit 13A is configured as one member and has the height adjustment portion formed according to the height of the semiconductor chip and a mounting position of the semiconductor chip. Therefore, it is possible to efficiently cool the semiconductor chip without increasing the number of components.

### (8) Eighth Embodiment

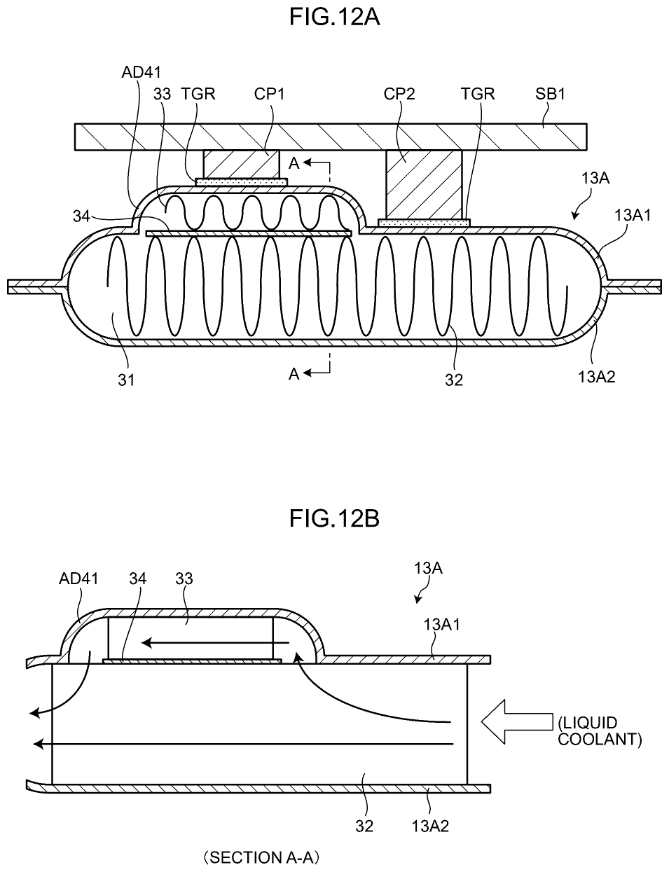

FIG. 12A is a schematic explanatory cross-sectional view illustrating a mounting state of a cooling unit of an eighth embodiment.

FIG. 12B is a cross-sectional view taken along line A-A of FIG. 12A.

In FIGS. 12A and 12B, portions similar to those of the seventh embodiment in FIG. 11 are denoted by the same reference numerals.

A cooling unit 13A of the eighth embodiment includes a first housing 13A1, a second housing 13A2, a liquid coolant flow path 31, a fin 32, a second fin 33, and a spacer 34.

In the first housing 13A1, a metal plate is drawn by a press device to form a part of the liquid coolant flow path and a height adjustment portion AD41.

Here, problems in the seventh embodiment will be described.

In the seventh embodiment, since there is a gap between an upper surface of the height adjustment portion AD41 and an upper surface of the fin 32, when a height in an up-down direction is increased, a straightening effect of the fin 32 is reduced, and there is a possibility that heat exchange efficiency is reduced. In addition, when a coolant pressure is increased, the height adjustment portion AD41 is deformed, and unnecessary stress is generated in a semiconductor chip CP1, which may lead to a decrease in reliability.

Therefore, in order to secure a pressure resistance and the straightening effect and improve the reliability of the cooling unit 13A, it is conceivable to provide the second fin 33 in the height adjustment portion AD41. However, peaks of the fins overlap each other in some shapes of the fin 32 and the second fin 33, and thus, a shape of the height adjustment portion AD41 cannot be maintained, and the straightening effect is also reduced, as a result of which the heat exchange efficiency is reduced.

Therefore, in the eighth embodiment, as illustrated in FIG. 12A, the plate-shaped spacer 34 is disposed between the fin 32 and the second fin 33, and the fin 32 and the second fin 33 are brazed to the spacer 34.

According to such a configuration, the peaks of the fin 32 and the second fin 33 do not overlap each other, and thus, the shape of the height adjustment portion AD41 can be maintained, and the straightening effect is also maintained, so that the heat exchange efficiency is not reduced.

In this case, in the example of FIG. 12A, the height adjustment portion AD41 is formed of a single member as the first housing 13A1 so as to have a height corresponding to a corresponding position based on a height and disposition of the semiconductor chip CP1 mounted on a substrate SB1. The height adjustment portion AD41 is thermally coupled to the semiconductor chip CP1 via a thermally conductive member TGR.

Similarly, a semiconductor chip CP2 mounted on the substrate SB1 is thermally coupled to a top surface (an upper surface in FIG. 12A) of the first housing 13A1 via the thermally conductive member TGR.

Also in the example of FIG. 12A, only the height adjustment portion AD41 is illustrated as the height adjustment portion. However, in a case where a plurality of cooling target semiconductor chips are mounted on the substrate SB1, the height adjustment portions are formed as a part of the first housing 13A1 at positions corresponding to the cooling target semiconductor chips.

The second housing 13A2 is brazed to the first housing 13A1 and integrated to form the liquid coolant flow path 31.

In the example of FIGS. 12A and 12B, the height adjustment portion is not formed in the second housing 13A2 for easy understanding. However, in a case where the cooling target semiconductor chip is present on a second substrate SB2 positioned below the second housing 13A2, the height adjustment portion may be formed at a position corresponding to the semiconductor chip on the second substrate SB2.

As illustrated in FIG. 12B, there is a predetermined gap between a front end (a left end in FIG. 12B) and a rear end of the second fin 33 in a fin extending direction and an inner wall surface of the height adjustment portion AD41. Therefore, a liquid coolant flowing from a rear end (a right end in FIG. 12B) of the fin 32 easily branches, is guided to the rear end of the second fin 33 as indicated by a thin arrow, is straightened through the inside of the second fin 33, is discharged from the front end of the second fin 33, and joins the liquid coolant flowing in the fin 32 again without delay to perform heat exchange.

With such a configuration, the semiconductor chip CP1 and the semiconductor chip CP2 are cooled by heat exchange with high efficiency via the thermally conductive member TGR using a coolant flowing in the liquid coolant flow path 31 from the back side to the front side in the drawing or from the front side to the back side in the drawing.

As described above, in the configuration of the eighth embodiment, the first housing 13A1 of the cooling unit 13A is configured as one member and has the height adjustment portion AD41 formed according to the height of the semiconductor chip and a mounting position of the semiconductor chip. Therefore, it is possible to efficiently cool the semiconductor chip without increasing the number of components.

In addition, since the plate-shaped spacer 34A is disposed between the fin 32 and the second fin 33, and brazing is performed, the peaks of the fin 32 and the second fin 33 do not overlap each other, and thus, the shape of the height adjustment portion AD41 can be maintained, and the straightening effect is also maintained, so that the heat exchange efficiency is not reduced.

### (9) Ninth Embodiment

In the eighth embodiment, a plate-shaped spacer 34 is disposed between a fin 32 and a second fin 33, and brazing is performed, so that the fin 32 and the second fin 33 do not overlap each other to prevent a flow of a coolant from being hindered. However, it is necessary to braze the fin 32 and the second fin 33, and a manufacturing process becomes complicated.

Therefore, in the ninth embodiment, there is provided a cooling unit that can maintain a shape of a height adjustment portion AD41 without overlapping between peaks of the fin 32 and the second fin 33 while simplifying the manufacturing process by changing a shape of the spacer.

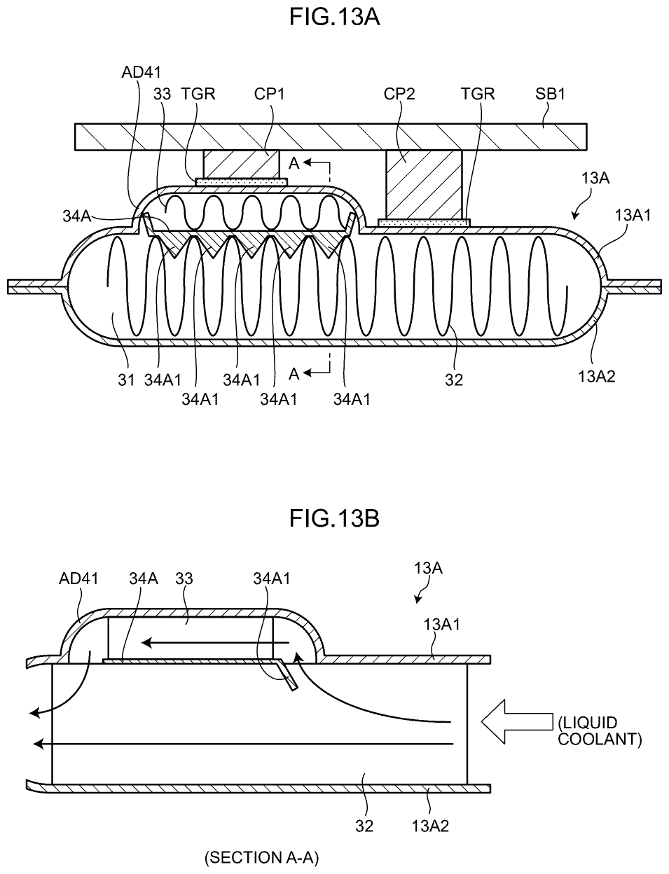

FIG. 13A is a schematic explanatory cross-sectional view illustrating a mounting state of the cooling unit of the ninth embodiment.

FIG. 13B is a cross-sectional view taken along line A-A of FIG. 13A.

In FIGS. 13A and 13B, portions similar to those of the seventh embodiment in FIG. 11 are denoted by the same reference numerals.

A cooling unit 13A of the ninth embodiment includes a first housing 13A1, a second housing 13A2, a liquid coolant flow path 31, the fin 32, the second fin 33, and a spacer 34A.

In the ninth embodiment, as illustrated in FIG. 13A, the plate-shaped spacer 34A is disposed between the fin 32 and the second fin 33, and a bent portion 34A1 having a triangular shape in a front view of the spacer 34A is disposed so as to fit into a valley portion of the fin 32.

According to such a configuration, a side of the bent portion 34A1 comes into contact with the fin 32, and as illustrated in FIG. 13A, rising portions of left and right ends of the spacer 34A come into contact with side walls of the height adjustment portion AD41, so that the spacer 34A is fixed at a predetermined position without being lifted.

As a result, an arrangement relationship between the fin 32 and the second fin 33 becomes fixed, the peaks of the fin 32 and the second fin 33 do not overlap each other, and thus, the shape of the height adjustment portion AD41 can be maintained, and a straightening effect is also maintained, so that heat exchange efficiency is not reduced.

In this case, in the example of FIG. 13A, the height adjustment portion AD41 is formed of a single member as the first housing 13A1 so as to have a height corresponding to a corresponding position based on a height and disposition of a semiconductor chip CP1 mounted on a substrate SB1. The height adjustment portion AD41 is thermally coupled to the semiconductor chip CP1 via a thermally conductive member TGR.

Similarly, a semiconductor chip CP2 mounted on the substrate SB1 is thermally coupled to a top surface (an upper surface in FIG. 13A) of the first housing 13A1 via the thermally conductive member TGR.

Also in the example of FIG. 13A, only the height adjustment portion AD41 is illustrated as the height adjustment portion. However, in a case where a plurality of cooling target semiconductor chips are mounted on the substrate SB1, the height adjustment portions are formed as a part of the first housing 13A1 at positions corresponding to the cooling target semiconductor chips.

The second housing 13A2 is brazed to the first housing 13A1 and integrated to form the liquid coolant flow path 31.

In the example of FIG. 13A, the height adjustment portion is not formed in the second housing 13A2 for easy understanding. However, in a case where the cooling target semiconductor chip is present on a second substrate SB2 positioned below the second housing 13A2, the height adjustment portion may be formed at a position corresponding to the semiconductor chip on the second substrate SB2.

As illustrated in FIG. 13B, there is a predetermined gap between a front end (a left end in FIG. 13B) and a rear end of the second fin 33 in a fin extending direction and an inner wall surface of the height adjustment portion AD41. Therefore, a liquid coolant flowing from a rear end (a right end in FIG. 13B) of the fin 32 is guided by the bent portion 34A1 and easily branches, is guided to the rear end of the second fin 33 as indicated by a thin arrow, is straightened through the inside of the second fin 33, is discharged from the front end of the second fin 33, and joins the liquid coolant flowing in the fin 32 again without delay to perform heat exchange.

With such a configuration, the semiconductor chip CP1 and the semiconductor chip CP2 are cooled by heat exchange with high efficiency via the thermally conductive member TGR using a coolant flowing in the liquid coolant flow path 31 from the back side to the front side in the drawing or from the front side to the back side in the drawing.

As described above, in the configuration of the ninth embodiment, the first housing 13A1 of the cooling unit 13A is configured as one member and has the height adjustment portion AD41 formed according to the height of the semiconductor chip and a mounting position of the semiconductor chip. Therefore, it is possible to efficiently cool the semiconductor chip without increasing the number of components.

In addition, since the plate-shaped spacer 34 is disposed between the fin 32 and the second fin 33, and brazing is performed, the peaks of the fin 32 and the second fin 33 do not overlap each other, and thus, the shape of the height adjustment portion AD41 can be maintained, and the straightening effect is also maintained, so that the heat exchange efficiency is not reduced.

### (10) Tenth Embodiment

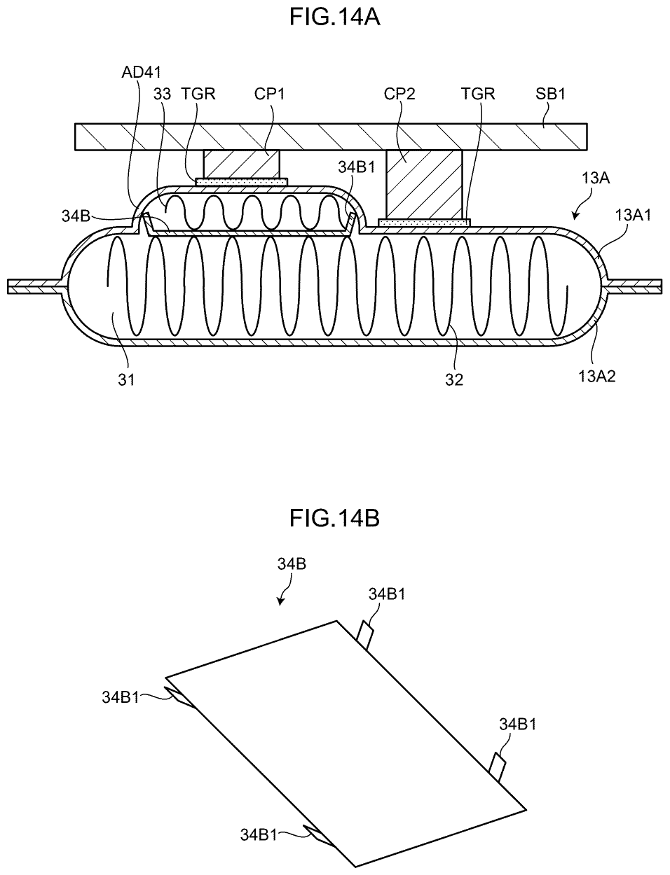

FIG. 14A is a schematic explanatory cross-sectional view illustrating a mounting state of a cooling unit of a tenth embodiment.

FIG. 14B is an external perspective view of a spacer of the tenth embodiment.

Similarly to the ninth embodiment, in the tenth embodiment, there is provided a cooling unit that can maintain a shape of a height adjustment portion AD41 without overlapping between peaks of the fin 32 and the second fin 33 while simplifying a manufacturing process by changing a shape of the spacer.

In FIGS. 14A and 14B, portions similar to those of the seventh embodiment in FIG. 11 are denoted by the same reference numerals.

A cooling unit 13A of the tenth embodiment includes a first housing 13A1, a second housing 13A2, a liquid coolant flow path 31, a fin 32, a second fin 33, and a spacer 34B.

In the tenth embodiment, as illustrated in FIG. 14A, the plate-shaped spacer 34B is disposed between the fin 32 and the second fin 33, and bent projection portions 34B1 of the spacers 34B at four positions illustrated in FIG. 14B come into contact with side walls of the height adjustment portion AD41, so that the spacer 34B is fixed at a predetermined position without being lifted.

As a result, an arrangement relationship between the fin 32 and the second fin 33 becomes fixed, the peaks of the fin 32 and the second fin 33 do not overlap each other, and thus, the shape of the height adjustment portion AD41 can be maintained, and a straightening effect is also maintained, so that heat exchange efficiency is not reduced.

In the example of FIG. 14A, the height adjustment portion is not formed in the second housing 13A2 for easy understanding. However, in a case where the cooling target semiconductor chip is present on a second substrate SB2 positioned below the second housing 13A2, the height adjustment portion may be formed at a position corresponding to the semiconductor chip on the second substrate SB2.

As described above, in the configuration of the tenth embodiment, the first housing 13A1 of the cooling unit 13A is configured as one member and has the height adjustment portion AD41 formed according to the height of the semiconductor chip and a mounting position of the semiconductor chip. Therefore, it is possible to efficiently cool the semiconductor chip without increasing the number of components.

In addition, since the plate-shaped spacer 34B is disposed between the fin 32 and the second fin 33, the peaks of the fin 32 and the second fin 33 do not overlap each other, and thus, the shape of the height adjustment portion AD41 can be maintained, and the straightening effect is also maintained, so that the heat exchange efficiency is not reduced.

### (11) Eleventh Embodiment

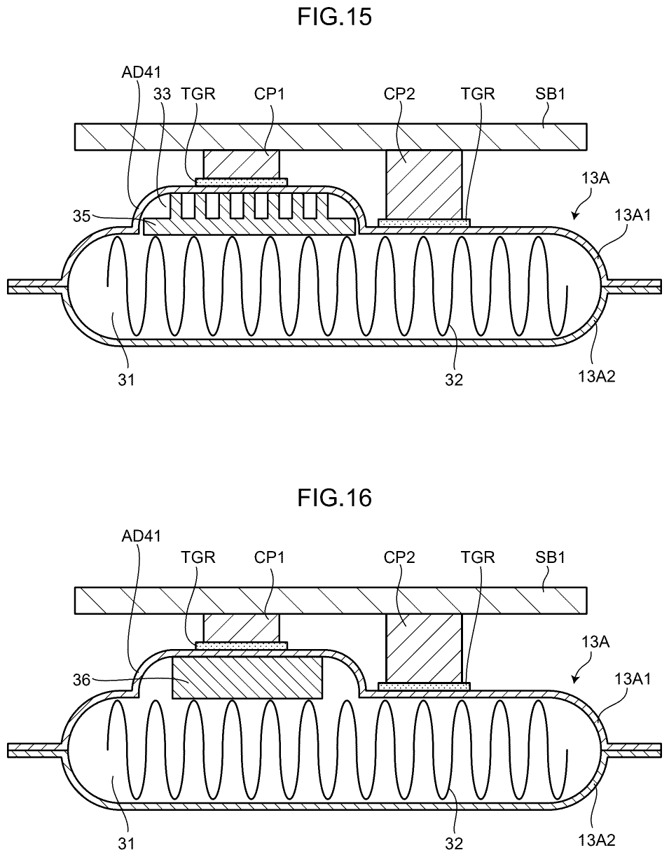

FIG. 15 is a schematic explanatory cross-sectional view illustrating a mounting state of a cooling unit of an eleventh embodiment.

In the eighth to tenth embodiments, a second fin 33 and spacers 34, 34A, and 34B are provided, but in the present eleventh embodiment, a bottom-plate-attached extrusion fin 35 is provided instead of the second fin 33 and the spacers 34, 34A, and 34B.

According to the eleventh embodiment, a first housing 13A1 of a cooling unit 13A is configured as one member and has a height adjustment portion AD41 formed according to a height of a semiconductor chip and a mounting position of the semiconductor chip. Therefore, it is possible to efficiently cool the semiconductor chip without increasing the number of components.

Furthermore, since there is no need to provide the second fin, a shape of the height adjustment portion AD41 can be maintained while simplifying a manufacturing process, and a straightening effect is also maintained, so that heat exchange efficiency is not reduced.

### (12) Twelfth Embodiment

FIG. 16 is a schematic explanatory cross-sectional view illustrating a mounting state of a cooling unit of a twelfth embodiment.

In the twelfth embodiment, a bottom-plate-attached extrusion fin 35 is provided instead of a second fin and spacers, and the twelfth embodiment is an embodiment in which a block-shaped member 36 having thermal conductivity is provided instead of the bottom-plate-attached extrusion fin 35.

According to the eleventh embodiment, a first housing 13A1 of a cooling unit 13A is configured as one member and has a height adjustment portion AD41 whose inner side is supported by the block-shaped member 36 having thermal conductivity, the height adjustment portion AD41 being formed according to a height of a semiconductor chip and a mounting position of the semiconductor chip. Therefore, it is possible to efficiently cool the semiconductor chip without increasing the number of components.

Furthermore, since there is no need to provide the second fin, a shape of the height adjustment portion AD41 can be maintained while simplifying a manufacturing process, so that heat exchange efficiency is not reduced.

### (13) Thirteenth Embodiment

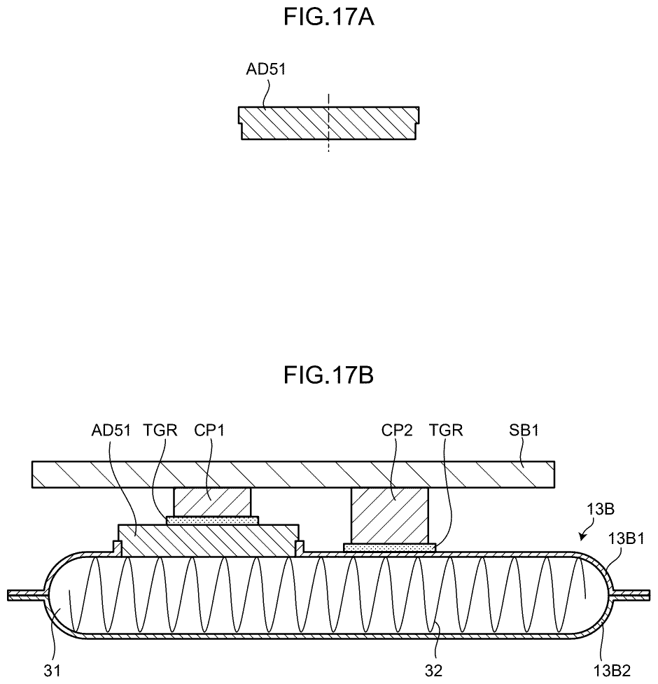

FIG. 17A is a cross-sectional view of a height adjustment portion of a thirteenth embodiment.

FIG. 17B is a schematic explanatory cross-sectional view illustrating a mounting state of a cooling unit of the thirteenth embodiment.

In the eighth to twelfth embodiments, a height adjustment portion AD41 is provided as one member in a first housing 13A1 of a cooling unit 13A. Here, a configuration in which a cylindrical burring portion is formed in the first housing 13A1, and a disk-shaped block member having thermal conductivity as a height adjustment portion AD51 illustrated in FIG. 17A is fitted into the burring portion and brazed is adopted.

With such a configuration, a semiconductor chip CP1 is cooled by heat exchange with high efficiency via the disk-shaped block member AD51 and a thermally conductive member TGR using a coolant flowing in a liquid coolant flow path 31 from the back side to the front side in the drawing or from the front side to the back side in the drawing.

Similarly, a semiconductor chip CP2 is cooled by heat exchange with high efficiency via the thermally conductive member TGR.

As described above, in the configuration of the thirteenth embodiment, the disk-shaped block member AD51 forming the height adjustment portion is provided in the burring portion of the first housing 13A1 of the cooling unit 13A. Therefore, it is possible to efficiently cool the semiconductor chip without significantly increasing the number of components.

### (14) Fourteenth Embodiment

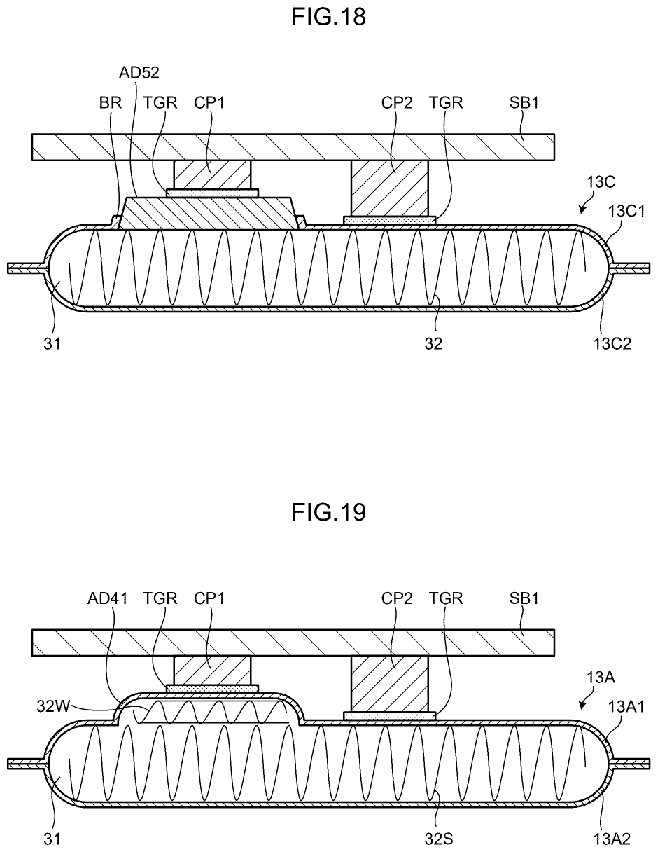

FIG. 18 is a schematic explanatory view illustrating a mounting state of a cooling unit of a fourteenth embodiment.

In the eighth to twelfth embodiments, a height adjustment portion AD41 is provided as one member in a first housing 13A1 of a cooling unit 13A. Here, a configuration in which a burring portion BR whose diameter is decreased toward an upper portion is formed in the first housing 13A1, and a truncated conical block member having thermal conductivity as a height adjustment portion AD52 illustrated in FIG. 18 is fitted into the burring portion BR from a lower side of the first housing 13A1 and brazed is adopted.

With such a configuration, a semiconductor chip CP1 is cooled by heat exchange with high efficiency via the truncated conical block member AD51 and a thermally conductive member TGR using a coolant flowing in a liquid coolant flow path 31 from the back side to the front side in the drawing or from the front side to the back side in the drawing.

Similarly, a semiconductor chip CP2 is cooled by heat exchange with high efficiency via the thermally conductive member TGR.

As described above, in the configuration of the fourteenth embodiment, the truncated conical block member AD52 forming the height adjustment portion is provided in the burring portion BR of the first housing 13A1 of the cooling unit 13A. Therefore, it is possible to efficiently cool the semiconductor chip without significantly increasing the number of components.

### (15) Fifteenth Embodiment

FIG. 19 is a schematic explanatory cross-sectional view illustrating a mounting state of a cooling unit of a fifteenth embodiment.

In FIG. 19, portions similar to those of the seventh embodiment in FIG. 11 are denoted by the same reference numerals.

In the eighth to tenth embodiments, types of a fin 32 and a second fin 33 have not been mentioned. In the fifteenth embodiment, in a case where a fin and a second fin are stacked by specifying the shapes of the fins, the second fin does not fit into the fin.

A cooling unit 13A of the fifteenth embodiment includes a first housing 13A1, a second housing 13A2, a liquid coolant flow path 31, a straight fin 32S, and a wave fin 32W.

In the first housing 13A1, a metal plate is drawn by a press device to form a part of the liquid coolant flow path and a height adjustment portion AD41.

In the fifteenth embodiment, a combination of the fins having shapes in which peak portions or valley portions of the fins do not overlap each other even when the fins are stacked is selected.

More specifically, in the example of FIG. 19, the wave fin 32W having a zigzag-shaped wave form is stacked in the height adjustment portion AD41 on the straight fin 32S having a straight shape.

In this case, in the example of FIG. 19, the height adjustment portion AD41 is formed of a single member as the first housing 13A1 so as to have a height corresponding to a corresponding position based on a height and disposition of a semiconductor chip CP1 mounted on a substrate SB1. The height adjustment portion AD41 is thermally coupled to the semiconductor chip CP1 via a thermally conductive member TGR.

Similarly, a semiconductor chip CP2 mounted on the substrate SB1 is thermally coupled to a top surface (an upper surface in FIG. 19) of the first housing 13A1 via the thermally conductive member TGR.

Also in the example of FIG. 19, only the height adjustment portion AD41 is illustrated as the height adjustment portion. However, in a case where a plurality of cooling target semiconductor chips are mounted on the substrate SB1, the height adjustment portions are formed as a part of the first housing 13A1 at positions corresponding to the cooling target semiconductor chips.

The second housing 13A2 is brazed to the first housing 13A1 and integrated to form the liquid coolant flow path 31.

Also in the example of FIG. 19, the height adjustment portion is not formed in the second housing 13A2 for easy understanding. However, in a case where the cooling target semiconductor chip is present on a second substrate SB2 positioned below the second housing 13A2, the height adjustment portion may be formed at a position corresponding to the semiconductor chip on the second substrate SB2.

As described above, in the configuration of the fifteenth embodiment, the peaks or valleys of the straight fin 32S and the wave fin 32W do not overlap each other. Therefore, a shape of the height adjustment portion AD41 can be maintained, and a straightening effect is also maintained, so that heat exchange efficiency is not reduced.

In the above description, a combination of the straight fin and the wave fin has been described as a combination of fin shapes in which peaks or valleys of the fins do not overlap each other when the fins are stacked. However, for example, the following combinations can also be applied in addition to such a combination.

(1) A combination of the wave fin and an offset fin

Here, the offset fin refers to a fin in which short straight fins are sequentially offset in a direction intersecting a flow direction of the liquid coolant.

(2) A combination of the straight fin and the offset fin.

(3) A combination of the offset fins.

### (16) Sixteenth Embodiment

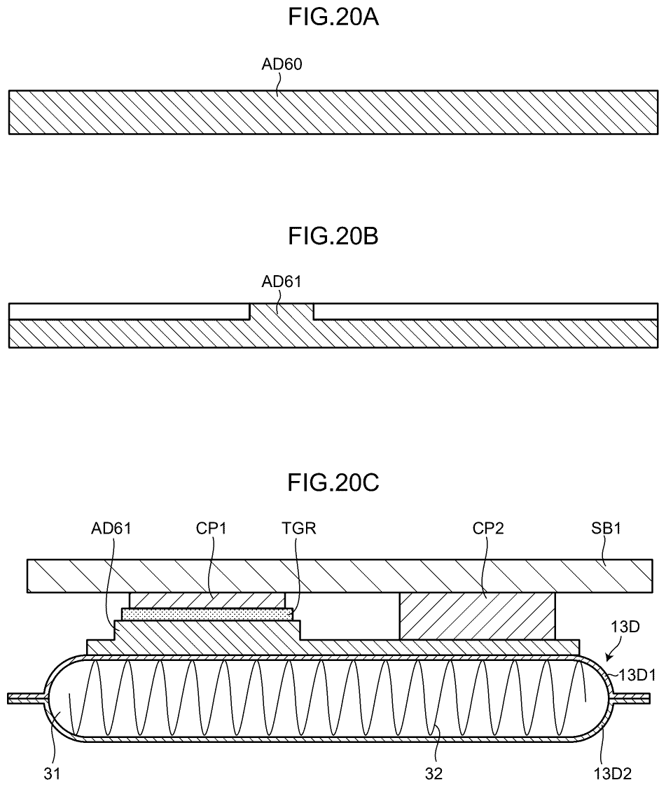

FIG. 20A is a schematic explanatory cross-sectional view of a metal thick plate used in a sixteenth embodiment.

FIG. 20B is a schematic explanatory cross-sectional view of a height adjustment member of the sixteenth embodiment.

FIG. 20C is a schematic explanatory cross-sectional view illustrating a mounting state of a cooling unit of the sixteenth embodiment.

In FIGS. 20A, 20B, and 20B, portions similar to those of the seventh embodiment in FIG. 11 are denoted by the same reference numerals.

In the sixteenth embodiment, a height adjustment portion AD61 is formed by pressing the thermally conductive metal thick plate using a press machine while leaving a portion for forming a protrusion.

Specifically, a thermally conductive metal thick plate AD60 illustrated in FIG. 20A is pressed by the press machine, and the height adjustment member AD61 is formed by pressing using the press machine while leaving a portion where the protrusion is actually formed.

According to the sixteenth embodiment, in all cases where a combination of a first housing 13D1 and a second housing 13D2 of a cooling unit 13D is the same (completely shared), only one of the first housing 13D1 and the second housing 13D2 is the same (partially shared), and the combination of the first housing 13D1 and the second housing 13D2 is completely different, since shapes of coupling surfaces of the cooling unit and the height adjustment member are standardized (the shapes need not be completely the same and are sufficient for thermal coupling), it is possible to support various substrates by forming the height adjustment member AD61 according to a mounting position and a height of a semiconductor chip on a substrate SB1 even in a case where various cooling units are used, and it is possible to efficiently cool the semiconductor chip without increasing the number of components.

Furthermore, since it is sufficient if the height adjustment member corresponding to the substrate is formed for the common combination of the first housing 13D1 and the second housing 13D2, a manufacturing process can be simplified.

### (17) Seventeenth Embodiment

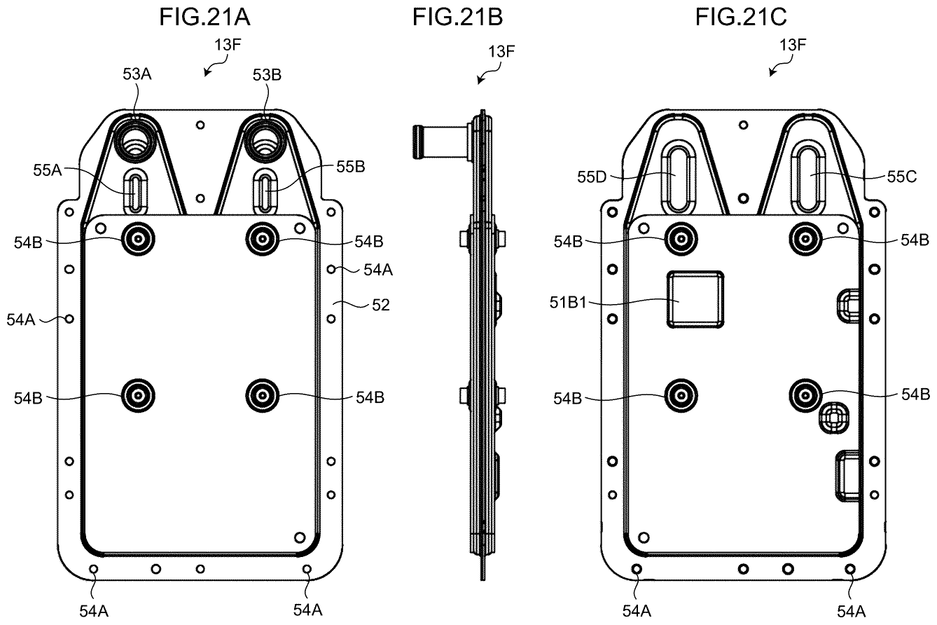

FIG. 21A is a front view of a cooling unit 13F of a seventeenth embodiment.

FIG. 21B is a (right) side view of the cooling unit 13F of the seventeenth embodiment.

FIG. 21C is a rear view of the cooling unit 13F of the seventeenth embodiment.

The cooling unit 13F includes heat transfer members 51F and 51B, a cooling unit body 52, an introduction coupler 53A, a discharge coupler 53B, a screw fastening portion 54A, studs 54B, and flow path protrusions 55A to 55D.

Each of the heat transfer members 51F and 51B is implemented by one metal plate, and in the examples of FIGS. 21A to 21C, the heat transfer member 51B is provided with a height adjustment portion 51B1 corresponding to a cooling target semiconductor chip. The height adjustment portion is provided as necessary, and one or more height adjustment portions can be provided in each of the heat transfer member 51F and the heat transfer member 51B.

In this case, a shape, a height, and a planar shape of the height adjustment portion 51B1 are determined according to a planar shape and a height of the cooling target semiconductor chip and a mounting position of the semiconductor chip.

A liquid coolant flow path is formed inside the cooling unit body 52 and the cooling unit body 52 performs heat exchange with the cooling target semiconductor chip via the heat transfer members 51F and 51B to cool the semiconductor chip.

The introduction coupler 53A is connected to a coolant cooling/circulation unit (not illustrated), and a liquid coolant is introduced into the cooling unit body 52 from the coolant cooling/circulation unit (not illustrated).

The discharge coupler 53B is connected to the coolant cooling/circulation unit (not illustrated), and the liquid coolant after the heat exchange is discharged to the coolant cooling/circulation unit (not illustrated).

The screw fastening portion 54A is formed as a through-hole, and a screw is inserted into and fastened to the through-hole. In FIGS. 21A and 21B, the screw fastening portion 54A is used to fasten a water-cooling unit together. However, the screw fastening portion 54A does not necessarily have such a function, and positioning pins may be provided in a necessary number of through-holes as necessary.

The studs 24B are provided on both of the heat transfer members 51F and 51B, and a corresponding substrate (not illustrated) is fixed and supported in a state of being separated by a predetermined distance.

Here, an internal structure of the cooling unit 13F will be described.

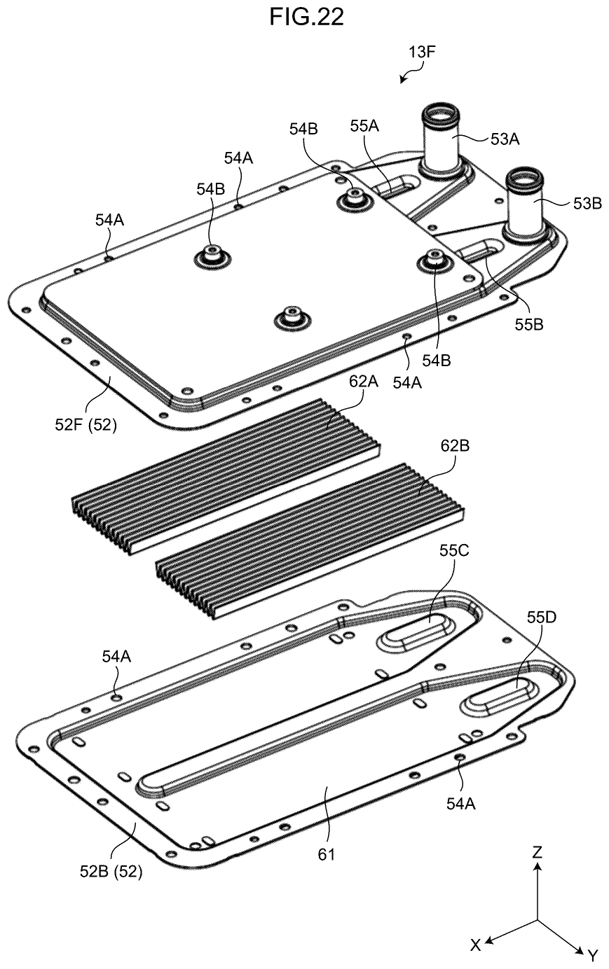

FIG. 22 is a partially exploded perspective view (part 1) of the cooling unit of the seventeenth embodiment.

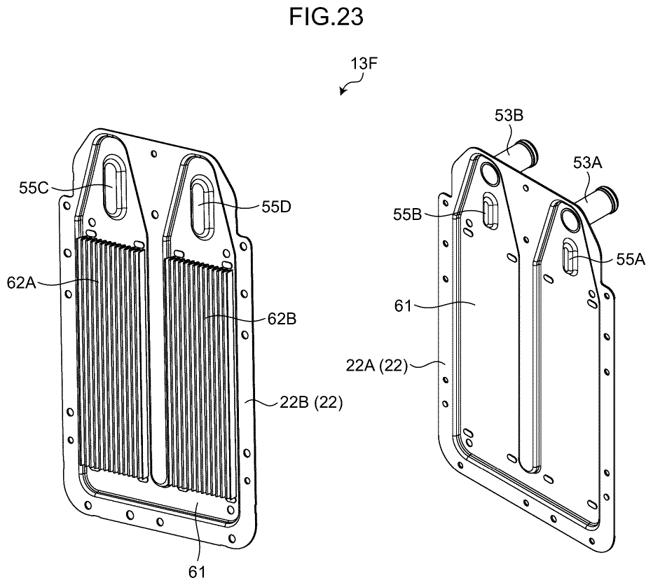

FIG. 23 is a partially exploded perspective view (part 2) of the cooling unit of the seventeenth embodiment.

A liquid coolant flow path 61 is formed inside the cooling unit body 52 of the cooling unit 13F, and two fins (straightening plates) 62A and 63B for straightening a flow of the liquid coolant are disposed in the liquid coolant flow path 61 having a U shape in plan view.

The cooling unit body 52 further includes a first cooling unit body portion 52F provided with the introduction coupler 53A and the discharge coupler 53B, and a second cooling unit body portion 52B provided to face the first cooling unit body portion 52F and cooperatively forming the liquid coolant flow path 61.

Here, the first cooling unit body portion 52F and the second cooling unit body portion 52B are bonded by brazing, welding, or the like.

The first cooling unit body portion 52F is provided such that the elliptical track-shaped flow path protrusion 55A protruding in the liquid coolant flow path 61 in plan view extends in an X-axis direction in FIG. 22 in the vicinity of the introduction coupler 53A.

Similarly, the first cooling unit body portion 52F is provided such that the elliptical track-shaped flow path protrusion 55B protruding in the liquid coolant flow path 61 in plan view extends in the X-axis direction in FIG. 22 in the vicinity of the discharge coupler 53B.

The second cooling unit body portion 52B is provided such that the elliptical track-shaped flow path protrusion 55C protruding in the liquid coolant flow path 61 in plan view extends in the X-axis direction in FIG. 22 in the vicinity of a position partially facing the introduction coupler 53A.

Similarly, the second cooling unit body portion 52B is provided such that the elliptical track-shaped flow path protrusion 55D protruding in the liquid coolant flow path 61 in plan view extends in the X-axis direction in FIG. 22 in the vicinity of a position partially facing the discharge coupler 53B.

In the above configuration, it is assumed that lengths of the flow path protrusion 55A and the flow path protrusion 55B in the X-axis direction are the same as each other, and lengths of the flow path protrusion 55C and the flow path protrusion 55D in the X-axis direction are the same as each other.

Furthermore, the lengths of the flow path protrusion 55C and the flow path protrusion 55D in the X-axis direction are larger than the lengths of the flow path protrusion 55A and the flow path protrusion 55B in the X-axis direction.

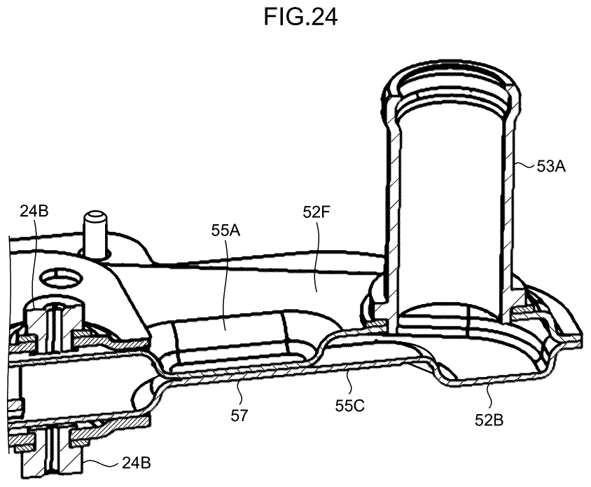

FIG. 24 is a partially enlarged cross-sectional perspective view of the cooling unit of the seventeenth embodiment.

As illustrated in FIG. 24, the flow path protrusion 55A and the flow path protrusion 55C are bonded by brazing, welding, or the like on surfaces facing each other to form a bonding portion 57.

Similarly, the flow path protrusion 55B and the flow path protrusion 55D are bonded by welding or the like on surfaces facing each other to form a bonding portion.

The reason why the flow path protrusion 55A and the flow path protrusion 55C are bonded and the flow path protrusion 55B and the flow path protrusion 55D are bonded in this manner is to ensure strengths of the first cooling unit body portion 52F and the second cooling unit body portion 52B and prevent the cooling unit body 52 from being deformed by a liquid coolant pressure.

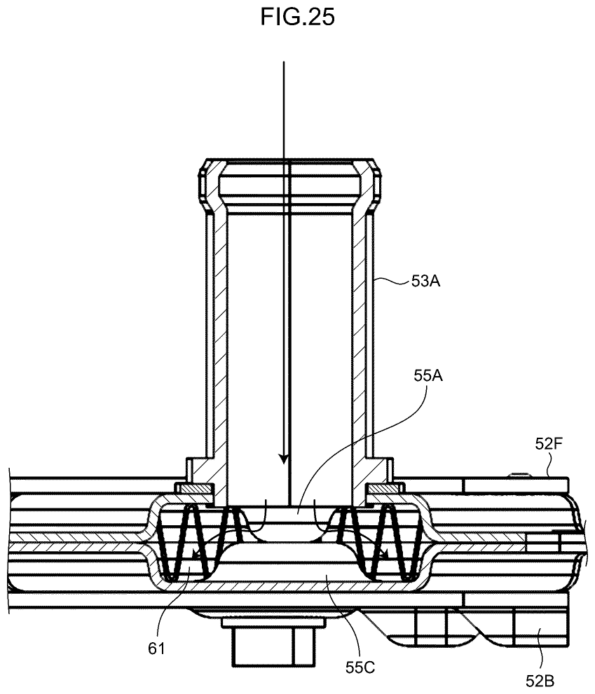

FIG. 25 is an explanatory view of a flow of the liquid coolant in the cooling unit of the seventeenth embodiment.

As a result, when the liquid coolant is introduced into the liquid coolant flow path 61 from the introduction coupler 53A, the flow of the liquid coolant is diffused and uniformly expanded in a width direction of the fin 62A, that is, in a Y-axis direction in FIG. 22 as indicated by arrows in FIG. 25 to make a flow velocity of the liquid coolant uniform, thereby improving heat exchange efficiency.

When the liquid coolant is discharged from the liquid coolant flow path 61 to the discharge coupler 53B, a swirl is generated to discharge the liquid coolant more quickly, thereby suppressing an increase in flow path resistance.

In the above description, a case where the flow path protrusions 55A to 55D have track shapes in plan view has been described, but the shapes of the flow path protrusions are not limited thereto.

In the above description, a case where the lengths of the flow path protrusion 55C and the flow path protrusion 55D are larger than the lengths of the flow path protrusion 55A and the flow path protrusion 55B has been described, but the lengths of the flow path protrusions may be the same.

A more specific description will be given below.

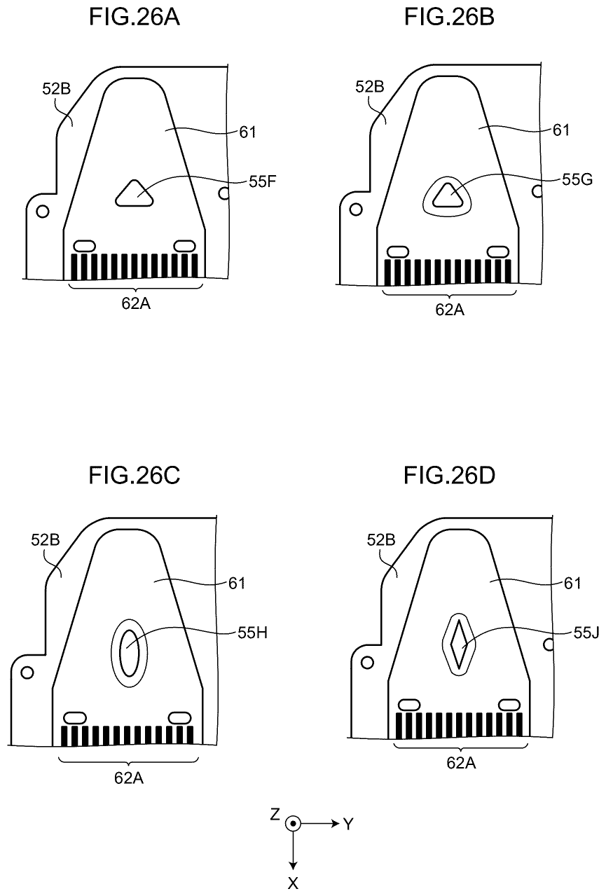

FIGS. 26A to 26D are explanatory views of other shape examples of the flow path protrusion.

In FIGS. 26A to 26D, for easy understanding, only the flow path protrusion formed adjacent to the fin 62A on the second cooling unit body portion 52B is illustrated.

FIG. 26A is a plan view of a flow path protrusion 55F as another shape example of the flow path protrusion.

The flow path protrusion 55F protrudes in the liquid coolant flow path 61, has a triangular shape in plan view, and is disposed such that one vertex portion faces an upstream side.

As a result, the liquid coolant introduced from the introduction coupler 53A (not illustrated) is diffused by the flow path protrusion 55F toward the fin 62A.

In this case, a flow path protrusion protruding on the first cooling unit body portion 52F may have the same shape as the flow path protrusion 55F, and can have a shape elongated in the X-axis direction or a shape shortened in the X-axis direction as illustrated in FIG. 22. In short, it is sufficient if the flow path protrusion is formed so as to achieve a desired diffusion state.

Even in this case, the flow path protrusion 55F and the flow path protrusion protruding on the first cooling unit body portion 52F are bonded by brazing, welding, or the like, so that the strength can be secured and deformation of the cooling unit body 52 can be suppressed.

FIG. 26B is a plan view of a flow path protrusion 55G as another shape example of the flow path protrusion.

The flow path protrusion 55G protrudes in the liquid coolant flow path 61, has a rounded triangle shape in plan view, and is disposed such that one vertex portion faces the upstream side.

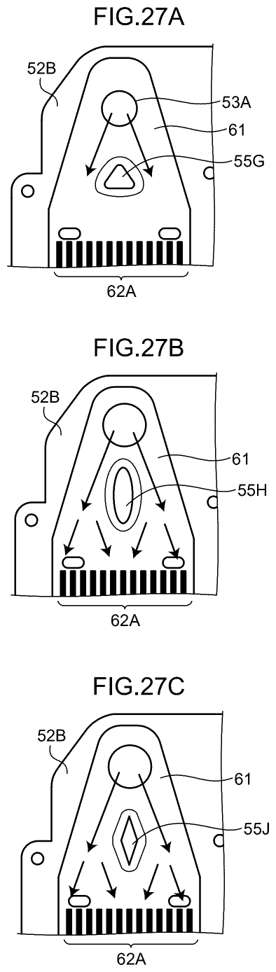

FIG. 27A is an explanatory view (part 1) of a flow of the liquid coolant on an introduction side.

As a result, the liquid coolant introduced from the introduction coupler 53A is diffused along the flow path protrusion 55G toward the fin 62A as indicated by arrows in FIG. 27A.

In this case, a flow path protrusion protruding on the first cooling unit body portion 52F may have the same shape as the flow path protrusion 55G, and can have a shape elongated in the X-axis direction or a shape shortened in the X-axis direction as illustrated in FIG. 22. In short, it is sufficient if the flow path protrusion is formed so as to achieve a desired diffusion state.

Even in this case, the flow path protrusion 55G and the flow path protrusion protruding on the first cooling unit body portion 52F are bonded by brazing, welding, or the like.

FIG. 26C is a plan view of a flow path protrusion 55H as another shape example of the flow path protrusion.

The flow path protrusion 55H protrudes in the liquid coolant flow path 61, has an elliptical shape in plan view, and is disposed such that a longitudinal direction thereof is along a direction from the upstream side to a downstream side.

FIG. 27B is an explanatory view (part 2) of a flow of the liquid coolant on the introduction side.

As a result, the liquid coolant introduced from the introduction coupler 53A is diffused by the flow path protrusion 55H, and a part of the liquid coolant joins again to flow toward the fin 62A as indicated by arrows in FIG. 27B.

In this case, a flow path protrusion protruding on the first cooling unit body portion 52F may have the same shape as the flow path protrusion 55H, and can have a shape elongated in the X-axis direction or a shape shortened in the X-axis direction as illustrated in FIG. 22. In short, it is sufficient if the flow path protrusion is formed so as to achieve a desired diffusion state.

Even in these cases, the flow path protrusion 55H and the flow path protrusion protruding on the first cooling unit body portion 52F are bonded by brazing, welding, or the like.

FIG. 26D is a plan view of a flow path protrusion 55J as another shape example of the flow path protrusion.

The flow path protrusion 55J protrudes in the liquid coolant flow path 61, has a rounded rhombus shape in plan view, and is disposed such that one vertex portion in the longitudinal direction faces the upstream side.

FIG. 27C is an explanatory view (part 3) of a flow of the liquid coolant on the introduction side.

As a result, the liquid coolant introduced from the introduction coupler 53A is diffused by the flow path protrusion 55J, and a part of the liquid coolant joins again to flow toward the fin 62A as indicated by arrows in FIG. 27C.

In this case, a flow path protrusion protruding on the first cooling unit body portion 52F may have the same shape as the flow path protrusion 55J, and can have a shape elongated in the X-axis direction or a shape shortened in the X-axis direction as illustrated in FIG. 22. In short, it is sufficient if the flow path protrusion is formed so as to achieve a desired diffusion state.

Even in these cases, the flow path protrusion 55J and the flow path protrusion protruding on the first cooling unit body portion 52F are bonded by brazing, welding, or the like.

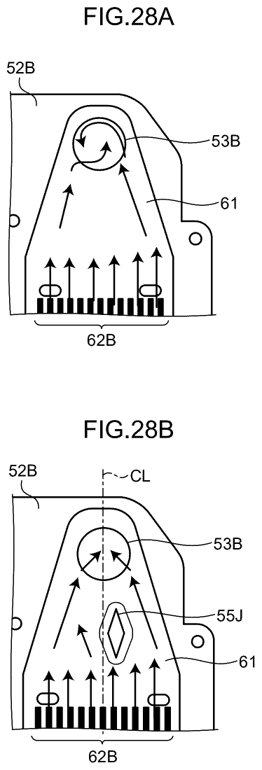

FIG. 28A is an explanatory view illustrating a case where distribution of a flow of the liquid coolant is uneven on a discharge side.

In a case where the distribution of the flow of the liquid coolant is uneven, as illustrated in FIG. 28A, a vortex is generated in the liquid coolant discharged from the discharge coupler 53B, an effective discharge speed is decreased, and the heat exchange efficiency is decreased.

FIG. 28B is an explanatory view illustrating a case where an installation position of the flow path protrusion is shifted to suppress unevenness of the distribution of the flow of the liquid coolant when the distribution of the flow of the liquid coolant is uneven on the discharge side.

When the distribution of the flow of the liquid coolant is uneven, as illustrated in FIG. 28B, for example, the flow path protrusion (the flow path protrusion 55J in the example of FIG. 28B) is disposed on a side where the liquid coolant flows more (a right side in FIG. 28B) instead of the center of the liquid coolant flow path 61 (indicated by a one-dot chain line CL in FIG. 28B), so that the distribution of the flow of the liquid coolant is made uniform, and the liquid coolant is smoothly discharged without generating a vortex when discharged from the discharge coupler 53B.

As a result, it is possible to suppress a decrease in effective discharge speed and to maintain the heat exchange efficiency at a predetermined value.

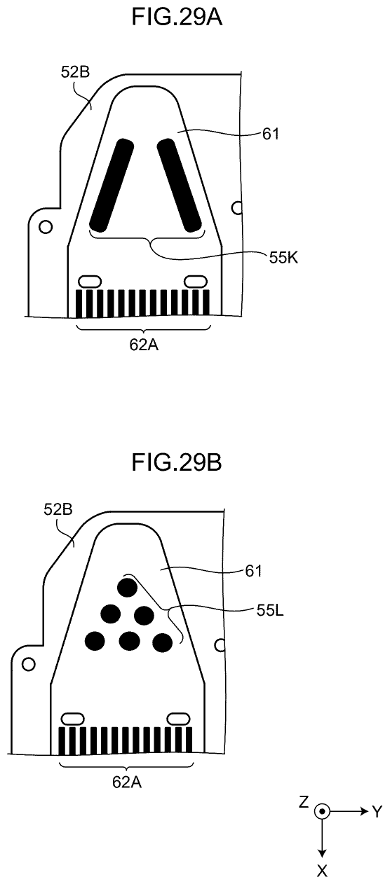

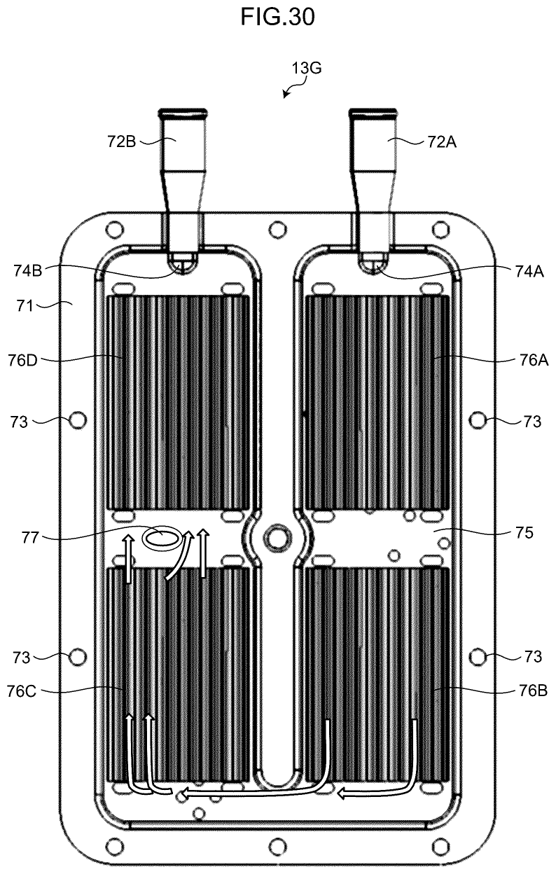

FIGS. 29A and 29B are explanatory views of other shape examples of the flow path protrusion.

Also in FIGS. 29A and 29B, for easy understanding, only the flow path protrusion formed adjacent to the fin 62A on the second cooling unit body portion 52B is illustrated.

The flow path protrusions in FIGS. 29A and 29B are different from the flow path protrusions in FIGS. 26A to 26D in that a plurality of protrusions are combined to form the flow path protrusion.

FIG. 29A is a plan view of a flow path protrusion 55K as another shape example.

The flow path protrusion 55K is disposed such that a pair of rod-shaped projections protruding in the liquid coolant flow path 61 forms an inverted V shape and face the upstream side.

As a result, when the liquid coolant introduced from the introduction coupler 53A (not illustrated) passes near the flow path protrusion 55K, the flow path resistance is gradually decreased, and the liquid coolant is diffused toward the fin 62A.

In this case, a flow path protrusion protruding on the first cooling unit body portion 52F may have the same shape as the flow path protrusion 55K, and can have a shape elongated in the X-axis direction or a shape shortened in the X-axis direction as illustrated in FIG. 22. In short, it is sufficient if the flow path protrusion is formed so as to achieve a desired diffusion state.

Even in this case, the flow path protrusion 55F and the flow path protrusion protruding on the first cooling unit body portion 52F are bonded by brazing, welding, or the like, so that the strength can be secured and deformation of the cooling unit body 52 can be suppressed.

FIG. 29B is a plan view of a flow path protrusion 55L as another shape example.

The flow path protrusion 55L is disposed such that pins on a plurality of cylinders protruding in the liquid coolant flow path 61 are arranged in a triangular shape in plan view, and one vertex portion of the triangular shape faces the upstream side.

As a result, the liquid coolant introduced from the introduction coupler 53A (not illustrated) is gradually diffused by the plurality of pins forming the flow path protrusion 55L toward the fin 62A.

In this case, a flow path protrusion protruding on the first cooling unit body portion 52F may have the same shape as the flow path protrusion 55L, and can have a shape in which a diameter of each pin is increased as illustrated in FIG. 22 or a shape in which the diameter of each pin is decreased. In short, it is sufficient if the flow path protrusion is formed so as to achieve a desired diffusion state.

Even in this case, the flow path protrusion 55L and the flow path protrusion protruding on the first cooling unit body portion 52F are bonded by brazing, welding, or the like.

As described above, according to the seventeenth embodiment, it is possible to suppress a decrease in effective discharge speed of the liquid coolant, and eventually, it is possible to maintain the heat exchange efficiency at a predetermined value, and it is possible to increase a mounting density of the components or reduce the size of the device.

Further, it is possible to suppress variations in heat exchange efficiency (heat dissipation efficiency) due to variations in flow velocity at locations in the liquid coolant flow path, thereby achieving uniform cooling efficiency and high efficiency.

Further, by bonding the flow path protrusion protruding on the first cooling unit body portion 52F and the flow path protrusion protruding on the second cooling unit body portion 52B by brazing, welding, or the like, it is possible to improve a mechanical strength, improve resistance to the liquid coolant pressure, suppress deformation of the cooling unit body portion, and suppress unnecessary stress application to a cooling target component.

Furthermore, since a pressure loss can be reduced and an output of a pump or the like for circulating the liquid coolant can be maintained low, power consumption can be reduced and the device can be downsized.

In the above description, the flow path protrusions having the same shape are provided on the introduction side for the liquid coolant (the introduction coupler 53A) and the discharge side for the liquid coolant (the discharge coupler 53B). The flow path protrusion having a shape that prioritizes suppression of the variations in flow velocity depending on locations in the liquid coolant flow path and achievement of uniformity can be provided on the introduction side for the liquid coolant, and the flow path protrusion having a shape that prioritizes reduction of a pressure loss and maintaining of a high discharge speed while securing a strength for suppressing deformation of the cooling unit body portion can be provided on the discharge side of the liquid coolant.

If there is no problem from the viewpoint of the coolant pressure or the strength of the cooling unit body portion (pressure resistance performance during pressurization or depressurization), a configuration in which the flow path protrusion is not provided on the discharge side can be adopted.

### (18) Eighteenth Embodiment

FIG. 30 is an internal explanatory view of a cooling unit of an eighteenth embodiment.

A cooling unit 13G includes a cooling unit body 71, an introduction coupler 72A, a discharge coupler 72B, a screw fastening portion 73A, and flow path protrusions 74A and 74B.

The introduction coupler 72A is connected to a coolant cooling/circulation unit (not illustrated), and a liquid coolant is introduced into the cooling unit body 71 from the coolant cooling/circulation unit (not illustrated).

The discharge coupler 72B is connected to the coolant cooling/circulation unit (not illustrated), and the liquid coolant after the heat exchange is discharged to the coolant cooling/circulation unit (not illustrated).

The screw fastening portion 73A is formed as a through-hole, and a screw is inserted into and fastened to the through-hole. In FIG. 30, the screw fastening portion 73A is used to fasten a water-cooling unit together. However, the screw fastening portion 73A does not necessarily have such a function, and positioning pins may be provided in a necessary number of through-holes as necessary.

A liquid coolant flow path 75 is formed inside the cooling unit body 71 of the cooling unit 13G, and four fins (straightening plates) 76A to 76D for straightening a flow of the liquid coolant and a flow path protrusion 77 are disposed in the liquid coolant flow path 75 having a U shape in plan view.

As illustrated in FIG. 30, in the U-shaped liquid coolant flow path 75, the liquid coolant introduced from the introduction coupler 72A passes through the fin 76A and the fin 76B in a state of being diffused by the flow path protrusion 74A, and turns in a U shape toward the discharge coupler 72B.

When the liquid coolant turns in a U-shape in this manner, distribution of a flow of the liquid coolant becomes biased toward the outside of the liquid coolant flow path 75 (a left side of the fin 76C and the fin 76D in the example of FIG. 30).

Therefore, in the eighteenth embodiment, by providing the flow path protrusion 77 at a location to which distribution of a flow of the liquid coolant between the fin 76C and the fin 76D is biased as illustrated in FIG. 30, the flow of the liquid coolant is forcibly diffused and returned to a side where the less liquid coolant flows, so that the flow introduced into the fin 76D becomes less biased again and flows toward the discharge coupler 72B as indicated by arrows in FIG. 30.

As described above, by providing the flow path protrusion 77, the distribution of the flow of the liquid coolant is made uniform, and the liquid coolant discharged from the discharge coupler 72B is smoothly discharged.

As a result, it is possible to suppress a decrease in effective discharge speed and to maintain the heat exchange efficiency at a predetermined value.

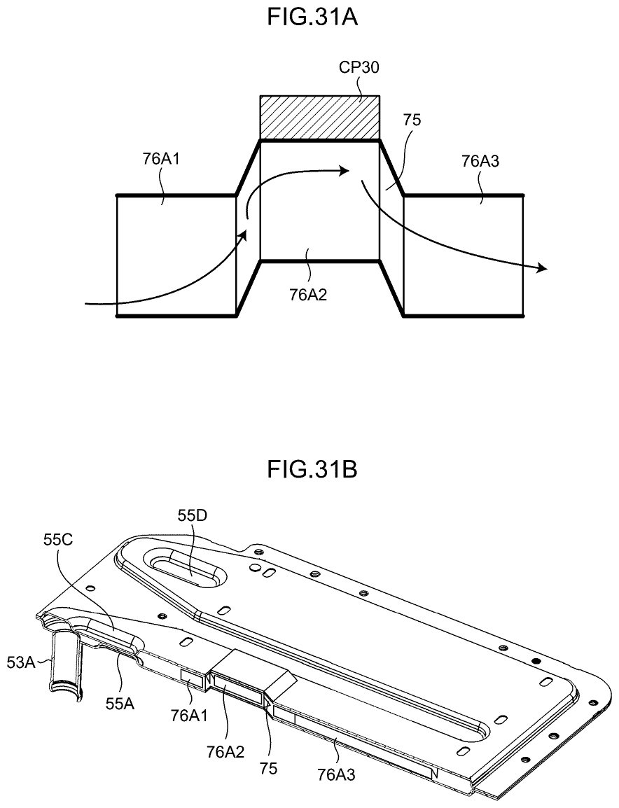

FIGS. 31A and 31B are explanatory views of a modified example of the eighteenth embodiment.

FIG. 31A is a partial cross-sectional view of a liquid coolant flow path of the modified example of the eighteenth embodiment.

FIG. 31B is a cross-sectional view of the liquid coolant flow path of the modified example of the eighteenth embodiment.

For example, in the eighteenth embodiment, in a case where a semiconductor chip CP30 whose height needs to be adjusted at a portion corresponding to the fin 76A is mounted on a substrate (not illustrated) positioned above in FIGS. 31A and 31B, the liquid coolant flow path is bent upward in a zigzag shape without providing a height adjustment portion, so that the height in the liquid coolant flow path 75 becomes uniform.

By forming the fin 76A further using three fins 76A1 to 76A3 having the same height, the cooling unit body 71 can be brought into direct contact with the semiconductor chip CP30, and the semiconductor chip CP30 can be cooled more efficiently.

In the above description, the modified example of the eighteenth embodiment has been described, but such a modified example can be similarly applied to other embodiments.

As described above, the fins having the same height can be used as the fin, and thus, it is possible to reduce a manufacturing cost and perform highly efficient cooling as compared with a case where the height of the liquid coolant flow path is partially changed and fins having different heights are used.

### (19) Nineteenth Embodiment

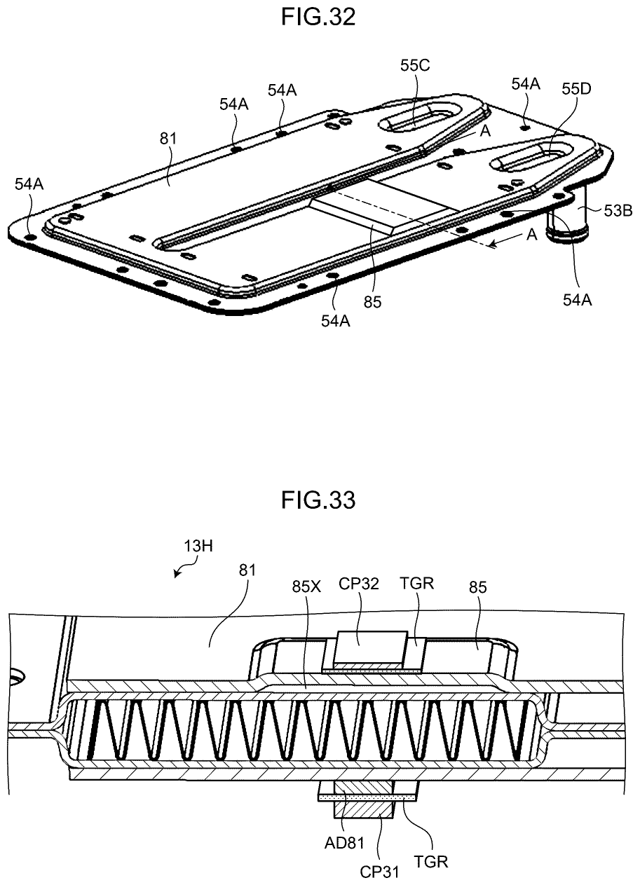

FIG. 32 is an external perspective view of a cooling unit of a nineteenth embodiment when viewed from a rear side.

In FIG. 32, portions similar to those in FIGS. 21A and 21B are denoted by the same reference numerals.

A cooling unit 13H includes a cooling unit body 81, an introduction coupler 53A, a screw fastening portion 54A, and flow path protrusions 55C and 55D.

In this case, a heat insulating protrusion 85 is provided in a flow path on a side of the discharge coupler 53B on a rear side of the cooling unit body 81.

Here, the reason why the heat insulating protrusion 85 is provided will be described.

In a case where a semiconductor chip CP31 and a semiconductor chip CP32 are disposed without providing the heat insulating protrusion 85, there is a possibility that heat transferred from the semiconductor chip CP31 to a liquid coolant via a thermally conductive member TGR and a height adjustment portion AD81 and heat transferred from the semiconductor chip CP32 to the liquid coolant via the thermally conductive member TGR interfere with each other and cooling is not performed normally.

Therefore, in the nineteenth embodiment, the heat insulating protrusion 85 is provided, a space through which the liquid coolant can pass is provided below the heat insulating protrusion, and heat transferred from the semiconductor chip to the liquid coolant via the thermally conductive member is immediately moved by causing the liquid coolant to flow in a space 85X to prevent thermal interference from occurring.

As a result, in the configuration of the nineteenth embodiment, even the liquid coolant immediately before being discharged can be cooled with high efficiency, and a highly reliable device can be implemented.

### (20) Twentieth Embodiment

FIG. 33 is an explanatory view of a twentieth embodiment.

As illustrated in FIG. 33, it is assumed that a semiconductor chip CP31 and a semiconductor chip CP32, which are cooling target heat sources, are positioned at positions facing each other with a cooling unit body 81 interposed therebetween.

In such a situation, in a case where the semiconductor chip CP31 and the semiconductor chip CP32 are disposed without providing a heat insulating protrusion 85, there is a possibility that heat transferred from the semiconductor chip CP31 to a liquid coolant via a thermally conductive member TGR and a height adjustment portion AD81 and heat transferred from the semiconductor chip CP32 to the liquid coolant via the thermally conductive member TGR interfere with each other and cooling is not performed normally.

Therefore, in the twentieth embodiment, the heat insulating protrusion 85 is provided, a space 85X through which the liquid coolant can pass is provided below the heat insulating protrusion 85, and heat transferred from the semiconductor chip CP32 to the liquid coolant via the thermally conductive member TGR is immediately moved by causing the liquid coolant to flow in the space 85X to prevent thermal interference from occurring.

As a result, in the configuration of the twentieth embodiment, even when there are heat sources at positions facing each other via a cooling unit 13H, cooling can be performed with high efficiency, and a highly reliable device can be implemented.

### (21) Twenty-First Embodiment

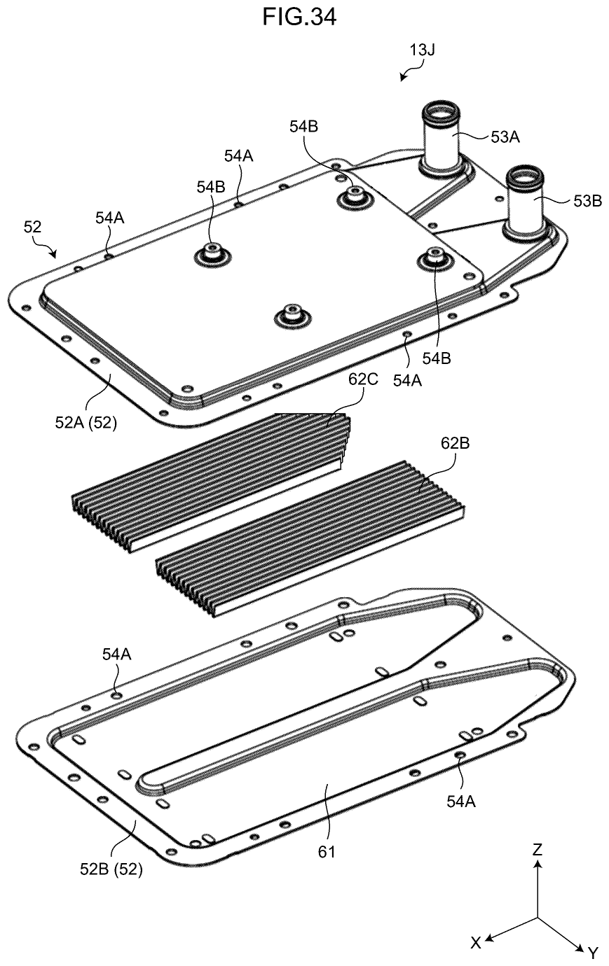

FIG. 34 is a partially exploded perspective view of a cooling unit of a twenty-first embodiment.

In FIG. 34, portions similar to those of the cooling unit of the seventeenth embodiment in FIG. 23 are denoted by the same reference numerals.

A liquid coolant flow path 61 is formed inside a cooling unit body 52 of a cooling unit 13J, and two fins (straightening plates) 62C and 62B for straightening a flow of a liquid coolant are disposed in the liquid coolant flow path 61 having a U shape in plan view.

The cooling unit body 52 further includes a first cooling unit body portion 52A provided with an introduction coupler 53A and a discharge coupler 53B, and a second cooling unit body portion 52B provided to face the first cooling unit body portion 52A and cooperatively forming the liquid coolant flow path 61.

Here, the first cooling unit body portion 52A and the second cooling unit body portion 52B are bonded by brazing, welding, or the like.

The first cooling unit body portion 52A is provided such that an elliptical track-shaped flow path protrusion 55A protruding in the liquid coolant flow path 61 in plan view extends in the X-axis direction in FIG. 22 in the vicinity of the introduction coupler 53A.

Similarly, the first cooling unit body portion 52A is provided such that an elliptical track-shaped flow path protrusion 55B protruding in the liquid coolant flow path 61 in plan view extends in the X-axis direction in FIG. 22 in the vicinity of the discharge coupler 53B.

The second cooling unit body portion 52B is provided such that an elliptical track-shaped flow path protrusion 55C protruding in the liquid coolant flow path 61 in plan view extends in the X-axis direction in FIG. 22 in the vicinity of a position partially facing the introduction coupler 53A.

Similarly, the second cooling unit body portion 52B is provided such that an elliptical track-shaped flow path protrusion 55D protruding in the liquid coolant flow path 61 in plan view extends in the X-axis direction in FIG. 22 in the vicinity of a position partially facing the discharge coupler 53B.

In the above configuration, unlike the fin 62B, a tip of the fin 62C that is adjacent to the introduction coupler 53A is cut obliquely.

This is because the liquid coolant supplied from the introduction coupler 53A has a high flow velocity at a central portion and thus increases a flow path resistance, and has a low flow velocity at both end portions and thus decreases the flow path resistance, thereby achieving a uniform flow as a whole.

As a result, by providing the fin 62C whose tip is obliquely cut, a distribution of the flow of the liquid coolant is made uniform, and the liquid coolant discharged from the discharge coupler 72B is smoothly discharged, so that it is possible to suppress a decrease in effective discharge speed and to maintain heat exchange efficiency at a predetermined value.

### (22) Twenty-Second Embodiment

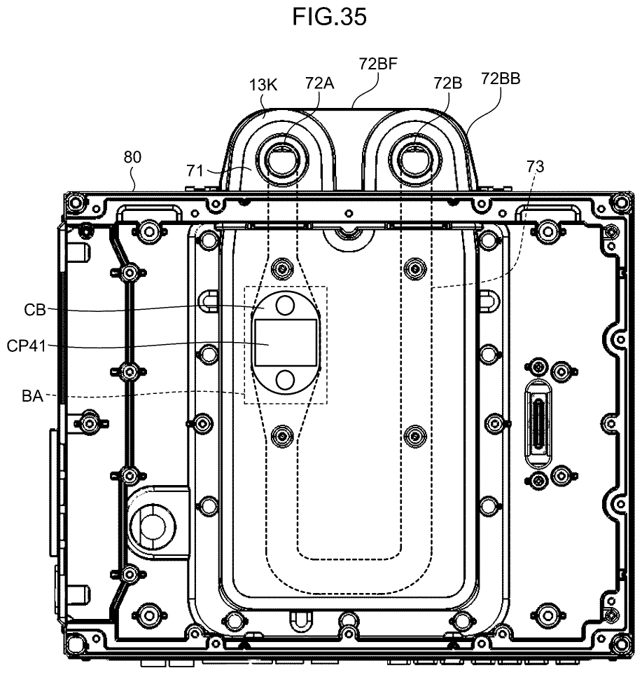

FIG. 35 is a plan view of a cooling unit of a twenty-second embodiment.

FIG. 35 illustrates a state in which a cooling unit 13K is housed in a casing 80.

The cooling unit 13K of the twenty-second embodiment includes a cooling unit body 71, an introduction coupler 72A, a discharge coupler 72B, and a cooling block CB.

In the cooling unit body 71, a liquid coolant flow path 73 is provided as indicated by a thick broken line in FIG. 35.

The cooling unit body 71 further includes a first cooling unit body portion 72BF provided with the introduction coupler 72A and the discharge coupler 72B, and a second cooling unit body portion 72BB provided to face the first cooling unit body portion 72BF and cooperatively forming the liquid coolant flow path 73.

As can be seen from a configuration of the liquid coolant flow path 73, the cooling unit 13K cools only a semiconductor chip CP41 as a heat source via the cooling block CB.

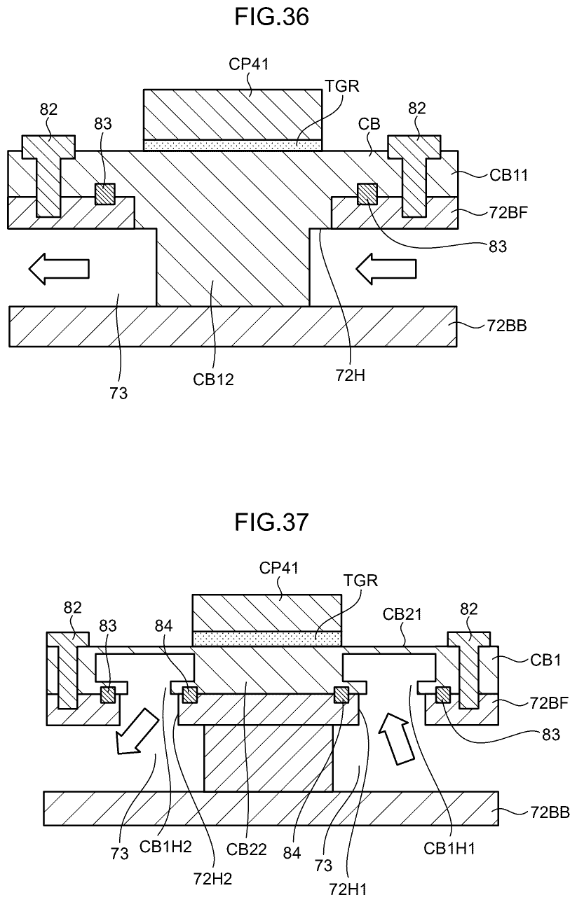

FIG. 36 is a cross-sectional view of a portion corresponding to a broken line frame BA in FIG. 35.

As illustrated in FIG. 36, in the cooling block CB, a heat transfer portion CB12 protruding from a lid portion CB11 having a track shape in plan view for closing an opening 72H provided in the first cooling unit body portion 72BF in a watertight state is inserted into the opening 72H.

Then, in a state in which an O-ring 83 is fitted into a groove provided in the lid portion CB11 and a groove provided in the first cooling unit body portion 72BF, a screw 82 is inserted through a screw hole provided in the lid portion CB11 and screwed into a screw groove provided in the first cooling unit body portion 72BF, and the heat transfer portion CB12 is disposed in the liquid coolant flow path 73 in a watertight state.

As a result, as indicated by arrows in FIG. 36, a liquid coolant flows in the liquid coolant flow path 73, whereby heat generated by the semiconductor chip CP41 as a heat source is transferred to the liquid coolant via a thermally conductive member TGR and the cooling block CB to dissipate heat.

Therefore, as in each of the above embodiments, the heat can be directly transferred to the liquid coolant and be dissipated without passing through the cooling unit body, so that cooling efficiency can be further improved.

Therefore, according to the twenty-second embodiment, cooling can be efficiently performed even with a heat source that generates a large amount of heat as the semiconductor chip CP41, such as a power semiconductor of a power system.

FIG. 37 is a cross-sectional view of a cooling unit of a modified example of the twenty-second embodiment.

In FIG. 36, the heat transfer portion CB12 is inserted into the opening 72H, but in the present modified example, the liquid coolant flow path branches toward the cooling block.

Specifically, as illustrated in FIG. 37, the liquid coolant flow path 73 is divided into two flow paths, a liquid coolant flow path leading to an opening 72H1 provided in the first cooling unit body portion 72BF, and a liquid coolant flow path leading from an opening 72H2 provided in the first cooling unit body portion 72BF.

Further, an opening CB1H1 of a cooling block CB1 that is provided at a position corresponding to the opening 72H1 and an opening CB1H2 of the cooling block CB1 that is provided at a position corresponding to the opening 72H2 are disposed at corresponding positions.

Then, the O-ring 83 is fitted into a groove provided in a lid portion CB21 and a groove provided in the first cooling unit body portion 72BF.

In parallel with this, an O-ring 84 is similarly fitted into a groove provided in a heat transfer portion CB22 and a groove provided in the first cooling unit body portion 72BF.

Then, the screw 82 is inserted through a screw hole provided in the lid portion CB21 and screwed into a screw groove provided in the first cooling unit body portion 72BF, and the cooling block CB1 is attached to the first cooling unit body portion 72BF in a watertight state.

As a result, the liquid coolant flow path leading to the opening 72H1 provided in the first cooling unit body portion 72BF and the liquid coolant flow path leading from the opening 72H2 provided in the first cooling unit body portion 72BF communicate with each other in the cooling block CB1, so that an integrated liquid coolant flow path is formed.

As a result, as indicated by arrows in FIG. 37, the liquid coolant flows in the cooling block CB1 at the same time as flowing in the liquid coolant flow path 73, and heat generated by the semiconductor chip CP41 as a heat source is transferred to the liquid coolant via the thermally conductive member TGR and the cooling block CB1 to dissipate heat.

According to such a configuration, if the opening CB1H1 is provided at the position corresponding to the opening 72H1 in the cooling block CB1 and the opening CB1H2 is provided at the position corresponding to the opening 72H2 in the cooling block CB1, a shape of the cooling block CB1 can be easily changed. Therefore, the degree of freedom in design is further improved by forming the cooling block CB1 into a shape corresponding to a target heat source.

Therefore, according to the present modified example as well, as in each of the above embodiments, heat can be directly transferred to the liquid coolant and dissipated without passing through the cooling unit body while further improving the degree of freedom in design, so that the cooling efficiency can be further improved, and even a heat source that generates a large amount of heat can be efficiently cooled.

### (23) Twenty-Third Embodiment

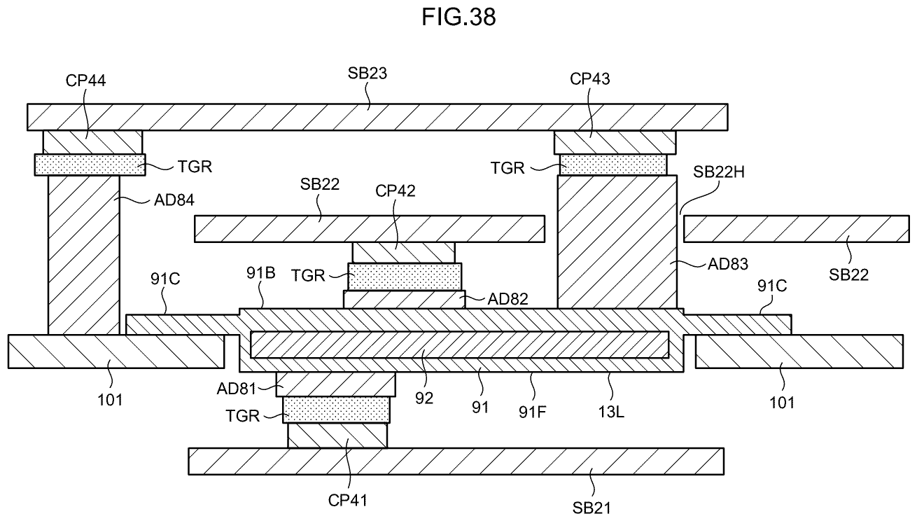

FIG. 38 is an explanatory view of a twenty-third embodiment.

FIG. 38 illustrates an embodiment in which semiconductor chips CP41 to CP43 as heat sources respectively mounted on three substrates SB21 to SB23 are cooled by one cooling unit.

As illustrated in FIG. 38, a cooling unit 13L of the twenty-third embodiment is configured to perform cooling via not only a first cooling unit body portion 91F and a second cooling unit body portion 91B included in a cooling unit 91 including a liquid coolant flow path 92 but also a frame portion 91C and a heat transfer member 101.

In the example of FIG. 38, the semiconductor chip CP41 as a heat source is mounted on the substrate SB21, the semiconductor chip CP42 as a heat source is mounted on the substrate SB22, and the semiconductor chips CP43 to CP44 as heat sources are mounted on the substrate SB23.

In addition, it is assumed that the semiconductor chips CP41 to CP43 generate a large amount of heat, and the semiconductor chip CP44 generates less heat than the semiconductor chips CP41 to CP43 and thus does not require significant cooling.

In the above configuration, the semiconductor chip CP41 is thermally coupled to the first cooling unit body portion 91F of the cooling unit 13L via a thermally conductive member TGR and a height adjustment portion AD81.

The semiconductor chip CP42 is thermally coupled to the second cooling unit body portion 91B of the cooling unit 13L via the thermally conductive member TGR and a height adjustment portion AD82.

Further, since the semiconductor chip CP43 is positioned on a back side of the substrate SB22 with respect to the cooling unit 13L, the semiconductor chip CP43 is thermally coupled to the second cooling unit body portion 91B of the cooling unit 13L via the thermally conductive member TGR and a height adjustment portion AD83 through an opening SB22H provided in the substrate SB22.

On the other hand, since the semiconductor chip CP44 generates relatively less heat, the semiconductor chip CP44 is thermally coupled to the heat transfer member 101 via the thermally conductive member TGR and a height adjustment portion AD84, and is thermally coupled to the cooling unit 13L via the heat transfer member 101 and the frame portion 91C.

As described above, according to the twenty-third embodiment, even in a case where three or more substrates are provided, the mounted semiconductor chips can be cooled as long as cooling performance of the cooling unit 13L allows, and it is not necessary to provide a plurality of cooling units, so that the device can be downsized.

In the above description, the heat transfer member 101 is disposed on a surface of the frame portion 91C that is adjacent to the first cooling unit body portion 91F. However, the heat transfer member 101 can also be disposed on a surface of the frame portion 91C that is adjacent to the second cooling unit body portion 91B, so that a height of the height adjustment portion AD84 can be reduced to further improve cooling efficiency.

### (24) Twenty-Fourth Embodiment

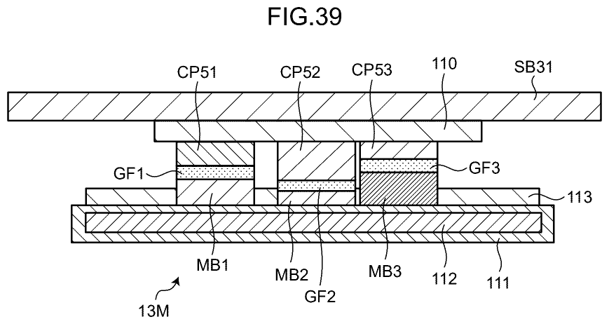

FIG. 39 is an explanatory view of a twenty-fourth embodiment.

The twenty-fourth embodiment is an embodiment for supporting a heat generating component included in a so-called system in package (SiP).

In the case of the SiP mounted on a substrate, since a plurality of semiconductor chips having different heights are mounted on the SiP itself, it is difficult to efficiently perform cooling.

Therefore, in the twenty-fourth embodiment, openings are provided in a heat transfer member, and heat transfer blocks having different plate thicknesses are incorporated in the respective openings and brazed or welded to accommodate a height difference between the respective heat generating components in the SiP, thereby optimizing a thickness of a thermally conductive member TGR (gap filler or thermal interface material (TIM)).

More specifically, as illustrated in FIG. 39, semiconductor chips CP51 to CP53 having different heights are mounted on a SiP 110 mounted on a substrate SB31.

Meanwhile, in a cooling unit 13M of the twenty-fourth embodiment, a liquid coolant path 112 is provided in a cooling unit body 111, and a heat transfer member 113 having a plurality of openings is provided on one surface of the cooling unit 13M by brazing or welding.

Metal blocks MB1 to MB3 as thermal interface materials (TIMs) corresponding to the heights of the semiconductor chips CP51 to CP53 are fixed to the respective openings of the heat transfer member 113 by brazing.

As a result, thicknesses of gap fillers GF1 to GF3 as thermally conductive members TGR can be optimized to more suitable thicknesses.

As a result, according to the twenty-fourth embodiment, even in a case where the semiconductor chips having different heights are mounted in a narrow region like the SiP 110, it is possible to easily accommodate such a difference.

Since a shape of the heat transfer member 113 can be easily changed, the cooling unit body 111 can be standardized to easily accommodate specification variations.

### (25) Twenty-Fifth Embodiment

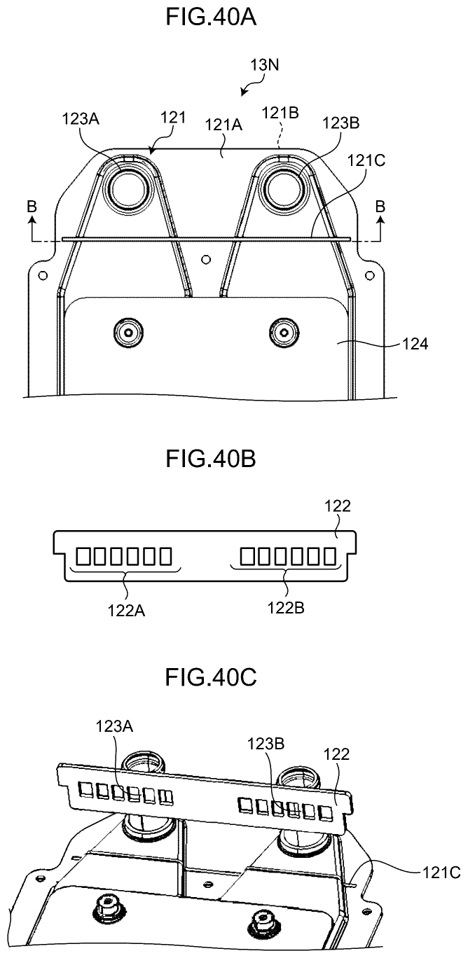

FIGS. 40A to 40C are explanatory views of a twenty-fifth embodiment.

In the above description, in order to eliminate unevenness of distribution of a flow of a liquid coolant in a liquid coolant flow path, a flow path protrusion is provided in the liquid coolant flow path. However, in the twenty-fifth embodiment, a slit member is provided in the liquid coolant flow path to eliminate the unevenness of the distribution of the flow of the liquid coolant.

FIG. 40A is a partial front view of a cooling unit 13N of the twenty-fifth embodiment.

FIG. 40B is a front view of the slit member of the twenty-fifth embodiment.

FIG. 40C is an explanatory view in a case where the slit member is inserted into the cooling unit 13N of the twenty-fifth embodiment.

In the cooling unit 13N of the twenty-fifth embodiment, as illustrated in FIGS. 40A and 40C, a cooling unit body 121 is provided with a slit-shaped insertion hole 121C communicating from a first cooling unit body portion 121F to a second cooling unit body portion 121B.

The cooling unit 13N is provided with an introduction coupler 123A and a discharge coupler 123B.

In actual use, the cooling unit 13N is fixed by inserting a slit member 122 into the slit-shaped insertion hole 121C, causing the slit member 122 to protrude from the second cooling unit body portion 121B, and brazing the slit member 122 to the cooling unit body 121.

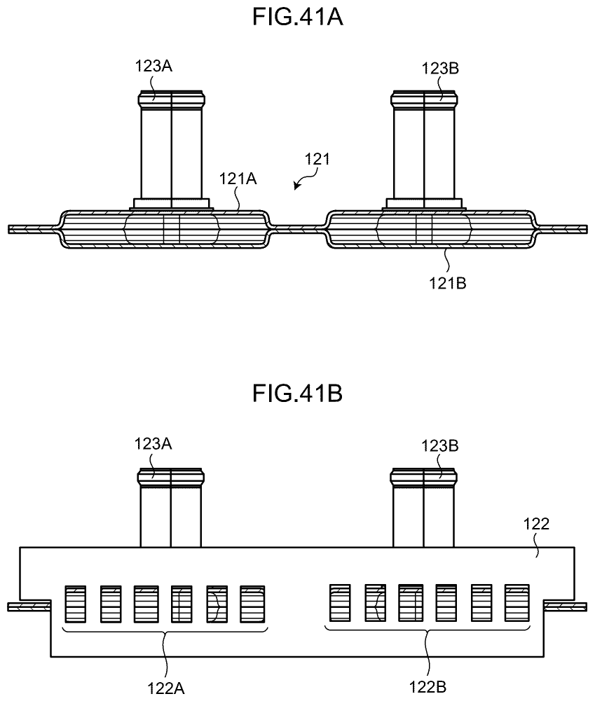

FIGS. 41A and 41B are explanatory views illustrating a state in which the slit member of the twenty-fifth embodiment is inserted and brazed.

FIG. 41A is a cross-sectional view taken along line B-B of FIG. 40A.

FIG. 41B is a view corresponding to a cross section taken along line B-B of FIG. 40A after brazing of the slit member 122.

As a result, a slit group 122A including a plurality of slits (holes) is positioned in the liquid coolant flow path adjacent to the introduction coupler 123A in the cooling unit body 121, and all the liquid coolants pass through the slit group 122A and flow to the liquid coolant flow path adjacent to the discharge coupler 123B.

Similarly, a slit group 122B including a plurality of slits (holes) is positioned in the liquid coolant flow path adjacent to the discharge coupler 123B in the cooling unit body 121, and all the liquid coolants pass through the slit group 122B and flow toward the discharge coupler 123B.

In this case, the liquid coolant passing through the slit group 122A is diffused due to a flow path resistance corresponding to a shape of each slit included in the slit group 122A, so that the distribution of the flow of the liquid coolant is made uniform, and the liquid coolant smoothly flows to the liquid coolant flow path adjacent to the discharge coupler 123B.

Furthermore, the liquid coolant passes through the slit group 122B, and the liquid coolant is diffused due to a flow path resistance corresponding to the shape of each slit included in the slit group 122B, so that the distribution of the flow of the liquid coolant is further made uniform, and the liquid coolant smoothly reaches the discharge coupler 123B.

As a result, the flow of the liquid coolant passing through the inside of the discharge coupler 123B is smoothly discharged from the discharge coupler 123B without generating a vortex.

Therefore, it is also possible to suppress a decrease in effective discharge speed by the cooling unit 13N of the twenty-fifth embodiment and to maintain heat exchange efficiency at a predetermined value.

In this case, since the slit formed in the slit member 122 can be variously changed according to an application thereof, the slit can be applied to various applications.

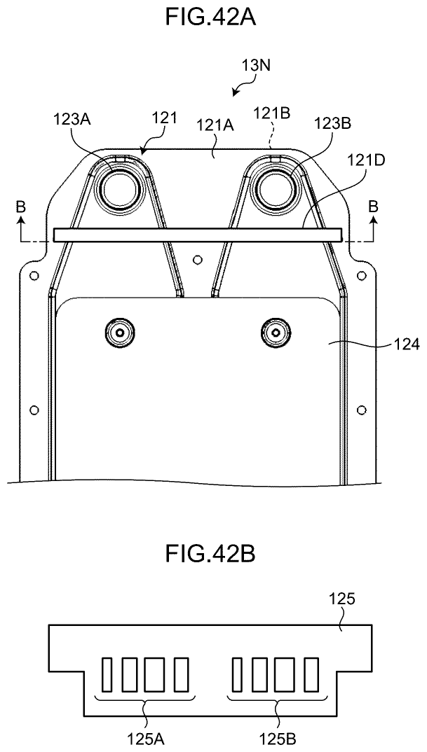

FIG. 42A is a partial front view of a cooling unit 13N of a first modified example of the twenty-fifth embodiment.

FIG. 42B is a front view of a slit member of the first modified example of the twenty-fifth embodiment.

In FIGS. 42A and 42B, portions similar to those in FIGS. 40A and 40B are denoted by the same reference numerals.

FIGS. 42A and 42B are different from FIGS. 40A and 40B in that, in a slit member 125, a through-hole 121D having a large width is provided instead of the slit-shaped insertion hole 121C, the number of slits is different, and a slit width of a slit that is included in slit groups 125A and 125B and is positioned at the center is larger than slit widths of slits positioned on both sides.

As described above, since the slit formed in the slit member 125 can be variously changed according to an application thereof, the slit can be applied to various applications.

FIG. 43 is an explanatory view of a second modified example of the twenty-fifth embodiment.

FIG. 43 is different from FIG. 40B in that, in a slit member 127, a slit group 127A adjacent to the introduction coupler 123A and a slit group 127B adjacent to the discharge coupler 123B are different from each other.

That is, in the slit group 127A adjacent to the introduction coupler 123A, since a flow rate of the liquid coolant introduced from the introduction coupler 123A is high at a central portion, which causes variations in flow rate, no slit is provided at the central portion in order to increase the flow path resistance and diffuse the liquid coolant.

On the other hand, since the slit group 127B adjacent to the discharge coupler 123B needs to smoothly discharge the liquid coolant, the slit width at the center is increased to decrease the flow path resistance and smoothly discharge the liquid coolant.

As a result, it is possible to suppress a decrease in effective discharge speed, and eventually, it is possible to maintain the heat exchange efficiency at a predetermined value, and efficient cooling can be performed.

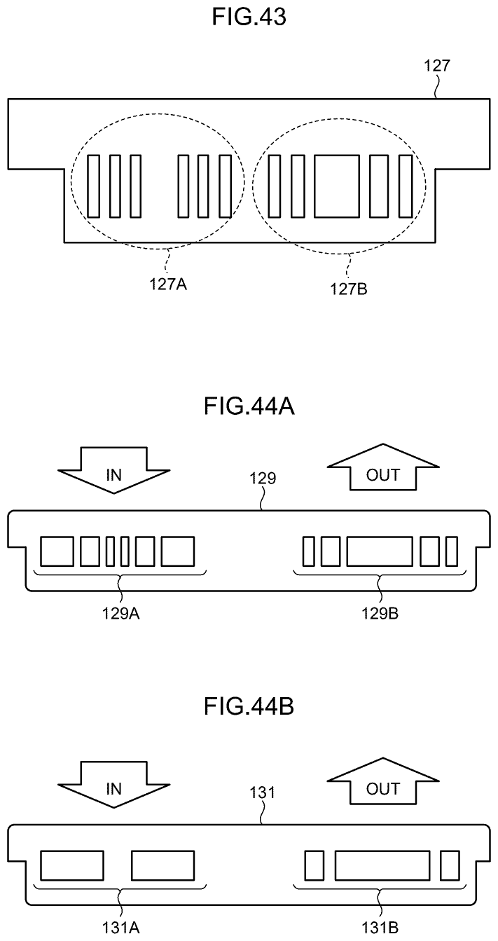

FIG. 44A is an explanatory view of a third modified example of the twenty-fifth embodiment.

FIG. 44B is an explanatory view of a fourth modified example of the twenty-fifth embodiment.

FIG. 44A is different from FIG. 43 in that, in a slit member 129, a configuration of a slit group 129A adjacent to the introduction coupler 123A and a configuration of a slit group 129B adjacent to the discharge coupler 123B are different from each other.

That is, in the slit group 129A adjacent to the introduction coupler 123A, since a flow rate of the liquid coolant introduced from the introduction coupler 123A is high at a central portion, which causes variations in flow rate, a slit having a small slit width that increases the flow path resistance is provided at the central portion to increase the flow path resistance and diffuse the liquid coolant. Since the slit group 129B adjacent to the discharge coupler 123B needs to smoothly discharge the liquid coolant, a slit width at a central portion is increased to decrease the flow path resistance and smoothly discharge the liquid coolant.

As a result, it is possible to suppress a decrease in effective discharge speed, and eventually, it is possible to maintain the heat exchange efficiency at a predetermined value, and efficient cooling can be performed.

FIG. 44B is different from FIG. 43 in that, in a slit member 131, a configuration of a slit group 131A adjacent to the introduction coupler 123A and a configuration of a slit group 131B adjacent to the discharge coupler 123B are different from each other.

That is, in the slit group 131A adjacent to the introduction coupler 123A, an opening ratio of the slit is larger than that in the third modified example to decrease the flow path resistance.

Similarly, also in the slit group 131B adjacent to the discharge coupler 123B, an opening ratio of the slit is larger than that in the third modified example to further decrease the flow path resistance, so that cooling can be efficiently performed not only when an introduction pressure of the liquid coolant is high but also when the introduction pressure of the liquid coolant is low.

Since a flow rate of the liquid coolant introduced from the introduction coupler 123A is high at a central portion, which causes variations in flow rate, a slit having a small slit width is provided at the central portion to increase the flow path resistance and diffuse the liquid coolant. Since the slit group 129B adjacent to the discharge coupler 123B needs to smoothly discharge the liquid coolant, a slit width at a central portion is increased to decrease the flow path resistance and smoothly discharge the liquid coolant.

As a result, it is possible to suppress a decrease in effective discharge speed, and eventually, it is possible to maintain the heat exchange efficiency at a predetermined value, and efficient cooling can be performed.

### (26) Twenty-Sixth Embodiment

In each of the above embodiments, an introduction coupler has a substantially cylindrical shape, and a liquid coolant is diffused by a flow path protrusion or a slit member.

In a twenty-sixth embodiment, a shape of the introduction coupler is changed such that the liquid coolant is diffused at a point in time when the liquid coolant is introduced into a cooling unit body, so that unevenness of a flow in a liquid coolant flow path is eliminated to achieve a uniform flow.

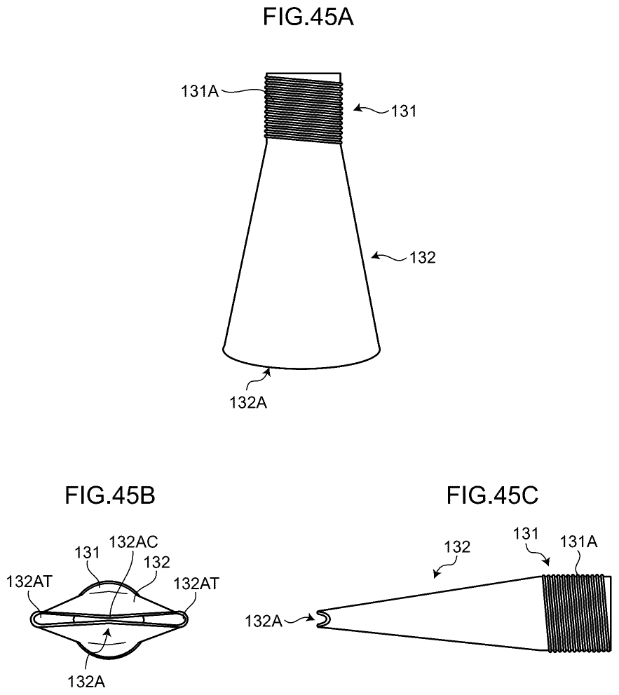

FIG. 45A is a plan view of an introduction coupler 130 of a first aspect of the twenty-sixth embodiment.

FIG. 45B is a front view of the introduction coupler 130 of the first aspect of the twenty-sixth embodiment.

FIG. 45C is a side view of the introduction coupler 130 of the first aspect of the twenty-sixth embodiment.

As illustrated in FIGS. 45A to 45C, the introduction coupler 130 of the first aspect includes a bulge portion 131, an introduction coupler body portion 132, and a flange portion 133.

The bulge portion 131 functions as a connector portion to which a coolant supply pipe of an external coolant cooling/circulation unit as illustrated in FIG. 1 is connected, and is provided at a portion protruding from a cooling unit in the present application.

The bulge portion 131 has a substantially cylindrical shape, is formed by bulging processing, and has shape that is partially expanded in diameter.

The introduction coupler body portion 132 has a shape in which a funnel shape corresponding to a side surface of a so-called truncated cone is partially crushed. As illustrated in FIG. 45B, an opening portion 132A at a tip has an appearance like an infinite symbol in which openings of both end portions 132AT are large when viewed from the front, and an opening of a central portion 132AC is small.

The flange portion 133 has a shape protruding in a flange shape and is provided so as to come into contact with an inner surface of the cooling unit.

Therefore, when the liquid coolant passes through the inside of the introduction coupler body portion 132, the central portion 132AC has a higher flow path resistance and is less likely to allow flowing of the liquid coolant, so that the liquid coolant is discharged into the liquid coolant flow path in the cooling unit body in a state of being diffused along a fan shape in plan view illustrated in FIG. 45A.

As a result, the liquid coolant uniformly flows to fins provided downstream, and the liquid coolant smoothly flows toward the discharge coupler.

As a result, it is possible to suppress a decrease in effective discharge speed, and eventually, it is possible to maintain the heat exchange efficiency at a predetermined value, and efficient cooling can be performed.

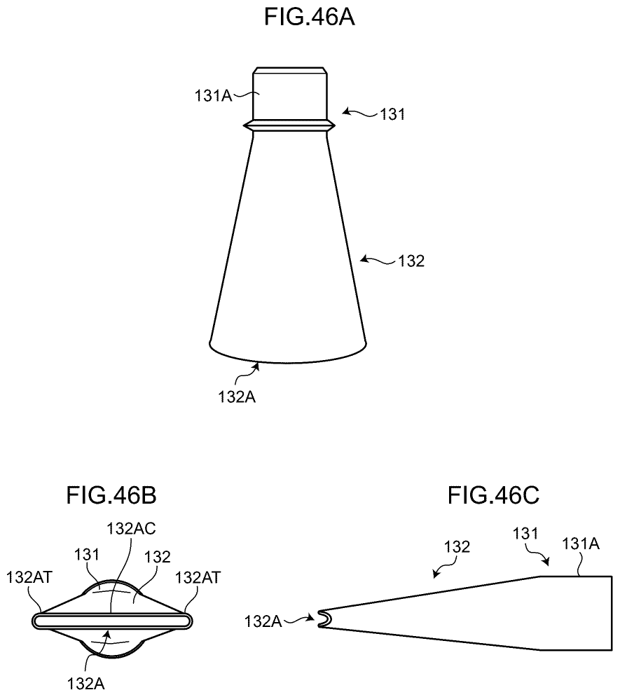

FIG. 46A is a plan view of an introduction coupler 130X of a second aspect of the twenty-sixth embodiment.

FIG. 46B is a front view of the introduction coupler 130X of the second aspect of the twenty-sixth embodiment.

FIG. 46C is a side view of the introduction coupler 130X of the second aspect of the twenty-sixth embodiment.

In FIGS. 46A to 46C, portions similar to those in FIGS. 45A to 45C are denoted by the same reference numerals.

As illustrated in FIGS. 46A to 46C, the introduction coupler 130X includes a bulge portion 131, an introduction coupler body portion 132X, and a flange portion 133.

The bulge portion 131 functions as a connector portion to which the coolant supply pipe of the external coolant cooling/circulation unit as illustrated in FIG. 1 is connected, and is provided at a portion protruding from a cooling unit in the present application.

The bulge portion 131 has a substantially cylindrical shape, is formed by bulging processing, and has shape that is partially expanded in diameter.

The introduction coupler body portion 132X has a shape in which a funnel shape corresponding to a side surface of a so-called truncated cone is crushed, and as illustrated in FIG. 46B, an opening portion 132B at a tip has a so-called track shape in which an opening width of both end portions 132BT and an opening width of a central portion 132BC are substantially equal to each other when viewed from the front.

The flange portion 133 has a shape protruding in a flange shape and is provided so as to come into contact with the inner surface of the cooling unit.

Therefore, when the liquid coolant passes through the introduction coupler body portion 132X, the liquid coolant is discharged into the liquid coolant flow path in the cooling unit body in a state of being slightly diffused along a fan shape in plan view illustrated in FIG. 46A.

As a result, the liquid coolant uniformly flows to fins provided downstream, and the liquid coolant smoothly flows toward the discharge coupler.

In addition, the flow path resistance can be decreased to be lower than that of the introduction coupler 130 of the first aspect.

As a result, it is possible to suppress a decrease in effective discharge speed, and eventually, it is possible to maintain the heat exchange efficiency at a predetermined value, and efficient cooling can be performed.

### (27) Twenty-Seventh Embodiment

As illustrated in FIG. 1, a cooling unit described in each of the above embodiments is connected to an external coolant cooling/circulation unit, and a liquid coolant is naturally supplied. Therefore, there is a possibility that the liquid coolant leaks.

As described above, a cooling unit body has a structure with many irregularities, and even if the cooling unit body is housed in a housing, an introduction coupler and a discharge coupler need to protrude from the housing, and it is assumed that a liquid intrudes through a gap formed between the cooling unit body and the housing.

Furthermore, since the cooling unit body is a cooling device, there is a very high possibility that moisture in the air condenses in the housing depending on an ambient temperature and an ambient humidity.

Furthermore, since various sensors such as a temperature sensor and a pressure sensor, a control circuit for controlling the sensors, and an electronic circuit such as a communication opening for performing communication with the outside are also incorporated in the housing, it is desired to avoid intrusion of the liquid from the outside, dew condensation, or the like as much as possible, and to promote discharge of the liquid to the outside in a case where the intrusion of the liquid from the outside or the dew condensation occurs, thereby reducing an influence thereof as much as possible.

Therefore, in view of the above problems, an object of a twenty-seventh embodiment is to provide a cooling unit having a structure capable of avoiding intrusion of a liquid from the outside, dew condensation, and the like as much as possible, and reducing an influence of the intrusion of the liquid from the outside or the dew condensation as much as possible when the intrusion of the liquid from the outside or the dew condensation occurs.

Hereinafter, problems to be solved will be described prior to the description of the embodiment.

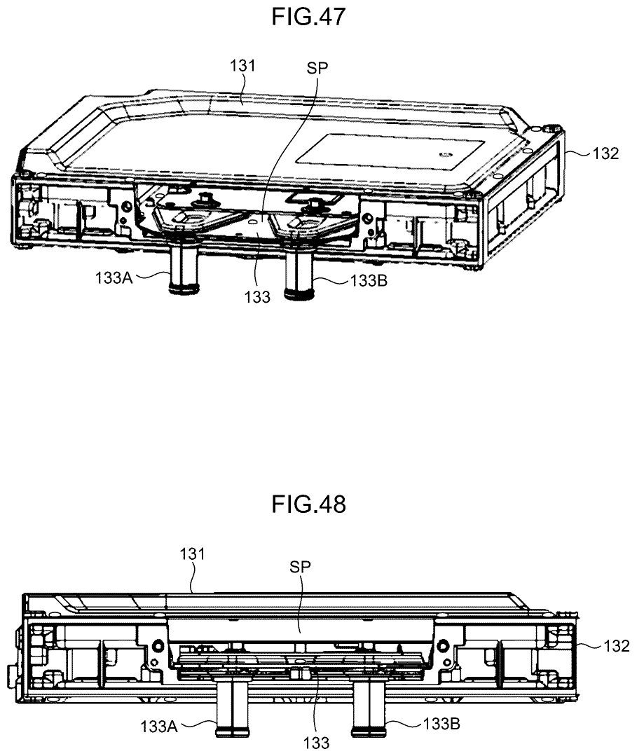

FIG. 47 is an explanatory perspective view of an example of a case where the cooling unit is housed between the housing and a front chassis.

FIG. 48 is a front view illustrating a case where the cooling unit is housed between the housing and the front chassis.

As illustrated in FIG. 47, when a cooling unit body 133 is housed between a front chassis 131 and a housing 132, an introduction coupler 133A and a discharge coupler 133B of the cooling unit body 133 need to protrude outside the housing 132.

As a result, as illustrated in FIG. 48, a gap SP is formed between the front chassis 131 and an upper surface of the cooling unit body 133.

Therefore, in order to avoid the intrusion of the liquid from the outside from such a portion, it is necessary to provide a member as a separate component that fills the gap SP.

Since the cooling unit body 133 of the cooling unit has irregularities formed by drawing or the like, dimensional accuracy is not necessarily high, and thus it is difficult to perform assembly with desired accuracy by using a member as a separate component. In addition, in a case where the liquid coolant leaks from the introduction coupler 133A or the discharge coupler 133B, there is a possibility that the liquid coolant intrudes into the housing 132.

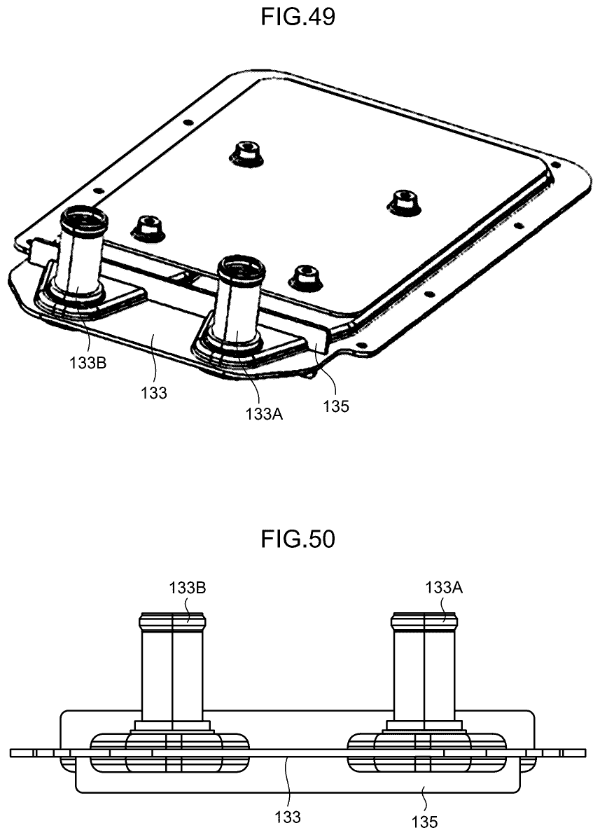

FIG. 49 is an external perspective view of the cooling unit attached with a liquid intrusion prevention wall member of the twenty-seventh embodiment.

FIG. 50 is a view of the cooling unit attached with the liquid intrusion prevention wall member of the twenty-seventh embodiment when viewed from the introduction coupler and the discharge coupler.

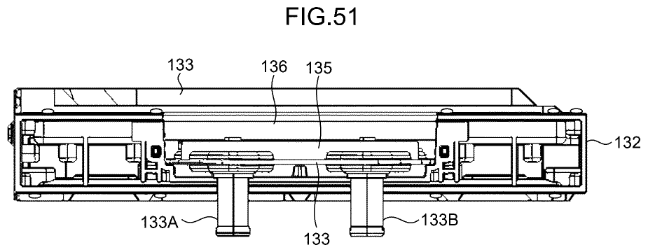

FIG. 51 is a front view illustrating a case where the cooling unit is housed between the housing and the front chassis, and the liquid intrusion prevention wall member and a liquid intrusion prevention member of the twenty-seventh embodiment are provided.

A liquid intrusion prevention wall member 135 is provided vertically in an up-down direction of the cooling unit body 133 in the vicinity of the introduction coupler 133A and the discharge coupler 133B of the cooling unit body 133 as illustrated in FIG. 49, so that the gap SP can be filled by pressing a liquid intrusion prevention member 136 disposed between the front chassis 131 and the cooling unit body 133 against a surface 135A of the liquid intrusion prevention wall member 135 as illustrated in FIG. 51.

In the above configuration, it is sufficient if the liquid intrusion prevention wall member 135 is inserted into openings respectively provided at positions opposed to each other in the up-down direction of the cooling unit body 133 so as to penetrate through the cooling unit body 133, and then is assembled by brazing.

Alternatively, the liquid intrusion prevention wall member 135 can be vertically divided into two members as in FIG. 50, and can be assembled by brazing to the cooling unit body 133 from above and below the cooling unit body 133.

### (28) Twenty-Eighth Embodiment

Next, a twenty-eighth embodiment will be described.

The twenty-eighth embodiment is an embodiment for preventing intrusion of a liquid from the outside.

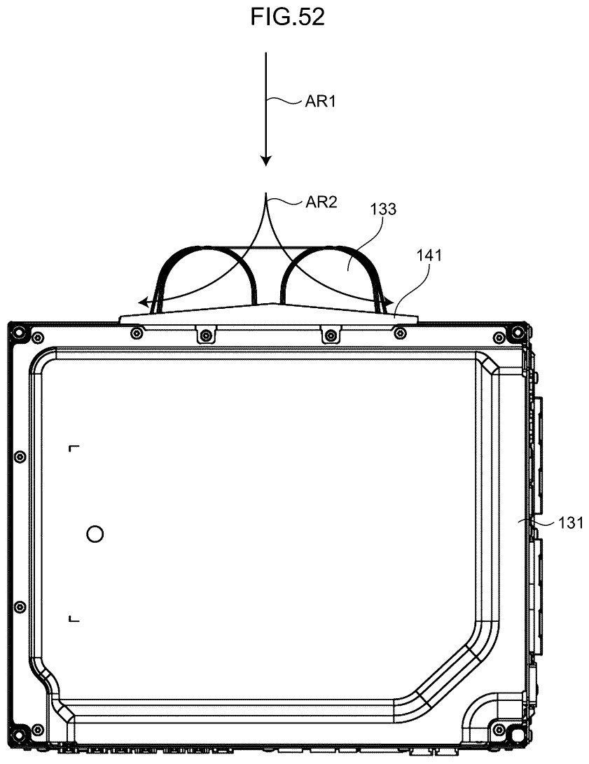

FIG. 52 is an explanatory view of the twenty-eighth embodiment.

In the twenty-eighth embodiment, for a gap SP between a front chassis 131 illustrated in FIG. 48 and an upper surface of a cooling unit body 133, a liquid guide member 141 inclined in a left-right direction when viewed from a side is disposed in front of a liquid intrusion prevention wall member 135 so as to cover the gap SP.

As a result, according to the twenty-eighth embodiment, even if the liquid from the outside moves in a direction indicated by an arrow AR1 from above in FIG. 49, a path of the liquid is blocked by the liquid guide member 141, and the liquid flows in a direction indicated by an arrow AR2, so that it is possible to prevent the liquid from intruding from the outside.

### (29) Twenty-Ninth Embodiment

Next, a twenty-ninth embodiment will be described.

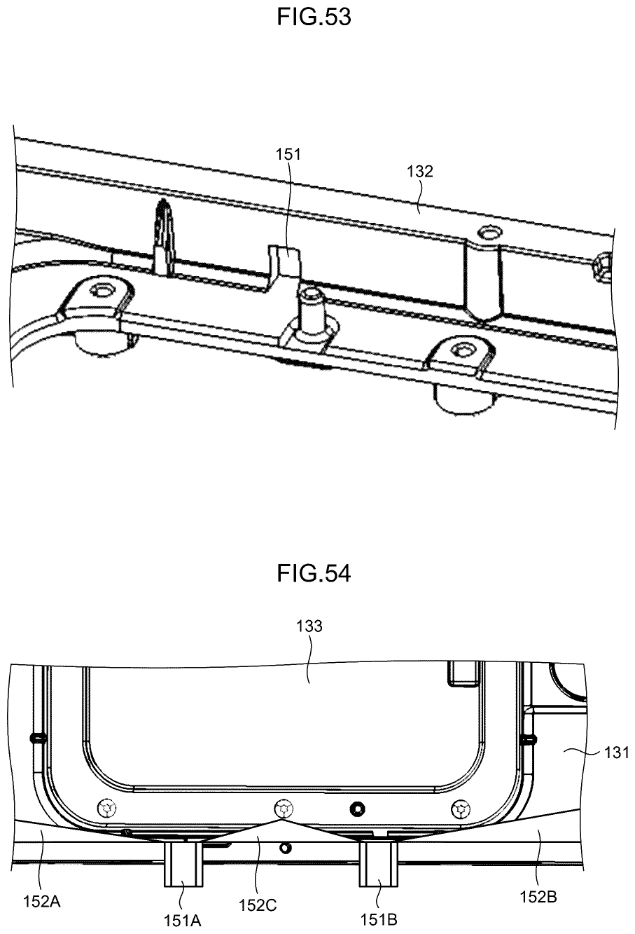

FIG. 53 is a partially enlarged view of a housing of the twenty-ninth embodiment.

The twenty-ninth embodiment is an embodiment corresponding to a countermeasure for a case where a liquid intrudes from the outside between a housing 132 and a cooling unit body 133 or between the cooling unit body 133 and a front chassis 131, or a case where the liquid is generated due to dew condensation.

Therefore, the housing 132 of the twenty-ninth embodiment is provided with a liquid discharge hole 151 positioned on a lower side when the housing 132 is actually installed in a vehicle or the like.

In this case, in the housing, the liquid discharge hole 151 is preferably provided on a side where an electronic component such as a semiconductor chip or an electric component such as a connector terminal is not disposed.

According to such a configuration, even when the liquid intrudes between the housing 132 and the cooling unit body 133 or between the cooling unit body 133 and the front chassis 131 from the outside, or even when the liquid is generated due to dew condensation, it is possible to promptly discharge the liquid to the outside, and it is possible to avoid an adverse effect caused by the intrusion of the liquid or the like.

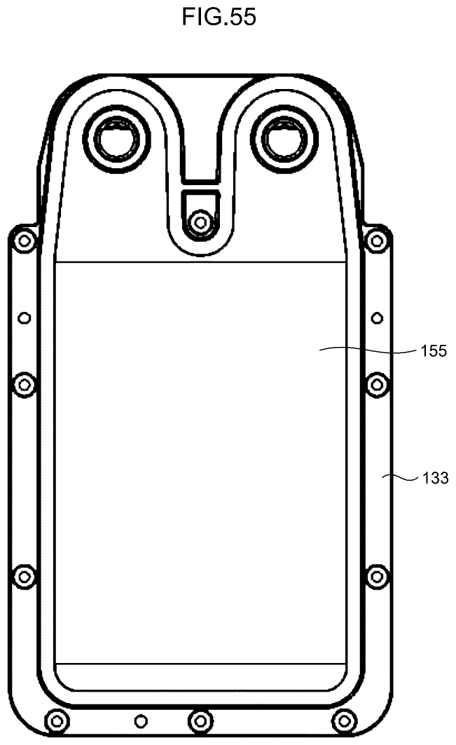

FIG. 54 is an explanatory view of a modified example of the twenty-ninth embodiment.

In the example of FIG. 54, liquid discharge holes 151A and 151B are provided on a lower side when the housing 132 is actually installed in a vehicle or the like.

Further, slope members 152A to 152C are provided in the housing 132 and are configured to guide the liquid falling from above in FIG. 54 to the liquid discharge hole 151A or the liquid discharge hole 151B and quickly discharge the liquid to the outside.

As a result, even when the liquid intrudes between the housing 132 and the cooling unit body 133 or between the cooling unit body 133 and the front chassis 131 from the outside, or even when the liquid is generated due to dew condensation, it is possible to promptly discharge the liquid to the outside, and it is possible to avoid an adverse effect caused by the intrusion of the liquid or the like.

### (30) Thirtieth Embodiment

Next, a thirtieth embodiment will be described.

FIG. 55 is an explanatory view of the thirtieth embodiment.

The thirtieth embodiment is an embodiment corresponding to a countermeasure for a case where a liquid is generated due to dew condensation on a cooling unit body 133.

Therefore, a liquid absorbing member 155 that absorbs the liquid generated by dew condensation is adhered to a surface of the cooling unit body 133 of the thirtieth embodiment.

As the liquid absorbing member 155, for example, a nonwoven fabric or the like is used.

As a result, even if dew condensation occurs, the liquid does not immediately drip, so that it is possible to reduce an influence on an electronic substrate or the like installed in a housing and to further improve reliability.

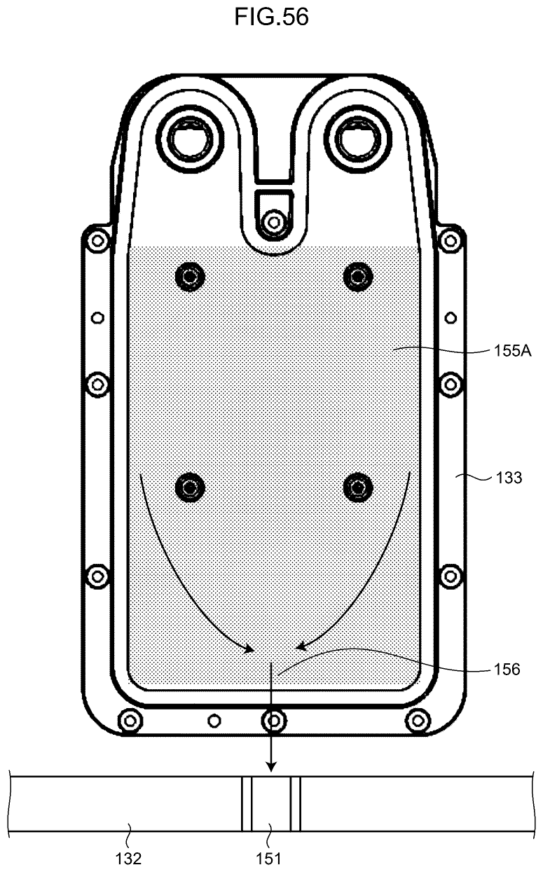

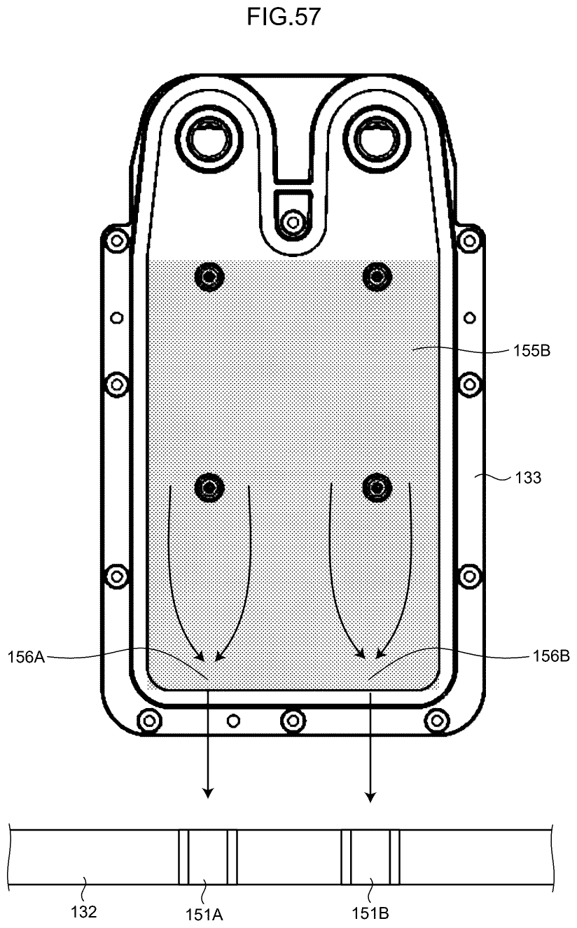

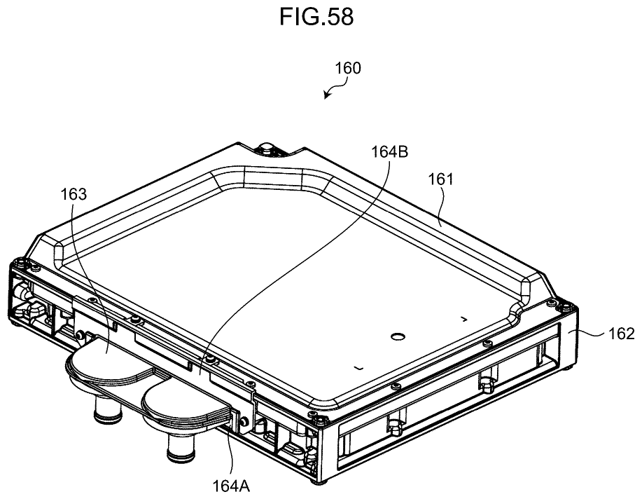

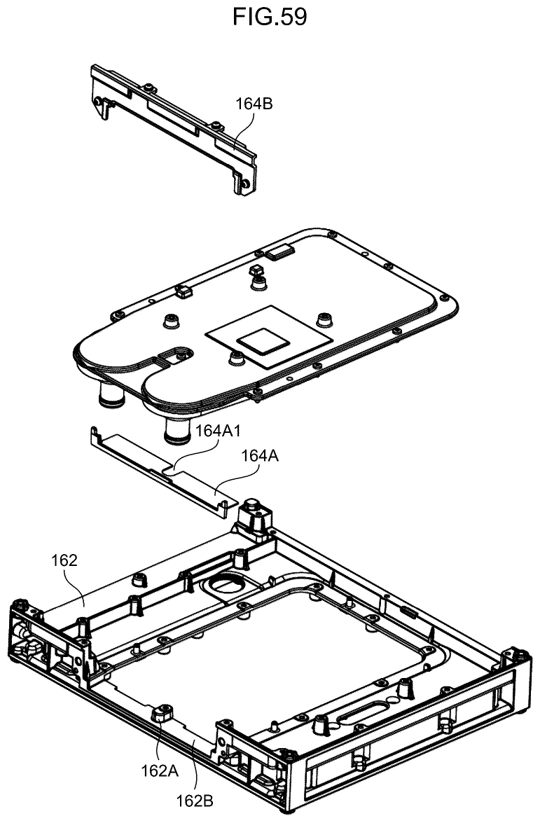

FIG. 56 is an explanatory view of a first modified example of the thirtieth embodiment.

In the first modified example of the thirtieth embodiment, a liquid discharge hole 151 is provided on a lower side when a housing 132 is actually installed in a vehicle or the like.

In this case, in the housing, the liquid discharge hole 151 is preferably provided on a side where an electronic component such as a semiconductor chip, a substrate, or an electric component such as a connector terminal is not disposed.

For example, a liquid absorbing member 155A having a home plate shape is adhered to a surface of the cooling unit body 133 of the first modified example of the thirtieth embodiment.

As the liquid absorbing member 155A, for example, a nonwoven fabric or the like is used.

As a result, when dew condensation occurs, the generated liquid is absorbed by the liquid absorbing member 155A and does not immediately drip.

In addition, when a large amount of dew condensation occurs, the liquid generated by the dew condensation gradually shifts to a pointed portion at a lower end of the liquid absorbing member 155A due to gravity. When the liquid cannot be held by the liquid absorbing member 155A, the liquid drips from the pointed portion at the lower end to the liquid discharge hole 151 due to gravity and is discharged outside the housing 132.

Therefore, an influence on the electronic substrate or the like installed in the housing 132 can be reduced, and the reliability can be further improved.

FIG. 57 is an explanatory view of a second modified example of the thirtieth embodiment.

In the second modified example of the thirtieth embodiment, liquid discharge holes 151A and 151B are provided on a lower side when the housing 132 is actually installed in a vehicle or the like.

In this case, in the housing 132, the liquid discharge holes 151A and 151B are preferably provided on a side where an electronic component such as a semiconductor chip, a substrate, or an electric component such as a connector terminal is not disposed.

For example, a W-shaped liquid absorbing member 155B is adhered to the surface of the cooling unit body 133 of the modified example of the thirtieth embodiment.

As the liquid absorbing member 155B, for example, a nonwoven fabric or the like is used.

As a result, when dew condensation occurs, the generated liquid is absorbed by the liquid absorbing member 155B and does not immediately drip.

In addition, when a large amount of dew condensation occurs, the liquid gradually shifts to a pointed portion 156A at a lower end of the liquid absorbing member 155B or a pointed portion 156B at the lower end of the liquid absorbing member 155B as indicated by arrows due to gravity.

Then, when an amount of the liquid exceeds a holding capacity of the liquid absorbing member 155A, the liquid accumulated at the pointed portion 156A at the lower end drips to the liquid discharge hole 151A due to gravity and is discharged outside the housing 132.

Similarly, the liquid accumulated at the pointed portion 156B at the lower end drips to the liquid discharge hole 151B due to gravity and is discharged outside the housing 132.

Therefore, an influence on the electronic substrate or the like installed in the housing 132 can be reduced, and the reliability can be further improved.

### (31) Thirty-First Embodiment

Next, a thirty-first embodiment will be described.

FIG. 58 is an external perspective view of a cooling unit of a thirty-first embodiment.

A cooling unit 160 of the thirty-first embodiment can house an electronic circuit board, a terminal board, and the like therein, and includes a front chassis 161, a housing 162, a cooling unit body 163, and a sealing member 164.

In the following description, the electronic circuit board, the terminal board, and the like are not illustrated for easy understanding, but in an actual device, the electronic circuit board, the terminal board, and the like are disposed between the front chassis 161 and the cooling unit body 163 or between the housing 162 and the cooling unit body 163. The same applies to the following embodiments.

FIG. 59 is an exploded perspective view of the cooling unit of the thirty-first embodiment.

In FIG. 59, the front chassis 161 is not illustrated for easy understanding.

As illustrated in FIG. 59, the sealing member 164 includes a first sealing member 164A and a second sealing member 164B.

By using two members, the first sealing member 164A and the second sealing member 164B, a sealing ability is secured, and assemblability is improved.

Then, a notch 164A1 of the first sealing member 164A is placed on a contact surface 162B of the housing 162 in a state in which an engagement projection portions 162A of the housing 162 is fitted into the notch 164A1.

In this state, the cooling unit body 163 is disposed in the housing 162 such that the first sealing member 164A comes into contact with a predetermined position on the cooling unit body 163.

Then, the second sealing member 164B is fitted to the cooling unit body 163 from above, and the second sealing member 164B is fixed to the housing 162.

Then, the front chassis 161 (not illustrated) is overlaid from above and fixed, the assembly is completed in a state illustrated in FIG. 59.

In the configuration of the thirty-first embodiment, it is possible to reliably secure a sealing state between the cooling unit body 163, and the front chassis 161 and the housing 162 with a simple process, and it is possible to guarantee an operation of an electronic device disposed between the housing 162 and the front chassis 161 and to maintain high reliability.

### (32) Thirty-Second Embodiment

Next, a thirty-second embodiment will be described.

FIG. 60 is an external perspective view of a cooling unit of the thirty-second embodiment.

A cooling unit 170 of the thirty-second embodiment includes a front chassis 171, a housing 172, a cooling unit body 173, and a sealing member 174.

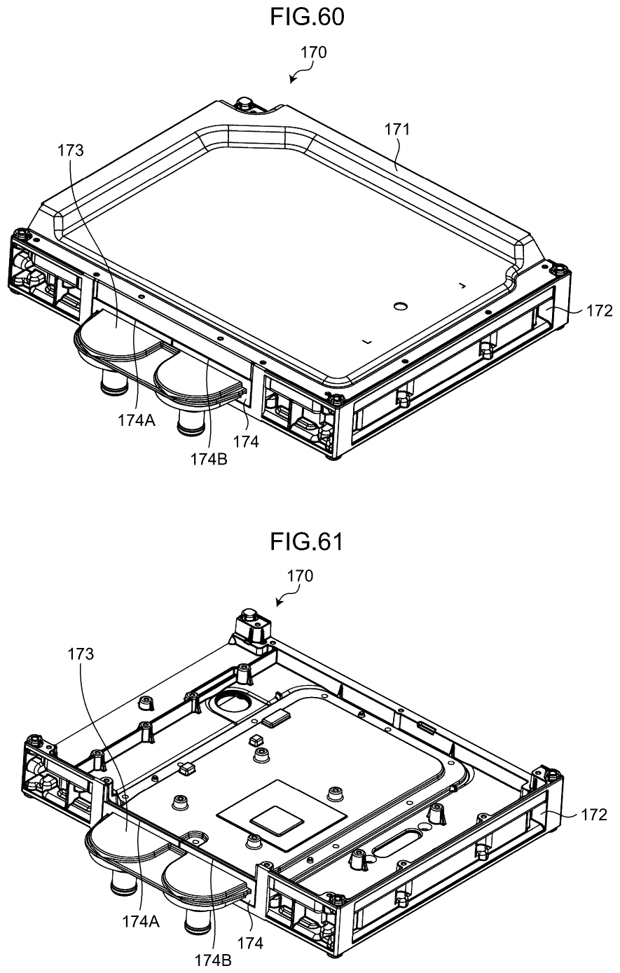

FIG. 61 is an exploded perspective view of the cooling unit of the thirty-second embodiment.

Also in FIG. 61, the front chassis 171 is not illustrated for easy understanding.

As illustrated in FIGS. 60 and 61, the sealing member 174 is made of rubber and has a C shape including a first arm portion 174A and a second arm portion 174B.

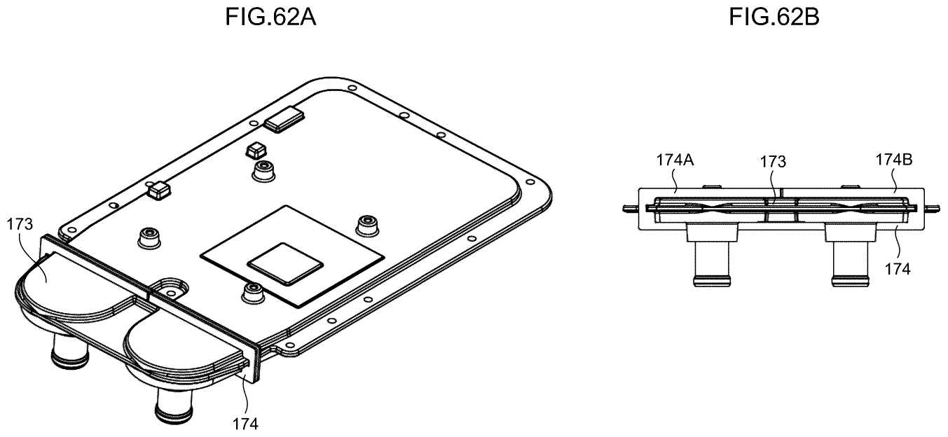

FIG. 62A is an external perspective view of the cooling unit body 173 in an assembled state.

FIG. 62B is a front view of the cooling unit body 173 in the assembled state.

As the sealing member 174 has a C shape including the first arm portion 174A and the second arm portion 174B, assemblability is improved.

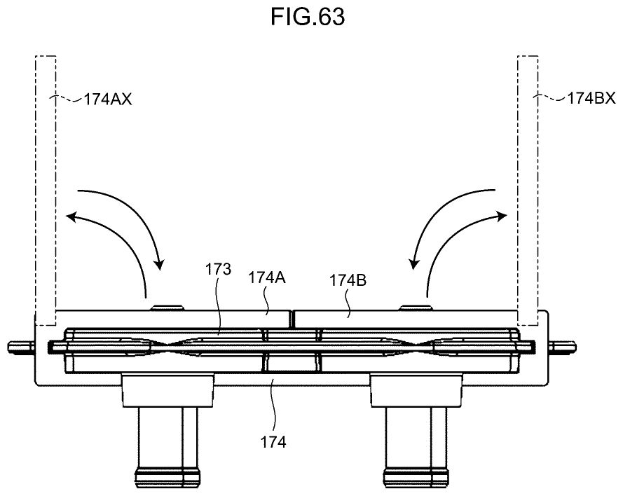

FIG. 63 is an explanatory view of a step of fitting the sealing member into the cooling unit.

As illustrated in FIG. 63, when the sealing member 174 is fitted to the cooling unit body 173, the first arm portion 174A and the second arm portion 174B of the sealing member 174 made of rubber are opened to a position 174AX and a position 174BX as indicated by one-dot chain lines in FIG. 63 and fitted to predetermined positions on the cooling unit body 173.

When the first arm portion 174A and the second arm portion 174B in this state are returned to original positions, the state illustrated in FIG. 62B is obtained.

Then, the front chassis 171 (not illustrated) is overlaid from above and fixed, the assembly is completed in a state illustrated in FIG. 60.

In the configuration of the thirty-second embodiment, it is possible to reliably secure a sealing state between the cooling unit body 173, and the front chassis 171 and the housing 172 with a simple process, and it is possible to guarantee an operation of an electronic device disposed on either the housing 172 or the front chassis 171 and to maintain high reliability.

### (33) Thirty-Third Embodiment

Next, a thirty-third embodiment will be described.

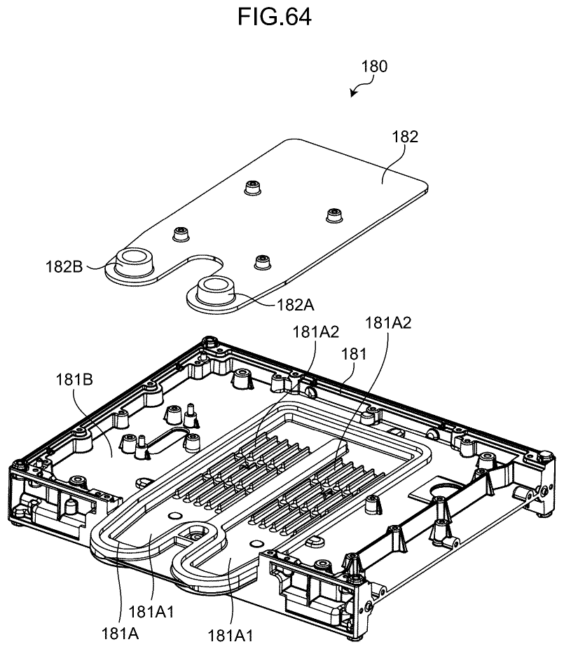

FIG. 64 is an exploded perspective view (part 1) of a cooling unit of the thirty-third embodiment at the time of assembly.

A cooling unit 180 of the thirty-third embodiment includes a cooling unit body housing portion 181 and a coupler panel 182.

The cooling unit body housing portion 181 is formed by integrally forming a main part of a cooling unit body and a housing in the above-described embodiments, and can reduce an intrusion path of a liquid and further improve reliability as compared with a case where the cooling unit body and the housing are formed separately.

As illustrated in FIG. 64, the cooling unit body housing portion 181 includes a liquid coolant flow path forming portion 181A1 that forms a liquid coolant flow path, and a fin forming portion 181A2 in which fins are formed.

The liquid coolant flow path forming portion 181A1 forms the liquid coolant flow path in cooperation with the coupler panel in a state in which the coupler panel 182 is attached.

Meanwhile, the coupler panel 182 includes an introduction coupler 182A and a discharge coupler 182B on one end side.

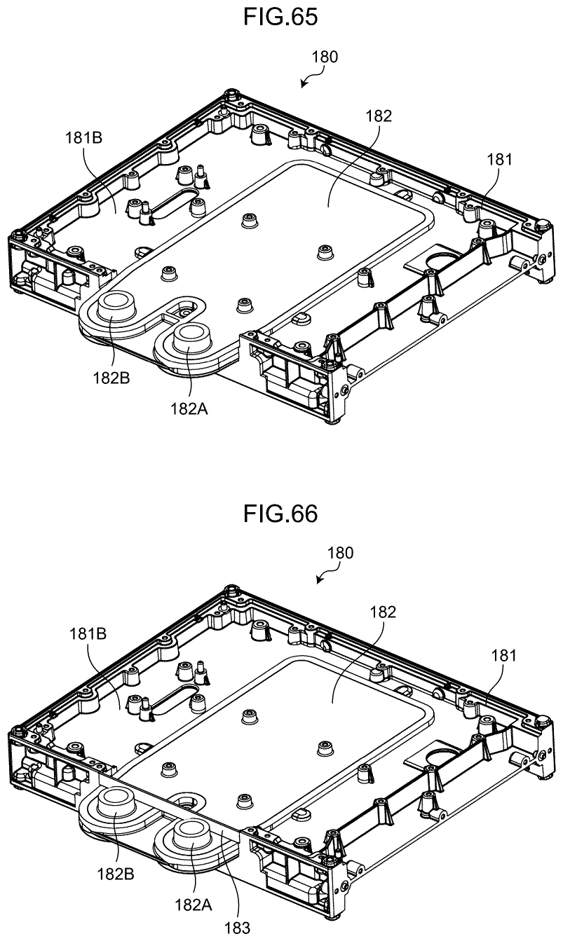

FIG. 65 is an exploded perspective view (part 2) of the cooling unit of the thirty-third embodiment at the time of assembly.

FIG. 65 illustrates a state in which the coupler panel 182 is attached to the cooling unit body housing portion 181.

In this case, the cooling unit body housing portion 181 and the coupler panel 182 are bonded by, for example, FSW processing.

FIG. 66 is an exploded perspective view (part 3) of the cooling unit of the thirty-third embodiment at the time of assembly.

In FIG. 66, a sealing member 183 for blocking a gap between the coupler panel 182 and a front chassis described below and preventing the liquid from intruding into the cooling unit 180 is attached to predetermined positions on the cooling unit body housing portion 181 and the coupler panel 182. The sealing member 183 is made of plastic resin or rubber.

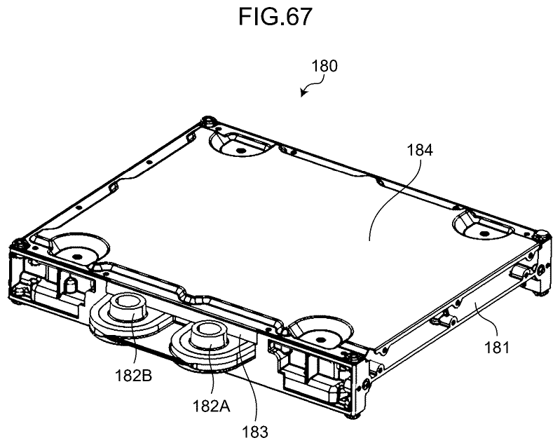

FIG. 67 is a completed perspective view of the cooling unit of the thirty-third embodiment.

FIG. 67 illustrates a state in which a front chassis 184 is attached to the cooling unit body housing portion 181 so as to cover the coupler panel 182 and the sealing member 183.

In this case, the cooling unit body housing portion 181 and the front chassis 184 are, for example, screwed.

According to the thirty-third embodiment, the cooling unit body housing portion 181 integrally forms the main part of the cooling unit body and the housing in the above-described embodiments. Therefore, it is possible to further reduce a possibility of the liquid intruding from the outside as compared with a case where the main part and the housing are formed separately, and it is possible to guarantee an operation of an electronic device disposed between the cooling unit body housing portion 181 and the front chassis 184 and to maintain high reliability.

### (17) Modified Example of Embodiment

In the above description, the sharing of components has not been described except for the description of the sixteenth embodiment. However, by forming components provided with the height adjustment portion, such as the first housing and the second housing of the cooling unit, or the height adjustment member, it is possible to support various substrates, and it is possible to efficiently cool a semiconductor chip that is a cooling target component without increasing the number of components.

In the above description, a case where the height adjustment portion (height adjustment member) has a protruding shape has been mainly described. However, the height adjustment portion may be formed as a recessed shape, an opening shape, or a notch shape depending on the mounting state of the semiconductor chip that is the cooling target component.

In the above description, the semiconductor chip has been described as the cooling target component, but the present disclosure is not limited thereto, and any component requiring cooling can be similarly applied. For example, the present disclosure can be similarly applied to a storage battery, a transformer, a capacitor, a coil, a resistance element, a crystal oscillator, a Peltier element, and the like.

### (18) Summary

As described above, according to each embodiment, it is possible to easily construct the cooling system according to the mounting state of the cooling target semiconductor chip on the substrate on which the semiconductor chips with various heights are mounted without a complicated manufacturing process or without increasing the number of components.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

Furthermore, the effects of the embodiments described in the present specification are merely examples and are not limited, and other effects may be provided.

### Supplementary Note

The present embodiment can also have the following aspects.

A cooling device according to a first other aspect is a cooling device that cools a plurality of cooling target chips mounted on a substrate, the cooling device including:
a heat transfer member configured as one member and having a plurality of height adjustment portions formed according to heights of the chips and mounting positions of the chips; and
a liquid cooling unit thermally coupled to the heat transfer member and through which a liquid coolant is circulated.

According to the present aspect, the number of components of the heat transfer member can be reduced, and the cooling efficiency can be maintained while simplifying the manufacturing process.

According to a second other aspect, in the cooling device according to the first other aspect, the liquid cooling unit has a plate shape having two planar cooling surfaces, and
the heat transfer member is thermally coupled to at least one of the cooling surfaces.

According to the present aspect, it is possible to implement a cooling device capable of supporting a plurality of types of substrates while sharing a liquid cooling unit.

According to a third other aspect, in the cooling device of the first other aspect, the height adjustment portion is formed as a protrusion, a recess, a notch, or an opening in the heat transfer member.

According to the present aspect, the heat transfer members of various aspects can be formed based on a mounting state (a position, a height, and a relationship to other components on the substrate) of the cooling target chip.

According to a fourth other aspect, in the cooling device according to the first other aspect,
in the heat transfer member, the height adjustment portion is formed by pressing a metal plate.

According to the present aspect, it is possible to easily form the height adjustment portions according to the mounting states of the plurality of cooling target chips.

According to a fifth other aspect, in the cooling device according to the first other aspect,
in the heat transfer member, the height adjustment portion is formed by forging a metal plate.

According to the present aspect, it is possible to easily form the height adjustment portions according to the mounting states of the plurality of cooling target chips.

According to a sixth other aspect, in the cooling device according to the first other aspect,
the heat transfer member is brazed to the liquid cooling unit.

According to the present aspect, it is possible to reliably perform cooling without changing an attachment position of the heat transfer member to the liquid cooling unit.

According to a seventh other aspect, in the cooling device of the sixth other aspect,
the height adjustment portion is formed as a protrusion, and
the heat transfer member is provided with a hole around the height adjustment portion.

According to the present aspect, when the heat transfer member is brazed to the liquid cooling unit, bubbles do not enter the brazed portion, so that a thermal resistance is reduced, and cooling can be easily performed.

According to an eighth other aspect, in the cooling device according to the first other aspect,
the heat transfer member is provided on the substrate.

According to the present aspect, the configuration of the liquid cooling unit can be simplified, and shielding or grounding can be performed by the heat transfer member.

A cooling device of a ninth other aspect is a cooling device that cools a plurality of cooling target chips mounted on a substrate, the cooling device including
a liquid cooling unit which has a plurality of height adjustment portions disposed according to heights of the chips and mounting positions of the chips and is configured as one member and through which a liquid coolant is circulated.

According to the present aspect, the number of components of the heat transfer member can be reduced, and the cooling efficiency can be maintained while simplifying the manufacturing process.

According to a tenth other aspect, in the cooling device according to the ninth other aspect, the liquid cooling unit includes:
a first housing that forms a housing;
a second housing that forms the housing and is integrated with the first housing to form a flow path space through which the liquid coolant flows;
one or more first fin members disposed in the flow path space;
an inlet port that introduces the liquid coolant into the flow path space; and
a discharge port that discharges the liquid coolant from the flow path space, and
the height adjustment portion is formed as the one member in at least one of the first housing and the second housing.

According to the present aspect, the cooling efficiency can be maintained with a simple configuration.

According to an eleventh other aspect, in the cooling device according to the tenth other aspect,
the height adjustment portion is formed as a protrusion having a height corresponding to the corresponding cooling target chip.

According to the present aspect, it is possible to reliably thermally couple the cooling target chip, and the cooling efficiency can be improved.

According to a twelfth other aspect, in the cooling device according to the eleventh other aspect,
a second fin member is disposed between the housing and the first fin member on a flow path space side in the protrusion.

According to the present aspect, it is possible to avoid a decrease in strength of the cooling device due to the formation of the height adjustment portion, and to improve reliability.

According to a thirteenth other aspect, in the cooling device according to the twelfth other aspect,
a separator for disposing the second fin member separately from the first fin member is provided between the first fin member and the second fin member.

According to the present aspect, it is possible to maintain a desired flow of the liquid coolant by eliminating overlap between the first fin member and the second fin member at the time of stacking.

According to a fourteenth other aspect, in the cooling device according to the thirteenth other aspect,
the separator has a flat plate shape and is fixed to both the first fin member and the second fin member.

According to the present aspect, a positional relationship between the first fin member and the second fin member can be stabilized to form a stable liquid coolant flow path.

According to a fifteenth other aspect, in the cooling device according to the thirteenth other aspect,
the separator includes a separator body and a movement restricting member that is bent in between fins of the first fin member from the separator body to contact with the fins of the first fin member to restrict movement of the separator.

According to the present aspect, a positional relationship between the first fin member and the second fin member can be stabilized to form a stable liquid coolant flow path.

According to a sixteenth other aspect, in the cooling device according to the thirteenth other aspect,
the separator includes: a separator body; and
a movement restricting member that is bent from the separator body into the height adjustment portion and comes into contact with a wall of the height adjustment portion to restrict movement of the separator.

According to the present aspect, a positional relationship between the first fin member and the second fin member can be stabilized to form a stable liquid coolant flow path.

According to a seventeenth other aspect, in the cooling device according to the thirteenth other aspect,
on the flow path space side in the protrusion, a bottom-plate-attached extrusion fin is disposed in a state in which it is in contact with both the housing and the first fin member and its movement is restricted.

According to the present aspect, a stable liquid coolant flow path can be formed.

According to an eighteenth other aspect, in the cooling device according to the eleventh other aspect,
on the flow path space side in the protrusion, a block-shaped height adjustment portion holding member is disposed in a state in which it is in contact with both the housing and the first fin member and its movement is restricted.

According to the present aspect, a stable liquid coolant flow path can be formed.

According to a nineteenth other aspect, in the cooling device according to the ninth other aspect,
the liquid cooling unit includes:
a first housing that forms a housing;
a second housing that forms the housing and is integrated with the first housing to form a flow path space through which the liquid coolant flows;
one or more first fin members disposed in the flow path space;
an inlet port that introduces the liquid coolant into the flow path space; and
an outlet port that discharges the liquid coolant from the flow path space, and
in at least one of the first housing and the second housing, a burring portion and
a block-shaped member that is inserted into an opening portion of the burring portion from a side opposite to a side on which the first fin member is positioned and bonded are formed as the height adjustment portion integrally with the housing.

According to the present aspect, a stable liquid coolant flow path can be formed without increasing the number of components.

According to a twentieth other aspect, in the cooling device according to the ninth other aspect,
the liquid cooling unit includes:
a first housing that forms a housing;
a second housing that forms the housing and is integrated with the first housing to form a flow path space through which the liquid coolant flows;
one or more first fin members disposed in the flow path space;
an inlet port that introduces the liquid coolant into the flow path space; and
a discharge port that discharges the liquid coolant from the flow path space, and
in at least one of the first housing and the second housing, a burring portion and
a block-shaped member that is inserted into an opening portion of the burring portion from a side on which the first fin member is positioned and bonded as the height adjustment portion are formed integrally with the housing.

According to the present aspect, a stable liquid coolant flow path can be formed without increasing the number of components.

According to a twenty-first other aspect, in the cooling device according to the eleventh other aspect,
a second fin member is disposed on the flow path space side in the protrusion and between the housing and the first fin member,
fin arrangements of the first fin member and the second fin member are a straight arrangement, a wave arrangement, or an offset arrangement, and not both are the straight arrangement.

According to the present aspect, a positional relationship between the first fin member and the second fin member can be stabilized to form a stable liquid coolant flow path.

According to a twenty-second other aspect, in the cooling device according to the ninth other aspect,
the liquid cooling unit includes:
a first housing that forms a housing;
a second housing that is integrated with the first housing to form the housing;
one or more height adjustment portions formed in at least one of the first housing and the second housing; and
a three-dimensional fin member in which a flow path space through which the liquid coolant flows is formed inside the housing including the height adjustment portion, and a liquid coolant flow path through which the liquid coolant flows in a three-dimensional direction in the flow path space is three-dimensionally stacked.

According to the present aspect, it is possible to form a stable liquid coolant flow path while maintaining the heat exchange efficiency.

According to a twenty-third other aspect, in the cooling device according to the twenty-second other aspect,
the three-dimensional fin member is formed by stacking a plurality of sub three-dimensional fin members.

According to the present aspect, a stable liquid coolant flow path can be secured, and heat exchange can be stably performed.

According to a twenty-fourth other aspect, in the cooling device according to the twenty-second other aspect,
the liquid cooling unit includes:
a first housing that forms a housing;
a second housing that forms the housing and is integrated with the first housing to form a flow path space through which the liquid coolant flows;
a plurality of first fin members that are stacked in the flow path space and at each of which the liquid coolant flows in a zigzag manner in a direction orthogonal to an overall flow direction;
an inlet port that introduces the liquid coolant into the flow path space; and
a discharge port that discharges the liquid coolant from the flow path space, and
in at least one of the first housing and the second housing, an opening portion and
a height adjustment member in which one or more height adjustment portions are provided by pressing a thick plate-shaped metal member and which is bonded so as to close the opening portion are provided.

According to the present aspect, it is possible to obtain a cooling device capable of supporting various mounting states with a simple manufacturing procedure.

A cooling device according to a twenty-fifth other aspect is
a cooling device that cools a plurality of cooling target components mounted on a substrate, the cooling device including
a liquid cooling unit which has a plurality of height adjustment portions disposed according to heights of the cooling target components and mounting positions of the cooling target components and is configured as one member and through which a liquid coolant is circulated, in which
the liquid cooling unit includes:
a first housing that forms a housing;
a second housing that forms the housing and is integrated with the first housing to form a flow path space through which the liquid coolant flows;
one or more fin members disposed in the flow path space;
an inlet port that introduces the liquid coolant into the flow path space; and
an outlet port that discharges the liquid coolant from the flow path space, and
a flow path protrusion that reduces unevenness of distribution of a flow of the liquid coolant and makes it more uniform is provided downstream of the inlet port or upstream of the outlet port in the flow path space.

According to the present aspect, effective cooling efficiency can be improved.

According to a twenty-sixth other aspect, in the cooling device according to the twenty-fifth other aspect,
the flow path protrusion is formed in at least one of the first housing and the second housing.

According to the present aspect, it is possible to reduce the unevenness of the flow of the liquid coolant and improve the effective cooling efficiency.

According to a twenty-seventh other aspect, in the cooling device according to the twenty-fifth other aspect,
the flow path protrusions are provided at both of positions facing each other in the first housing and the second housing and are bonded at the positions facing each other.

According to the present aspect, the cooling efficiency can be improved while increasing the strength of the housing and reducing deformation of the housing.

According to a twenty-eighth other aspect, in the cooling device according to the twenty-seventh other aspect,
the flow path protrusions at the positions facing each other have different lengths in an extending direction of the flow path space.

According to the present aspect, further diffusion of the liquid coolant can be promoted.

According to a twenty-ninth other aspect, in the cooling device according to the twenty-fifth other aspect,
a shape of the flow path protrusion provided downstream of the inlet port is the same as a shape of the flow path protrusion provided upstream of the outlet port.

According to the present aspect, it is possible to reduce the unevenness of the flow of the liquid coolant at positions downstream of the inlet port and upstream of the outlet port and improve the effective cooling efficiency.

According to a thirtieth other aspect, in the cooling device according to the twenty-fifth other aspect,
a shape of the flow path protrusion provided downstream of the inlet port is different from a shape of the flow path protrusion provided upstream of the outlet port.

According to the present aspect, it is possible to suitably reduce the unevenness of the flow of the liquid coolant at each of positions downstream of the inlet port and upstream of the outlet port and improve the effective cooling efficiency.

According to the thirtieth other aspect, in the cooling device according to the twenty-fifth other aspect,
the flow path protrusion provided downstream of the inlet port has a shape intended for diffusion of the liquid coolant, and
the flow path protrusion provided upstream of the outlet port has a shape that suppresses generation of a vortex.

According to the present aspect, it is possible to reduce an amount of the liquid coolant remaining in the cooling device and improve the heat exchange efficiency.

According to a thirty-first other aspect, in the cooling device according to the twenty-fifth other aspect,
a plurality of the fin members are provided between the inlet port and the outlet port, and
the flow path protrusion is provided between the fin member at an upstream position and the fin member at a downstream position.

According to the present aspect, even in the middle of the flow path space, cooling can be performed with reduced unevenness of the flow of the liquid coolant and further improved heat exchange efficiency.

A cooling device according to a thirty-second other aspect is
a cooling device that cools a plurality of cooling target components mounted on a substrate, the cooling device including:
a liquid cooling unit that is thermally coupled to the cooling target components and causes a liquid coolant to flow into a liquid coolant flow path to cool the cooling target components;
an inlet port that introduces the liquid coolant into the liquid coolant flow path;
an outlet port that discharges the liquid coolant from the liquid coolant flow path; and
a housing that houses the liquid cooling unit in a state in which the inlet port and the outlet port protrude, in which
the housing includes a guide member that guides a liquid to be removed in a predetermined direction.

According to the present aspect, it is possible to suppress the liquid to be removed from reaching the cooling target components, so that it is possible to improve reliability.

According to a thirty-third other aspect, in the cooling device according to the thirty-second other aspect,
the liquid to be removed is a liquid that has intruded into the housing or a liquid generated in the housing.

According to the present aspect, it is possible to cope with both the liquid to be removed, which has intruded from the outside, and the liquid to be removed, which is generated in the housing, and it is possible to suppress an influence on the plurality of cooling target components mounted on the substrate and to reliably perform cooling.

According to a thirty-fourth other aspect, in the cooling device according to the thirty-second other aspect,
the housing is provided with one or more discharge holes through which the liquid to be removed is discharged outside the housing, and
the guide member guides the liquid to be removed to the discharge hole.

According to the present aspect, since the liquid to be removed is guided outside the housing through the discharge hole, it is possible to suppress the influence on the plurality of cooling target components mounted on the substrate and reliably perform cooling.

According to a thirty-fifth other aspect, in the cooling device according to the thirty-second other aspect,
the guide member has a slope and guides the liquid to be removed in a predetermined direction by the slope.

According to the present aspect, since the liquid to be removed is guided in the predetermined direction by the slope, it is possible to suppress the influence on the plurality of cooling target components mounted on the substrate and reliably perform cooling.

According to a thirty-sixth other aspect, in the cooling device according to the thirty-fifth other aspect,
the guide member is provided on an upper surface of the housing and guides the liquid arriving from above by the slope to a side surface of the housing.

According to the present aspect, since the guide member guides the liquid arriving from above by the slope to the side surface of the housing, it is possible to suppress the influence on the plurality of cooling target components mounted on the substrate and reliably perform cooling.

According to a thirty-seventh other aspect, in the cooling device according to the thirty-second other aspect,
the guide member is made of a material capable of absorbing and holding a predetermined amount of the liquid to be removed.

According to the present aspect, movement of the liquid to be removed is restricted, and thus, it is possible to suppress the influence on the plurality of cooling target components mounted on the substrate and reliably perform cooling.

According to a thirty-eighth other aspect, in the cooling device according to the thirty-sixth other aspect,
the guide member is adhered to a surface of the liquid cooling unit.

According to the present aspect, the guide member can reliably guide the liquid to be removed on the surface of the liquid cooling unit, and thus, it is possible to reliably perform cooling while suppressing the influence on the plurality of cooling target components mounted on the substrate.

According to a thirty-ninth other aspect, in the cooling device according to the thirty-seventh other aspect,
the guide member is formed such that a tip in a gravity direction is gradually narrowed, and the liquid to be removed, which is no longer held, is released from the tip in the gravity direction due to a weight of the liquid to be removed.

According to the present aspect, since the liquid to be removed, which is no longer held, is released from the tip of the guide member in the gravity direction due to the weight of the liquid to be removed, the liquid to be removed can be reliably guided without any control, and thus, it is possible to reliably perform cooling while suppressing the influence on the plurality of cooling target components mounted on the substrate.

According to a fortieth other aspect, in the cooling device according to the thirty-ninth other aspect,
a discharge hole for discharging the liquid to be removed outside the housing is provided below the tip in the gravity direction.

According to the present aspect, the liquid to be removed can be reliably discharged outside the housing.

According to a forty-first other aspect, in the cooling device according to the thirty-ninth other aspect,
the guide member is mae of a nonwoven fabric.

According to the present aspect, the liquid to be removed can be reliably guided with a simple configuration.

A cooling device according to a forty-second other aspect is
a cooling device that cools a plurality of cooling target components mounted on a substrate, the cooling device including:
a housing that is integrated with a liquid cooling unit that is thermally coupled to the cooling target components and causes a liquid coolant to flow into a liquid coolant flow path to cool the cooling target components;
an inlet port that protrudes from the liquid cooling unit and introduces the liquid coolant into the liquid coolant flow path; and
an outlet port that protrudes from the liquid cooling unit and discharges the liquid coolant from the liquid coolant flow path.

According to the present aspect, since the housing integrated with the liquid cooling unit is provided, it is possible to prevent the liquid to be removed from being generated and to prevent the liquid to be removed from reaching the cooling target components, so that reliability can be improved.

According to a forty-third other aspect, in the cooling device according to the thirty-second other aspect or the cooling device according to the forty-second other aspect,
the substrate on which a cooling target component is mounted is housable in the housing.

According to the present aspect, cooling can be performed more efficiently.

An in-vehicle apparatus according to a forty-fourth other aspect includes:
the cooling device according to any one of the thirty-second to forty-second other aspects; and
the substrate on which the plurality of cooling target components are mounted.

According to the present aspect, it is possible to suppress the liquid to be removed from reaching the cooling target components, so that it is possible to improve reliability of the in-vehicle apparatus.

According to a forty-fifth other aspect, in the in-vehicle apparatus according to the forty-fourth other aspect,
the cooling device and the substrate are housed in the housing.

According to the present aspect, cooling efficiency for the substrate can be improved, and the reliability of the in-vehicle apparatus can be improved.

According to a forty-sixth other aspect, in the in-vehicle apparatus according to the forty-fourth other aspect,
the cooling device and a plurality of substrates are housed in the housing.

According to the present aspect, a cooling efficiency for the plurality of substrates can be improved, and the reliability of the in-vehicle apparatus can be improved.

An in-vehicle apparatus according to a forty-seventh other aspect includes:
the cooling device according to the forty-second other aspect; and
the substrate on which the plurality of cooling target components are mounted.

According to the present aspect, since the housing integrated with the liquid cooling unit is provided, it is possible to prevent the liquid to be removed from being generated and to prevent the liquid to be removed from reaching the cooling target components of the substrate, so that reliability can be improved.

According to a forty-eighth other aspect, in the in-vehicle apparatus according to the forty-seventh other aspect,
the substrate on which the cooling target components are mounted is housable in the housing.

According to the present aspect, since the number of components can be reduced, reliability can be further improved.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A cooling device that cools a plurality of cooling target components mounted on a substrate, the cooling device comprising:
a liquid cooler that is thermally coupled to the plurality of cooling target components and causes a liquid coolant to flow into a liquid coolant flow path to cool the plurality of cooling target components;
an inlet port that introduces the liquid coolant into the liquid coolant flow path;
an outlet port that discharges the liquid coolant from the liquid coolant flow path; and
a housing that houses the liquid cooler in a state in which the inlet port and the outlet port protrude, wherein
the housing includes a guide member that guides a liquid to be removed in a predetermined direction.

2. The cooling device according to claim 1, wherein
the liquid to be removed is a liquid that has intruded into the housing or a liquid generated in the housing.

3. The cooling device according to claim 1, wherein
the housing is provided with one or more discharge holes through which the liquid to be removed is discharged outside the housing, and
the guide member guides the liquid to be removed to the discharge hole.

4. The cooling device according to claim 1, wherein
the guide member has a slope and guides the liquid to be removed in a predetermined direction by the slope.

5. The cooling device according to claim 4, wherein
the guide member is provided on an upper surface of the housing and guides the liquid arriving from above by the slope to a side surface of the housing.

6. The cooling device according to claim 1, wherein
the guide member is made of a material that absorbs and holds a predetermined amount of the liquid to be removed.

7. The cooling device according to claim 5, wherein
the guide member is adhered to a surface of the liquid cooler.

8. The cooling device according to claim 6, wherein
the guide member is formed such that a tip in a gravity direction is gradually narrowed, and the liquid to be removed, which is no longer held, is released from the tip in the gravity direction due to its own weight.

9. The cooling device according to claim 8, wherein
a discharge hole for discharging the liquid to be removed outside the housing is provided below the tip in the gravity direction.

10. The cooling device according to claim 7, wherein
the guide member is made of a nonwoven fabric.

11. The cooling device according to claim 1, wherein
the substrate on which the cooling target components are mounted is housable in the housing.

12. A cooling device that cools a plurality of cooling target components mounted on a substrate, the cooling device comprising:
a housing that is integrated with a liquid cooler that is thermally coupled to the plurality of cooling target components and causes a liquid coolant to flow into a liquid coolant flow path to cool the plurality of cooling target components;
an inlet port that protrudes from the liquid cooler and introduces the liquid coolant into the liquid coolant flow path; and
an outlet port that protrudes from the liquid cooler and discharges the liquid coolant from the liquid coolant flow path.

13. The cooling device according to claim 12, wherein
the substrate on which the cooling target components are mounted is housable in the housing.

14. An in-vehicle apparatus comprising:
the cooling device according to claim 1; and
the substrate on which the plurality of cooling target components are mounted.

15. The in-vehicle apparatus according to claim 14, wherein
the substrate comprises a plurality of substrates.

16. The in-vehicle apparatus according to claim 14, wherein
the cooling device and the substrate are housed in the housing.

17. The in-vehicle apparatus according to claim 15, wherein
the cooling device and the plurality of substrates are housed in the housing.

18. An in-vehicle apparatus comprising:
the cooling device according to claim 12; and
the substrate on which the plurality of cooling target components are mounted.

19. The in-vehicle apparatus according to claim 18, wherein
the substrate on which the cooling target components are mounted is housable in the housing.
